(19) United States
(12) Patent Application Publication
(10) Pub. No.: US 2010/0181706 A1
(43) Pub. Date: Jul. 22, 2010

(54) Radiation Arrangement

(76) Inventors: Jari Ruuttu, Billnaes (FI); Reijo Lappalainen, Hiltulanlahti (FI); Vesa Myllymäeki, Helsinki (FI); Lasse Pulli, Helsinki (FI); Juha Mäkitalo, Tammisaari (FI)

Correspondence Address: BIRCH STEWART KOLASCH & BIRCH, PO BOX 747, FALLS CHURCH, VA, 22040-0747, US

(21) Appl. No.: 11/988,663

(22) PCT Filed: Jul. 13, 2006
(86) PCT No.: PCT/FI2006/000251

§ 371 Date: Apr. 21, 2008

(30) Foreign Application Priority Data
Jul. 13, 2005 (FI) 20050747
Feb. 23, 2006 (FI) 20060182
Apr. 12, 2006 (FI) 20060358

(51) Int. Cl. C23C 14/00; G02B 26/10; G02B 26/12; B23K 26/02; C23C 14/58; C23C 14/56; C23C 14/22; C23C 24/00; B29C 67/00; B29C 41/00

(52) U.S. Cl. 264/400; 359/200.4; 204/298.12; 204/298.02; 204/298.28; 204/192.1; 204/192.12; 204/192.15; 204/192.16; 204/192.25; 204/192.26; 427/248.1; 427/547; 427/532

(57) ABSTRACT

The invention relates in general level to radiation transference techniques as applied for utilisation of material handling. The invention relates to a radiation source arrangement comprising a path of radiation transference, or an improved path of radiation transference, which path comprises a turbine scanner or an improved turbine scanner. The invention also concerns a target material suitable for vaporization and/or ablation. The invention concerns an improved turbine scanner. The invention concerns also to a vacuum vaporization/ablation arrangement that has a radiation source arrangement according to invention. The invention concerns also a target material unit, to be used in coating and/or manufacturing target material.

### FIELD OF INVENTION

The invention relates in a very general level to radiation transference techniques as applied for utilisation of material handling. More specifically speaking, the invention relates to a radiation source arrangement according to the preamble of an independent claim thereof. The invention relates also to a path of radiation transference according to the preamble of an independent claim thereof. The invention relates also to target material according to the preamble of an independent claim thereof. The invention relates also to a vacuum vaporization/ablation arrangement according to the preamble of an independent claim thereof. The invention relates also to target material unit according to the preamble of an independent claim thereof. The invention relates also to turbine scanner according to the preamble of an independent claim thereof. The invention relates also to a surface processing method according to the preamble of an independent claim thereof. The invention relates also to a coating method according to the preamble of an independent claim thereof. The invention relates also to use of the coating method. The invention relates also to 3D-printer according to the preamble of an independent claim thereof. The invention relates also to 3D-copy machine according to the preamble of an independent claim thereof. The invention relates also to an arrangement to control radiation power of a radiation source via path of radiation transference according to the preamble of an independent claim thereof. The invention relates also to a manufacturing method of target material.

### BACKGROUND

In the recent years, considerable development of the laser technology has provided means to produce very high-efficiency laser systems that are based on semiconductor fibres, thus supporting advance in so called cold ablation methods.

However, the fibres of the conventional fibre-lasers do not facilitate high-powered, into pulsed shape compressed laser radiation transference into the working target with sufficient net-power. At required power level in the working target, the conventional fibres do not tolerate the losses in the radiation transference by the absorption of the radiation into the fibre. One reason, to use fibre-techniques in the laser radiation transference from the source to the target, has been that even a transference of a one single beam through free air is a considerable risk to the employers in industrial working environment and in industrial scale, technically very demanding if were not completely impossible.

At the priority date of the current application, solely fibrous diode-pumped semiconductor laser is competing with light-bulb pumped one, which both have the feature according to which the laser beam is lead first into a fibre, and then forwarded to the working target. These fibrous laser systems are the only ones to be applied in to the laser ablation applications in an industrial scale.

The recent fibres of the fibre lasers, as well as the consequent low radiation power limit the materials to be used in the vaporization/ablation as the vaporization/ablation targets. Vaporizing/ablating aluminium can be facilitated by a small-pulsed power, whereas the more difficult substances to be vaporized/ablated as Copper, Tungsten, etc. need more pulsed power. The same applies into situation in which new compounds were in the interest to be brought up with the same conventional techniques. Examples to be mentioned are for instance manufacturing diamond directly from carbon or alumina production straight from aluminium and oxygen via the appropriate reaction in the vapour-phase in post-laser-ablation conditions.

The transference of the laser beam by an optical fibre has been appearing to be the only way in the industrial world at the priority date of the current application.

Most significant obstacle to the forwarding progress of fibre-laser technology seems to be the fibre strength of the fibre to tolerate the high power laser pulses without break-up of the fibre or without diminished quality of the laser beam.

Because the energy content of a pulse, the power of the pulse increases in the decrease of the pulse duration, the problem significance increases with the decreasing laser-pulse duration. The problems occur significant even with the nano-second-pulse lasers, although they are not applied as such in cold ablation methods.

The pulse duration decrease further to femto or even to atto-second scale makes the problem almost irresolvable. For example, in a pico-second laser system with a pulse duration of 10-15 ps the pulse energy should be 5 μJ for a 10-30 μm spot, when the total power of the laser is 100 W and the repetition rate 20 MHz. Such a fibre to tolerate such a pulse is not available at the priority date of the current application according to the knowledge of the writer at the very date.

In an important field of applied laser-ablation utilising fibre-lasers, it is essentially important to facilitate the maximum optimal pulse-power and energy. The shorter the pulse, the larger the energy in a certain time to pass through the fibre. In the above-mentioned conditions of the pulse duration and total laser power, the power level of a single pulse can correspond 400 kW. Manufacturing of such a fibre that would tolerate even 200 kW and pass the 15 ps pulse through with non-distorted optimal pulse shape has been not possible before the priority date of the current application, according to the writer's knowledge.

Nevertheless, if unlimited facilities are desired for plasma production from any substance available, the power level of the pulse should be freely selectable, for instance between 200 kW and 80 MW.

The problems of the recent fibre-lasers are limited not only to the fibre itself, but concern also to the joining together of separate diode-pumped lasers by the optical connectors, so aiming to gain the desired total power. Such a joint beam is lead by a single fibre to the working target in the conventional techniques.

Consequently the optical connectors should tolerate as much power as the fibre itself, used as the path to transfer the high-power pulse into the working target. Even in the use of the conventional power levels, the manufacturing of the appropriate optical connectors is extremely expensive, the performance is uncertain in some extent and they are consumed up during the use, so they should be replaced with in a time interval.

### SUMMARY OF THE INVENTION

An aim of the current invention is to solve or at least to mitigate the problems of the known techniques. This aim is met by using embodiments of the invention.

The radiation source arrangement according to the invention is characterized in that what has been said in the characterizing part of an independent claim thereof. The path of radiation transference according to the invention is characterized in that what has been said in the characterizing part of an independent claim thereof. The target material according to the invention is characterized in that what has been said in the characterizing part of an independent claim thereof. The target material unit according to the invention is characterized in that what has been said in the characterizing part of an independent claim thereof. A vacuum-vaporization/ablation arrangement according to invention is characterized in that what has been said in the characterizing part of an independent claim thereof. An arrangement to control radiation power of a radiation source via path of radiation transference for guiding electromagnetic radiation is characterized in that what has been said in the characterizing part of an independent claim thereof. A surface processing method according to the invention is characterized in that what has been said in the characterizing part of an independent claim thereof. A coating method according to the invention is characterized in that what has been said in the characterizing part of an independent claim thereof. A 3D-printer according to invention is characterized in that what has been said in the characterizing part of an independent claim thereof. A 3D-copy-machine according to the invention is characterized in that what has been said in the characterizing part of an independent claim thereof. Manufacturing method of target material according to the invention is characterized in that what has been said in the characterizing part of an independent claim thereof. Other embodiments of the invention are shown in the dependent claims.

Radiation source arrangement as embodied according to the invention comprises a path of radiation transference, arranged to guide radiation beam as pulsed high-power radiation with turbine scanner from the radiation source to the target.

According to an embodiment of the invention, the radiation source arrangement comprises a radiation source arranged to produce radiation and an optical path arranged to direct said radiation into the working target without transference through external optical fibres or external optical high-power connectors, so to achieve the aim of the invention.

Various embodiments of the inventions are combinable in suitable part.

When read and understood the invention, the skilled men in the art may know many ways to modify the shown embodiments of the invention, however, without leaving the scope of the invention, which is not limited only to the shown embodiments which are shown as examples of the embodiments of the invention.

It is an astonishing observation, that a radiation beam can be actually directed to the working target without the transference fibre and/or optical high-power connectors. In this context “without” should be read so that for instance an optical expander is not so excluded where such a component is absolutely necessary in such embodiments, in which the expander is not integrated into the radiation source, but is needed at radiation-source end to modify the radiation beam geometry and/or to join various radiation sources for a joint beam.

According to an embodiment of the invention, the optical path for radiation transference comprises a scanner, which comprises according to a preferred embodiment of the invention at least a turbine scanner. According to an embodiment of the invention the optical path for radiation transference comprises an optical expander at a radiation-source end of the optical path. According to an embodiment of the invention the optical path for radiation transference comprises an optical contractor at a working target end of the optical path.

According to an embodiment of the invention the radiation source comprises an optical expander as integrated into the radiation source. According to an embodiment of the invention the optical path comprises a focusing system at the radiation source end and/or at the working target end of the optical path. According to an embodiment of the invention the optical path comprises joining means arranged to join several beams of radiation-sources into a joint radiation beam. According to an embodiment of the invention the joining means is arranged to join radiation beams in pulses in a certain phase.

According to an embodiment of the invention the radiation source arrangement comprises a first radiation source that has a first repetition rate and a second radiation source that has a second repetition rate, said radiation sources being connected with a joining member according to an embodiment of the invention so that the pulses of said first and second radiation sources are interlaced according to one embodiment variation, but at least partially non-interlaced according to another embodiment variation. Interlacing of the pulses can thus influence on the received power of the target, and can be used for optimizing the preparation for the target material and/or the vaporization/ablation. According to an embodiment of the invention a joining member is arrange to comprise means for joining at least two or more radiation sources together.

According to an embodiment of the invention each radiation source has several aspects of the radiation source so that at least one mode of radiation to be emitted when energized, said radiation has a wave length, polarization and/or pulse length and pulse shape as well as inter-pulse length in time. Each radiation source has also repetition rate of the pulses as a further aspect. According to an embodiment of the invention such a joining member to group individual radiation sources is arranged so that all the radiation sources were equal in said aspects. According to an embodiment of the invention such a joining member is arranged to be such that all the radiation sources were different in at least one aspect of the radiation source, which is not necessary the same for each jointed radiation sources.

According to an embodiment of the invention the radiation source arrangement comprises different radiation sources, with different aspects, jointed together with a joining member in order to be used to shape up the pulses experienced at the working target, so to optimize the pulse shape, total energy at the working target and/or to prepare the working target at the hit spot. According to one embodiment, an individual laser source is arranged to act as a radiation source with a first aspect and another laser source as a radiation source with a second aspect. According to an embodiment said first aspect is optimized for preparing the target by heating it before and/or during the ablation by the radiation with said second aspect optimized for the ablation in the related conditions. According to an embodiment of the invention a radiation source is arranged to prepare the target material and/or a part of it for ablation.

According to an embodiment of the invention the radiation-sources of the radiation source arrangement are diversified so that the actual radiation beam is formed at the working target. According to an embodiment of the invention the each radiation source has its own optical path according to the embodiment of the invention, preferably comprising a turbine scanner in each path.

The joining member can be arranged to operate as an expander as a separate component to join the radiation sources, or the expander can be arranged to be integrated into one radiation source so that the other radiation sources can join into the joining member. According to an embodiment of the invention the joining member is partly diversified between the radiation sources so that certain parts of the joining member are integrated into the radiation source and some other parts are not.

According to an embodiment of the invention concerning the radiation source arrangement radiation sources of the arrangement are arranged into a radiation source device. According to an embodiment the optical path according to an embodiment of the invention or parts of it are comprised by the device. According to an embodiment of the invention the in-vacuum-vaporization/ablation device comprises a radiation source arrangement according to an embodiment of the invention and/or optical path according to an embodiment of the invention.

A path of radiation transference for guiding electromagnetic radiation according to an embodiment of the invention comprises a turbine scanner arranged to guide said electromagnetic radiation, in a radiation geometry, from the radiation source to the target of the radiation transferred as pulsed high-power radiation, for example laser beam pulses.

A radiation source arrangement according to an embodiment of the invention, comprises at least one or several diode-pumped radiation sources and that each radiation source has an optical path according to an embodiment of the invention.

A radiation source arrangement according to an embodiment of the invention comprises a first feature and/or a second feature, which is at least one of the following:
(i) the wavelength characteristic to the radiation source,
(ii) on-duty pulse length,
(iii) length of off-duty period between two successive pulses,
(iv) repetition rate of the on-duty occurrences,
(v) radiation intensity,
(vi) energy and/or power per pulse,
(vii) polarization of the radiation, and
a combination of at least two or more of the features (i)-(vii).

According to an embodiment of the invention said first feature is different than said second feature. According to an embodiment said feature is considered as an aspect of a radiation source.

A radiation source arrangement according to an embodiment of the invention has at least one radiation source which is arranged to produce radiation having a wave length in range which wave length is at least one of the following:
wavelength between a radio wavelength and an infrared wavelength,
wavelength in infrared,
wavelength of visible light,
wavelength of ultraviolet,
wave length of X-rays, and
wavelength of gamma rays.

According to one embodiment of the invention the optical path is arranged to comprise at least one path for plurality of radiation sources comprising at least one radiation source arranged to direct at least one radiation beam to a plurality of targets comprising at least one target.

According to an embodiment of the invention the radiation is laser-radiation. According to an embodiment of the invention, the laser is diode pumped. According to an embodiment of the invention the laser is light bulb pumped. According to an embodiment of the invention the laser is pumped by another laser. According to an embodiment of the invention the laser is pumped by pulsed radiation.

A target material according to an embodiment of the invention is arranged to be vaporizable and/or ablatable by a radiation of a radiation source according to an embodiment of the invention.

A vacuum vaporization/ablation arrangement according to an embodiment of the invention comprises a radiation source arrangement according to an embodiment of the invention, said arrangement arranged to vaporize/ablate material from a target to be used in coating of a substrate.

A target material unit according to an embodiment of the invention comprises a first reel arranged to release target material in one end of the film path and a second reel arranged to roll the released target material in the opposite end of the film path.

A target material unit according to an embodiment of the invention comprises means to handle target material as sheets. In such an embodiment of the invention the target material unit has means to select a sheet of target material from a target material stack and/or from a plurality of stacks comprising at least one type of target material. In such an embodiment of the invention the target material unit has means to remove a used sheet of target material from a feeder of the target material unit into a stack of used sheets according to its type into a plurality of stacks arranged to comprise at least one type of target material.

The first aspect of the invention defines an ensemble of embodiments of the invention comprising at least an embodiment of the invention, but so that the embodiment is utilised for a coating-like actions, wherein material from a target is vaporized/ablated as a directable plume onto a substrate to be coated, so that it is the substrate or a derivable from that which forms the product. Also method related to the product, use of the product and/or use of the precursor for manufacturing such a product are considered to be comprised into the first aspect.

The second aspect of the invention defines an ensemble of embodiments of the invention comprising at least an embodiment of the invention, but so that the embodiment is utilised for a carving-like actions, wherein material from a target is vaporized/ablated as a directable plume, so that it is the target or a derivable from that which forms the product. Also method related to the product, use of the product and/or use of the precursor for manufacturing such a product are considered to be comprised into the second aspect. In to the scope of second aspect belongs thus such embodiments, in which a particular target material is not available, but a surface of a body is exposed to the carving like action.

The third aspect of the invention defines an ensemble of embodiments of the invention comprising at least an embodiment of the invention, but as a combination of the first aspect and/or the second aspect, in suitable part.

In theory, utilisation of embodiments of the invention so facilitates increasing the radiation power at the target without limitations, but provide also means to adjust several aspects of the radiation at the working target to match to the appropriate aspect of the invention. Thus this can be made by using one or several diode-pumped radiation sources as a radiation source for the radiation to be guided by an optical path, comprising a turbine scanner, to the working target, essentially without fibre-caused losses in an external optical path.

Embodiments of the invention according to the first aspect, second aspect or third aspect of the invention can be used to produce textured surface with coating to make catalytic surfaces, and/or biological or medical applications.

### FIGURES

In the following, the embodiments of the invention are described in more detail by referring to the following figures, in which

FIG. 1. illustrates a radiation arrangement according to an embodiment of the invention, comprising a diode-pumped fibre radiation source in a radiation system of type of modular oscillator power amplifier (MOPA), as arranged to form the radiation power at the target,

FIG. 2. illustrates a part of a radiation arrangement according to an embodiment of the invention, comprising the power amplifiers of the radiation pulse, such as the diode-pumps, are included into a vacuum evaporation system and in which optical fibre and/or optical high-power connectors are needed only the minimum for the radiation pulse,

FIG. 3. illustrates a part of a radiation source arrangement according to an embodiment of the invention, comprising optical path further comprising a turbine scanner to guide the radiation beam,

FIG. 4. illustrates a radiation source arrangement according to an embodiment of the invention, in which a diode-pumped radiation beam is arranged to be directable via correction optics into a vaporizable material,

FIG. 5. illustrates a part of a radiation source arrangement according to an embodiment of the invention embodied as an example with for radiation units in the radiation source arrangement of the vacuum vaporization device,

FIG. 6. illustrates vacuum vaporization device according to an embodiment of the invention,

FIG. 7. illustrates phased-diversified-amplified-directly directable-radiation system (PDADD-radiation system) according to an embodiment of the invention, in which the diode-pumped radiation beam is directable by a turbine scanner via correction optics integrated into the diode-pumped radiation,

FIG. 8. illustrates vacuum vaporization device according to an embodiment of the invention with a radiation source unit as a vaporization unit,

FIG. 9. illustrates vacuum vaporization device according to an embodiment of the invention with a radiation source unit inside the vacuum vaporization device,

FIG. 10. illustrates a radiation source arrangement according to an embodiment of the invention in which at least one or several of an ensemble of radiation beams are directable via an expander and/or turbine scanner to a vaporization target,

FIG. 11. illustrates a diode-pumped set of radiation sources according to an embodiment of the invention, wherein each diode-pump has own expander,

FIG. 12. illustrates a light pattern formation according to an embodiment of the invention as having an asymmetric shape,

FIG. 13. illustrates a light pattern formation according to an embodiment of the invention as having an asymmetric shape,

FIG. 14. illustrates examples of target materials according to an embodiment of the invention,

FIG. 15. illustrates a scan according to an embodiment of the invention,

FIG. 16. illustrates another scan according to an embodiment of the invention,

FIG. 17. illustrates a mechanism to handle target material in flat form as foil and/or ribbon, for example,

FIG. 18. illustrates the mechanism of FIG. 17, plume and the radiation source arrangement, as parts of vacuum vaporization/ablation arrangement according to an embodiment of the invention,

FIG. 19. illustrates example according to an embodiment of the invention,

FIG. 20. illustrates an example according to an embodiment of the invention,

FIG. 21. illustrates a schematic of an embodiment according to FIG. 20,

FIG. 22. illustrates a target material utilisation for a coating and/or material production according to an embodiment of the invention,

FIG. 23. illustrates a plume from target material during a scan line part,

FIG. 24. illustrates as an example a view from a control unit display of an embodiment arranged to control a stone or stone-plate coating process, such as to produce marble or like surfaces,

FIG. 25. illustrates targets, substrates and/or products according to embodiments of the invention, in respect to example of the manufacturing conditions,

FIG. 26. illustrates embodiments of low-faced turbine scanner according to an embodiment of the invention,

FIG. 27. illustrates embodiments of low-faced turbine scanner according to an embodiment of the invention,

FIG. 28. illustrates embodiments of high-faced turbine scanner according to an embodiment of the invention,

FIG. 29. illustrates embodiments of high-faced turbine scanner according to an embodiment of the invention,

FIG. 30. illustrate embodiments of high-faced turbine scanner according to an embodiment of the invention,

FIG. 31. illustrate radiation path during a scan with a turbine scanner with a face tilt,

FIG. 32. illustrates radiation paths during scans with a turbine scanner with another face tilt,

FIG. 33. illustrates rotating part of the turbine scanner and the scan line on target,

FIG. 34. illustrates a examples of a layered structure on a substrate,

FIG. 35.-52. illustrates further examples of use of coatings, each indicated substrate to be coated or made according to an embodiment of the invention,

FIG. 53. illustrates an example of an embodiment of the invention,

FIG. 54. illustrates a 3D-printer according to an embodiment of the invention,

FIG. 55. illustrates a 3D-copy machine according to an embodiment of the invention,

FIG. 56. illustrates a laser system according to an embodiment of the invention,

FIG. 57. illustrates a radiation source arrangement according to an embodiment of the invention,

FIG. 58. illustrates a target material unit according to an embodiment of the invention,

FIG. 59. illustrates target material feed according to an embodiment of the invention, and

FIG. 60. illustrates a surface processing method according to an embodiment of the invention.

The parts or details in the figures are not necessary in the scale, and thus have only an illustrative character. In different figures, also same reference numerals may be used for indicating like parts, which are not necessarily exactly the same in one figure as in another, which potential differences a skilled man in the art can realize from the embodiments shown and/or in the application text. The term “comprise” has been used as an open expression. Term “one embodiment” as well as “another embodiment” has been used for simplicity reasons to refer to at least one embodiment, but can also comprise an ensemble of embodiments with the indicated feature, alone, or in combination of suitable other embodiments.

### DETAILED DESCRIPTION OF EMBODIMENTS OF THE INVENTION

Embodiments of the invention concern radiation source arrangement. According to an embodiment of the invention the radiation is especially laser radiation. In a radiation source arrangement according to an embodiment of the invention, at least one or more radiation beams originating to a radiation source are directable to a target via an optical path according to an embodiment of the invention.

A radiation source arrangement according to an embodiment of the invention comprises a laser source as a radiation source. According to an embodiment of the invention, a radiation source comprises a diode-pumped radiation source. According to an embodiment of the invention a radiation source is a lamp-pumped radiation source. According to an embodiment of the invention a radiation source is a pulsed radiation source. According to an embodiment of the invention a radiation source is a pulsed radiation source, in which the pulse length is determined by the time of successive switch on and off of the radiation source, so including into the scope of the radiation source arrangement as one embodiment such an extreme embodiment of the invention comprising a source of continuously operable radiation source, between the moments switch on and off of the very radiation source.

In the following, an optical laser radiation has been used for simplicity reasons as an example only, so illustrating a coherent in phase radiation and/or its source without any particular intention to limit or exclude other wavelengths from the applicable electromagnetic spectrum for the radiation source arrangement.

In the following vaporization refers to a phase transition from liquid and/or solid phase to gaseous, if the energy used in vaporization does not produce significant amount of plasma, from the target material exposed to the radiation arranged to vaporize. However, when the phase transition of the target material is in significant sense about to yield a plasma phase, the phase transition of the target material is considered as ablation, although the writer of the applicant thinks that clear indication between vapour phase comprising ionized matter and pure plasma may at least in some cases not available.

According to an embodiment of the invention, the target comprises/is made of vaporizable/ablatable matter. Such matters, that are very easily vaporizable, comprise for example organic compounds and/or metals vaporizable in a low temperature as the temperature of vaporizing aluminium. The embodiments of the invention facilitate also vaporization/ablation of other substances, elements and/or compounds thereof, individually or in compounds, one substance individually or in groups, even several substances in parallel and/or in series, according to the respective embodiments. Of course, a provision is made on that some compounds can break into constituent parts of the compound during the vaporization/ablation, however as depending on the structure and/or the strength of the bond there between the parts of the compounds in question. Examples of substances having a high vaporization temperature are such substances as many other metals, their compounds, and carbon, which of the latter can form diamonds when leaving the vapour phase in industrially controllable conditions.

Thus, utilization of the radiation source arrangement according to an embodiment of the invention in the vaporization/ablation of target materials facilitates composing several materials quite freely, and thus manufacturing even new compounds. The substances can be so purified, manufactured as such, or used in coating applications to coat surfaces of various kinds once and/or several times.

According to an embodiment of the invention, the radiation source arrangement is arranged so, that the vaporization of the target material is made in a vacuum. Vacuum should be understood as a macroscopic volume, in which there is some material still present in a gaseous form. However, skilled men in the art know that vacuum can be considered as being several kinds of vacuums from the conditions of intermolecular empty space related conditions, via the empty space in the stellar space to the barely under-pressure conditions comparable to the ambient standard conditions. Atmosphere can thus comprise a vacuum with a predefined constituent composition, in under pressure. However, some embodiments of the invention can be implemented in an atmosphere that is over pressure, especially in embodiments in which the atmosphere comprises a product constituent, and/or in embodiments in which the phase balance is aimed to favour non-gaseous forms of the constituents.

Vacuum vaporization/ablation arrangement according to an embodiment of the invention comprises a radiation source arrangement according to an embodiment of the invention, but arranged to vaporize target material in vacuum conditions.

According to an embodiment of the invention the vacuum vaporization/ablation arrangement is embodied as a device. The path according to the embodiment of the invention, the radiation source arrangement according to an embodiment of the invention, the target material according to an embodiment of the invention and/or the handling equipment thereof are comprised in the same closure with the vacuum chamber unit in such a device. The device can also comprise the maintaining gadgets such as pumps, power sources, and/or data acquisition equipment etc. but is not limited only by said gadgets, their presence or absence.

According to an ensemble of embodiments of the invention, the path is at least partly outside the device. Particularly, such objects that change the radiation geometry and/or propagation direction as situated individually inside the device embody each an embodiment of the device. Also each combination of said objects situated inside the device define each an embodiment of the device.

Parts that are mounted solidly onto the chases of the device, essentially or completely outside the interior of the device, are included to the scope in the same cover.

Further embodiments on the vacuum vaporization/ablation arrangement have been further described via a non-limiting example within a paragraph addressed to examples.

A path of radiation transference for guiding electromagnetic radiation, (referred also as “path” in the following), according to an embodiment of the invention comprises a turbine scanner arranged to guide said electromagnetic radiation, in a radiation-geometry, from the radiation source to the target of the radiation. According to an embodiment of the invention the radiation is transferred as pulsed high-power laser beam pulses.

According to an embodiment of the invention the path of radiation transference for guiding electromagnetic radiation can comprise a beam expander, but is not limited thereto, for changing the radiation geometry of the radiation originating to the radiation source. A path according to an embodiment of the invention can comprise a correction optical means arranged to correct the beam geometry at the path. The expander and the correction optics are the same in one embodiment, but are separate in another embodiment. According to an embodiment of the invention the geometry can be modified in order to achieve a certain focus geometry, for example on the target to be vaporized. According to an embodiment of the invention the path can address the focus point being set above, into inside the target material or somewhere there between, in respect any of the surface formations of the target material to a certain distance, selectable by the target material, the radiation source features and/or other parameters relevant to the desired plume formation form the target piece. According to an embodiment of the invention the corrected geometry can be the geometry in which the beam is arranged to hit the turbine scanner part.

According to an embodiment, there can be also geometry for the radiation to hit the turbine scanner, a first geometry, and/or a geometry for the radiation to hit the target, a second geometry, which are not necessary the same, but each can be adjustable by the correction optics where absolutely necessary for the plume optimization emittable from the target. According to an embodiment of the invention the path is arranged from the radiation source to the target so that the radiation beam in said path is directed to another direction than an emitting plume, which is arranged to form from said target by said radiation.

Expander part, connectable to a diode-pump of the radiation source arrangement, can be an integrated part in one embodiment but connectable via a power fibre in another embodiment.

The path comprises advantageously a turbine scanner. Such a turbine scanner can be a conventional turbine scanner, which can tolerate radiation of the radiation source arrangement at a certain maximum level. Such a scanner in movement can tolerate very high pulsed radiation power without essential damage, and in theory facilitates the increase of the laser power, if not completely without limitation, at least to very high level. The currently embodied radiation source arrangement can comprise several turbine scanners, in one path according to an embodiment of the invention or in several paths according to another embodiment. Conventional turbine scanners are commercially available, and the speed can be typically about 5 km/s at the priority date of the current application.

According to an embodiment of the invention, a conventional turbine scanner piece can be arranged to be as a substrate, to receive a coating plume from a target, and the turbine scanner can be coated within a vacuum vaporization/ablation arrangement, which comprises a radiation source arrangement according to an embodiment of the invention and thus a path, comprising a turbine scanner, another one in duty. When the coating material is selected to be carbon, the turbine scanner according to an invention can be made by coating the conventional turbine scanner at least partly with a diamond coating and thus considerably increase the operating temperature and thus thermal conduction properties with a suitable dopant selection to be used to dope the diamond coating.

Such a turbine scanner according to an embodiment of the invention can tolerate radiation in a significantly higher level than a conventional turbine scanner. Thus, an improved path according to an embodiment of the invention comprises advantageously a turbine scanner according to an embodiment of the invention. Accordingly, an improved radiation source arrangement comprises an improved path according to an embodiment of the invention. Thus, an improved embodiment can be achieved from an embodiment of the invention, where applicable.

As according to an embodiment of the invention also according to an improved embodiment of the invention, the radiation from the radiation source arrangement can be directed to the target. Where applicable or necessary, in such an embodiment, an expander or correction optics can be used to form the radiation geometry at the target. According to an embodiment, each source of radiation sources arrangement or an ensemble of the sources can have its own path. The paths can lead to separate targets according to one embodiment, but to same target according to another embodiment. Those mentioned targets can be the same, but not necessarily at the same time. According to an embodiment of the invention two paths can lead to the same target in serial way in respect of time, but also in parallel in surface area, simultaneously or at least partly simultaneously in respect of the pulse durations.

Radiation source arrangement can be embodied to various embodiments according to radiation-source types present in each embodiment. So, for instance in one embodiment the arrangement can comprise hot-work laser such as micro- and/or nanosecond-laser. According to a more preferred embodiment of the invention, the arrangement comprises a cold-work laser, such as pico-, femto- and/or alto-second-laser. According to an embodiment the arrangement can comprise a laser that sends its pulse between a switch on and successive switch off, so including into a scope also a continuously operating laser, between said switch on and offs.

The embodiments of the invention have advantages such as the radiation source arrangement avoids as much as possible, if not entirely, the utilisation of high-power connectors in the radiation source arrangement parts, which connector utilisation limit the increase of the radiation power, and further the transferring the power into the target. At the priority date of the current application a theoretical tolerance of a fibre in optical range is about 5 μJ per pulse. Thus a great step forward can be achieved by using a path or an improved path according to an embodiment of the invention. For instance a radiation source arrangement as embodied as a cold-work laser can thus increase the power per pulse having shorter pulses at a constant pulse energy. Thus, limitations to the radiation sources are not so serious any more because the limiting fibres can be omitted. This leads to even larger pulse powers and working temperatures on the target, so facilitating vast potential to produce plasma from any material. When the pulse length and/or pitch are adjustable, the target material can be ablated from deeper layers. This avoids reflections thus contributing the power in the target to vaporization/ablation with a better yield.

For instance, a high-power laser pulse can be produced, scanned and used in one target. The diode-pump, optical expander in an optical application with optical laser light, scanner, and correction optics are in the same place, mountable into the same chases. The laser light is produced thus at the target. However, the radiation wavelength is not limited to the mere visible laser light, but also other wavelengths of the electromagnetic spectrum can be used for the laser radiation.

Expensive fibres can be omitted, thus saving the money and replacement periods are excluded, because there is no such part to be replaced. Especially expensive are the optical high-power connectors for visible radiation, for instance. The dimensioning of a fibre laser has been suffered from the limited applicable fibre length. The radiation source arrangement according to an embodiment or improved embodiment can be dimensioned much more freely.

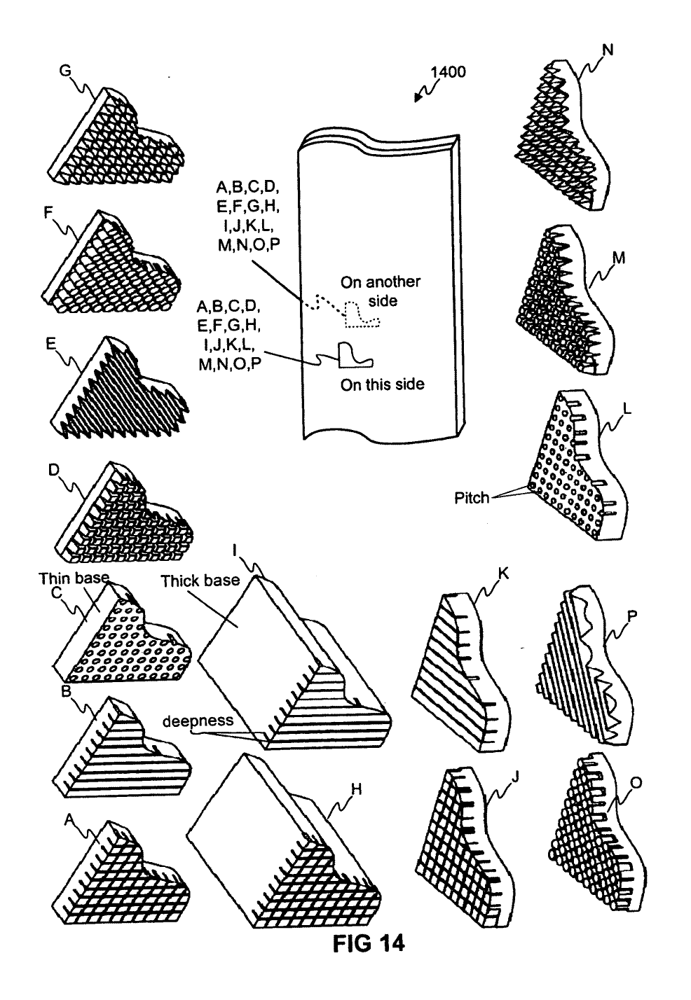

FIG. 14 illustrates target material surface structure, as a piece of the target material, which has formations on a base-structure. Inventors have noticed, that the target material surface formations influence on the ablation plume formation for optimizing the conditions. Different formation geometries can influence on the energy distribution in the target material, the formation itself, as well as on the thermal conditions inside the formation under the ablating radiation.

According to an embodiment of the invention, the base can be thin (A, B, C, D, E, F, G, J, K, L, M, N, O, P) or thick (H, I). The formations can be of different material than the base, but are not limited thereto only. Even on the same base there can be surface formations of different material, so arranged there to be utilizable for blending and/or phasing a coating with different materials in a vaporization/ablation. The skilled men in the art know from the FIG. 14 that although there are shown only surface formation on one side of the base, there can be also another surface at the opposite side of the base with similar surface formations, according to one embodiment, or different surface formations according to another embodiment.

For instance, in FIG. 14 the item A embodies a cubic like rectangular periodic structure of the surface formations, with a cube side as a characteristic formation parameter for the very embodiment. Another characteristic formation parameter in A is the pitch there between the formations, which are made with the pitch to certain deepness on to the thin base. The embodiment in FIG. 14 denoted by item B embodies rectangular formations on a thin base, so that the pitch is also very small in comparison to the cross-wise parameter of the rectangular ridge, whereas in the elongated direction the length of the formations is larger than cross-wise parameter. The deepness seems to be the same as in the example denoted A, but is not limited to the shown examples with their measures, which embody only certain examples having an illustrative nature only. The pitch can be even larger than the characteristic parameter in a direction and/or in a crosswise direction to said direction.

The surface formations in the item C are holes with a distance as the pitch. The holes are round in this embodiment of the target material, but could be in another embodiment rectangular, ellipsoid or even multi-conical.

In the embodiment in the item D the surface formations are like cut pyramids, whereas in the item G, the pyramids have a sharp cone, although in the embodiment D the bottom of the pyramids is rectangular, as an example on a multi-conical bottom, but the bottom in the item G is triangular. The embodiment with E is similar to the embodiment with B, but in the E the ridges are triangular, whereas in B rectangular. The pitch in embodiment E appears to be zero, but only because of drawing-technical clarity reasons. In a variant of embodiment E the pitch can be even of the magnitude of elongated ridges, or of that of the cross-section thereof. In one embodiment ensemble, the pitch is defined at the bottom of the surface formation, at the joint to the base without limitation to the orientation of the macroscopic target piece, as a distance of successive similar formation parts. In another embodiment ensemble, the pitch is defined at the middle of the surface formation height from the top deep to the joint of the base. In a further embodiment ensemble the pitch is defined at a height in a plane parallel to the base somewhere else.

Embodiment at F is related to cylindrical surface formations having their axis perpendicular to the base plane. However, according to another embodiment of the invention the ridges can be elongated half cylinders having parallel axis to each other but also with the base surface as defined by the joint of the surface formations and the base.

The embodiment of H shows an example of embodiments with thick base, so the base thickness is larger than the height of the surface formations from the base. The surface formations in H are similar as in A, and the surface formations of I are similar to B, but only as the illustrative nature of the shown examples. A skilled man in the art knows from the FIG. 14 and the related embodiments that whatever surface formations can be embodied also with a thick plate, although not all are advantageous to the ablation.

The embodiment examples from J to P illustrate modifications to the surface formation basic form as embodied with the examples from A to I. A modification can be orientation modification, tilt of a part of the formation, or the whole formation, distance there between two successive adjacent formations in line, which can vary periodically, or in an escalating manner. A modification can be formation shape curvature in one direction, and/or in a cross-wise direction. A modification can be also a material and/or material structural modification. In one embodiment, for instance a certain cubes can be made of left-handed polarizing matter, but the next one for each in a certain direction could be made of right-hand polarizing matter. The degree of polarization or way of it could be also one modification.

In the embodiment J, the cubes of A have at least one modification of the mentioned, or a suitable combination of the above mentioned. In the embodiment K, the rectangular ridges of B have at least one modification of the mentioned, or a suitable combination of the above mentioned. In the embodiment L, the holes of C have at least one modification of the mentioned, or a suitable combination of the above mentioned. In the embodiment M, the cut pyramids of D have at least one modification of the mentioned, or a suitable combination of the above mentioned. In the embodiment N, the triangular pyramids of G have at least one modification of the mentioned, or a suitable combination of the above mentioned. In the embodiment O, the cylinders of F have at least one modification of the mentioned, or a suitable combination of the above mentioned. In the embodiment P, the triangular ridges of E have at least one modification of the mentioned, or a suitable combination of the above mentioned.

The orientation of the formations in A-I and the orientation of the formations J-P also illustrate the target material feed in different possible orientations to be used in an arrangement/apparatus for vaporization/ablation according to an embodiment of the invention.

The target material has been shown in FIG. 14 as a film-like ribbon 1400, with an indication to have the target material on one side in one embodiment only but in another embodiment on both sides. The second sided target material is indicated by the dashed line. According to an embodiment of the invention the target material is used from the film side. According to another embodiment the target material is used from the end of the target material ribbon. According to an embodiment of the invention target material is arranged into a form of a wire. According to an embodiment of the invention the wire has sub-structure comprising several wires. According to an embodiment of the invention the sub-wires in the substructure are arranged to match to the composition of the plume and/or the coating. According to an embodiment of the invention the target material is arranged to fit into target material unit that has electrostatic means to catch particles and/or potential fragments of the target material.

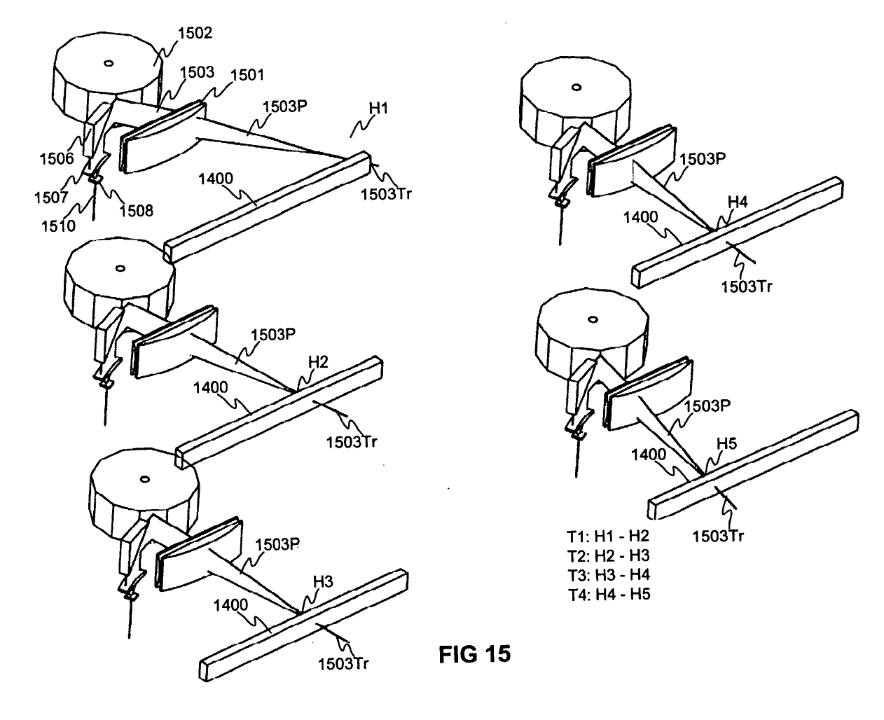

FIG. 15 illustrates an operation of a scanner to be used in the radiation path according to an embodiment of the invention. The scanner is a conventional turbine scanner, or an improved turbine scanner 1502 according to an embodiment of the invention. The rotation direction has been illustrated in the figures by a curved arrow. The radiation source 1600 (not shown in FIG. 15, but demonstrated by the beam 1510) can be embodied as a laser source embodied according to diode-pump of PDAD-system or any other cold ablation capable laser, i.e. with sufficiently powered laser, preferably with 100 W or larger in total power and having pulse length of pico-second, femto-second, or atto-second, with an inter-pulse pitch, and a pulse repetition rate larger than 20 MHz, advantageously larger than 50 MHz. The wavelength can be in the visible light region, but is not limited to that only. Although just one drawn, there can be also two or more radiation sources, operable in the same path in parallel or in series, which are not limited to the embodiment of similar source nor to that with all-different sources.

In FIG. 15, the radiation beam is reflected as a reflected beam 1503 via the turbine scanner 1502 mirror surface to an optical lens 1501, to the target 1400, which can have a smooth surface structure, roughened arbitrarily or a surface structure described according to FIG. 14 or the related text. The ablation point at the target is illustrated by H and the related number to illustrate also the scan on the surface of the target. So, the H1 defines a moment when the beam 1503P, which can be polarized to a certain polarization by its production and/or the optics 1501. Polarization of the beam in one hand, but the certain pattern of the surface formations on the target as arranged to have the same polarization with a certain composition but the others with a different composition and polarization on the other hand, can be used for certain selectiveness of the ablation during a scan, at least in theory. By selecting materials that are easy to ablate and materials that are very hard to ablate, the selectivity can be boosted for an embodiment of the invention. The FIG. 15 demonstrate the scan point H1, H2, H3, H4 and H5 which forms a series of arbitrary points from the scan path on the substrate 1400. The scan path can be continuous, according to an embodiment, from the scanner mirror part edge to the next edge, but can be discrete according to another embodiment, as depending the exact repetition rate of the radiation source, and/or the rotation speed of the turbine scanner 1502, in a certain fixed geometry. Also the inter-point times T1, T2, T3, T4 and T5 are shown.

The 1503Tr illustrates the beam part, which is gone through the substrate, and thus can be used for the estimating of even each individual pulse intensities and thus for the quality monitoring. In FIG. 15 the beam 1510 formed in the radiation source meets an expander 1508, which expands the beam to tapered shape, then the collimator unit 1507 to form a curtain-like broad but thin radiation wedge to be deflected by the turbine scanner 1502, through the correction optics 1501 optionally or in addition to polarization operation so that the beam 1503P hit the ablation target 1400 at the H1

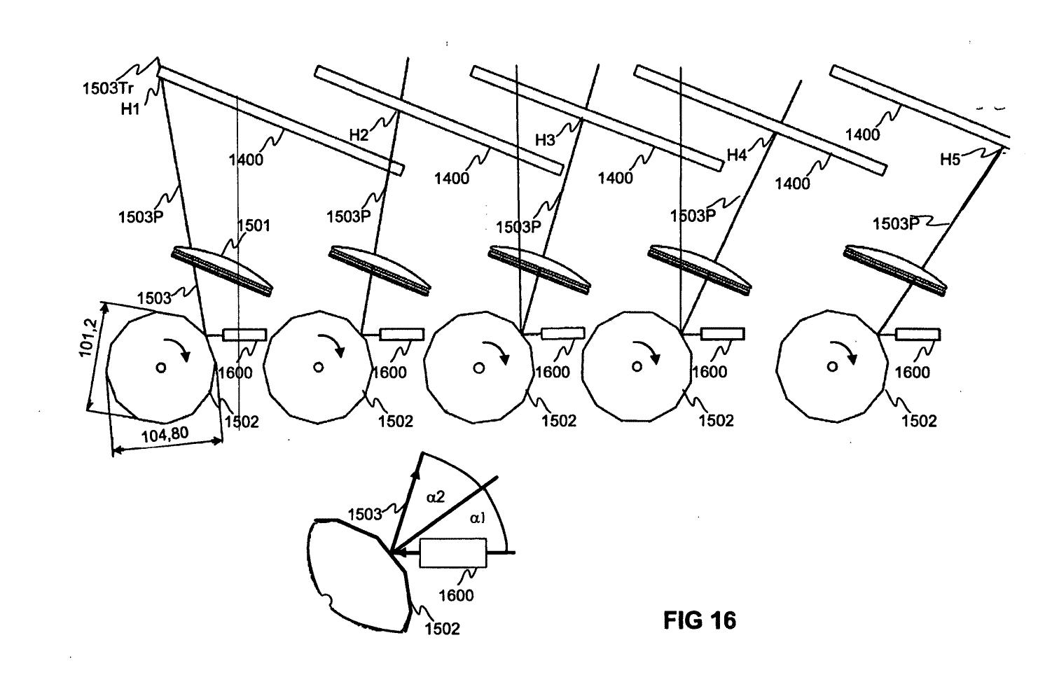

FIG. 16 embodies a similar kind of cycle as FIG. 15. The mirror 1502 can be a Turrent mirror, other rotatable mirror with mirror surfaces or a mirror part of the turbine scanner according to an embodiment of the invention. The angles α1 and α2 are embodied in the figure to indicate the useful range α2 for the scan to avoid the beam to hit the radiation arrangement 1602 and thus instability as a consequence. Although not shown in the figure, it is also advantageous to select an optical path, so that first surface modifying beam of the radiation source arrangement does not go through the material beam, the plume, ablated from the target. The measures apparent from the FIG. 16 are only examples and do not limit the size of the rotor of the turbine scanner only to the just mentioned.

In one example of the embodiments, the primary beam has 20 μm diameter. The beam has a wavelength of 1064 nm. The optical path has been arranged so that the beam has a focus diameter at a hit spot (H1, H2, H3, H4, H5) of 20 μm. The beam has proceeded the radiation path so that it has been having an elliptic cross-section, having a width of 30 mm in one direction and in crosswise 0.02 mm, at the scanner 1502 surface to avoid burning the mirror. The scan width has been 250 mm from the beginning to the end of the path. In the example, the focused beam is provided with linear correction (1501) on whole scan width on the target 1400. The distance from the optics to the target was 150 mm in the example.

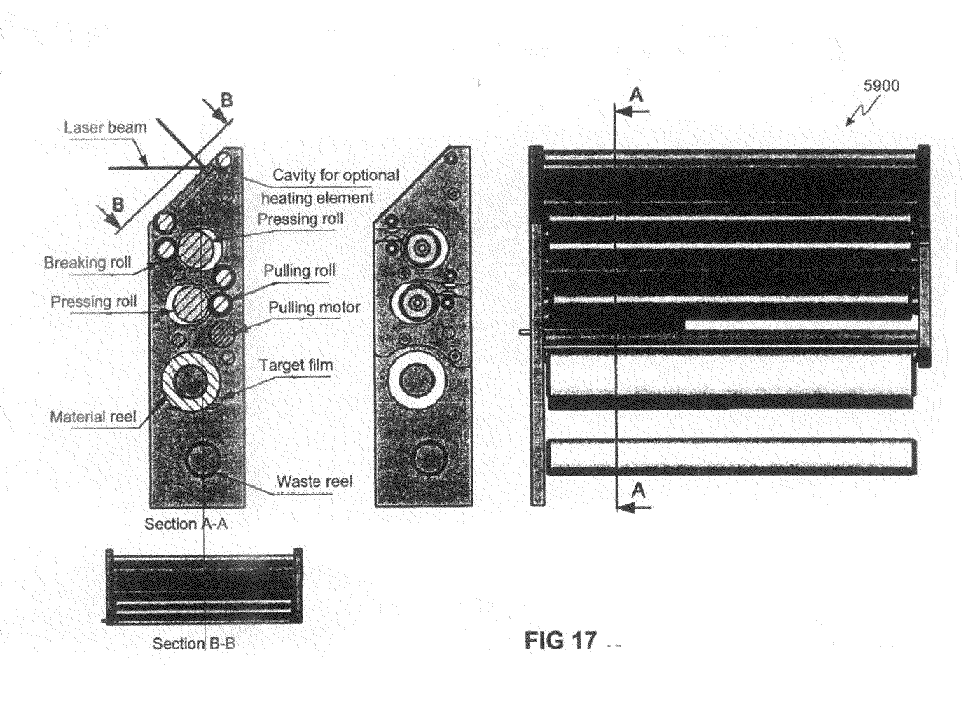

FIG. 17 embodies a foil-like/ribbon type target material, but also flat belt or solid rod like target materials and related mechanisms to be used in a target material unit to feed the target material. In the figure, the target film can be stored in a material reel, that is operated optionally by the friction of the target film pulled by the pulling motor or by a gear or by a system of its own in synchronism with the waste reel collection of the used material, so that film is tense only for the suitable part not to break. Flat solid belt-type target material sheets can be stored in a stack and as used in another stack, according to an embodiment of the invention. The mechanism can comprise breaking roll, a pressing roll to arrange the target material feed. The figure shows also a heater to be mounted in the cavity for optional heating element for the target material heating at the ablating area where the laser beam as a radiation has been indicated to meet the target material. The FIG. 17 shows the unit from several directions, also along the lines B-B and A-A as indicated in the FIG. 17.

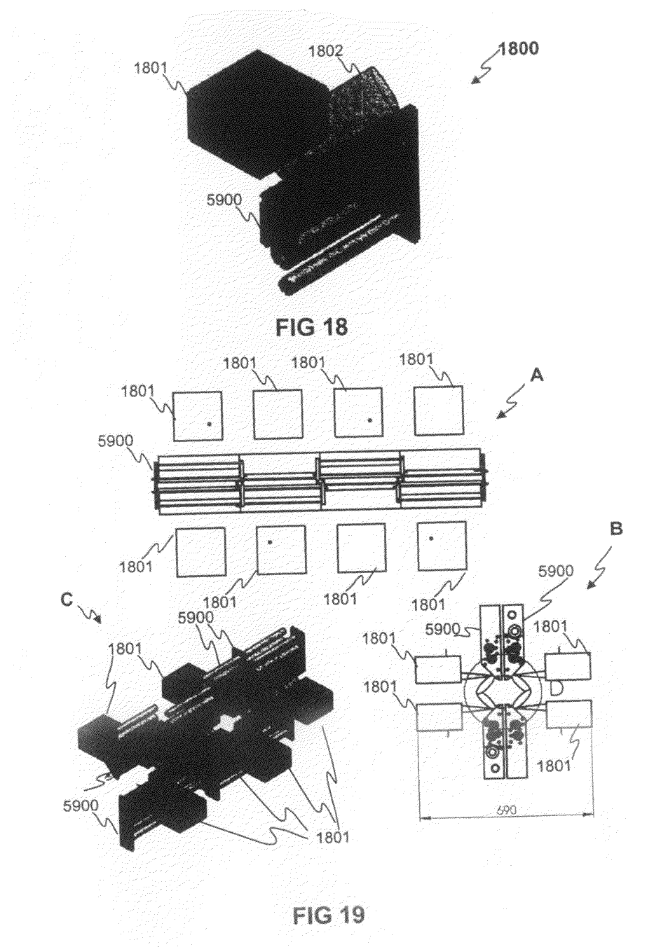

FIG. 18 demonstrates a radiation source arrangement 1801 to be used for a plume 1802 formation for a coating application with a target material fed to the coating process by the target material unit mechanism of FIG. 17. The arrangement 1800 can be comprised by a vacuum vaporization/ablation arrangement according to an embodiment of the invention. The target material can be fed optionally by a wire or a bunch of wires, the ablation to occur from an end of the wire. In such an embodiment with wire feed of the target, the system advantageously comprises an electrostatic collector to arranged to collect potential fragments so increasing the product quality and performance security for the high quality products.

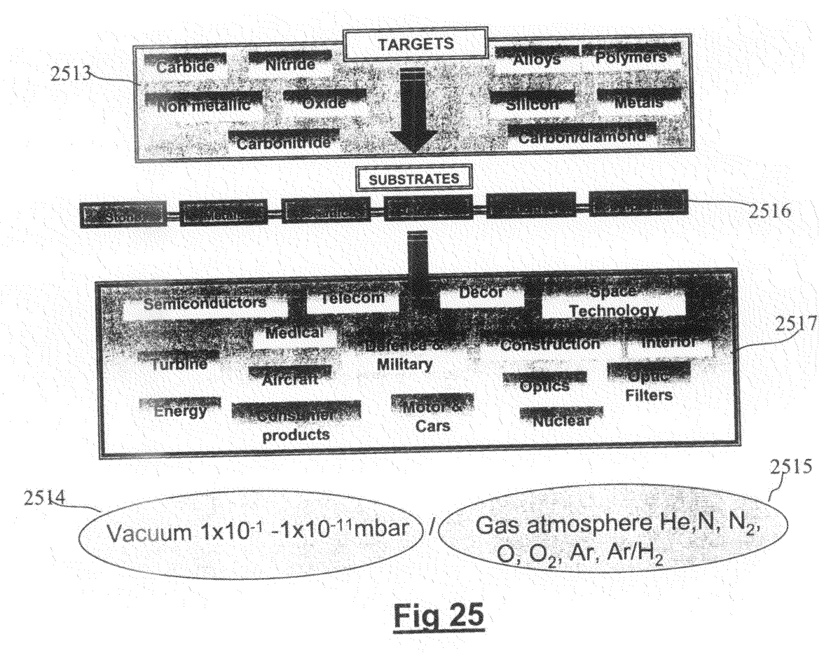

FIG. 19. demonstrates vaporization/ablation arrangements according to an embodiment of the invention comprising at least one arrangement from FIG. 18. According to an embodiment, such arrangement can be arranged to operate in vacuum, but according to another embodiment in a sheath gas atmosphere, in conditions of FIG. 25 for instance. The embodiment denoted by the capital A shows an embodiment for an arrangement for one side coating of the substrate, but also a two-sided coating application as a top view. The capital B embodiment illustrates a two-side coating by a suitable arrangement according to an embodiment of the invention. The capital C arrangement illustrates a two-side arrangement in which the coating can made in a serial way to the substrate sides that are opposite. The dots in units 1801 in A-type embodiments indicate a difference to the ones without the dot. The difference can be related to the position as in C, but also or optionally to the radiation source arrangement and/or target material as embodied in the various embodiments. The number of units 1801 and 5900 indicate that there can be several units or just one as embodied in FIG. 18, however, the number of the said units is not limited only to the shown. A skilled man in the art can see from the embodiments of the invention that the relative aspects of the units 5900 and 1801 fall into the scope of embodiments of the invention, as well as the positional aspects to situate said units in various positions in respect to the gradient of gravity.

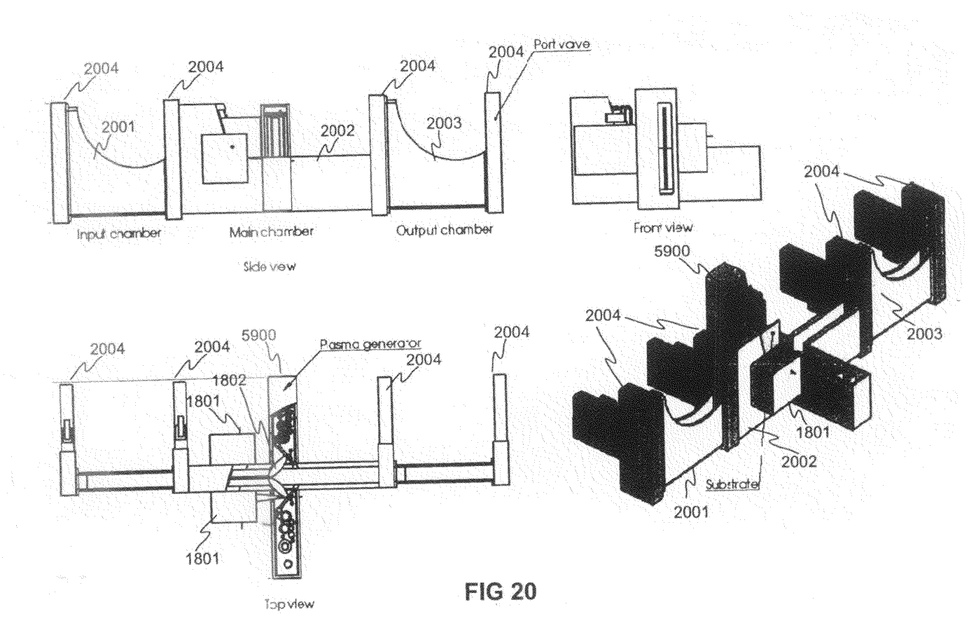

FIG. 20 illustrates a coating arrangement according to an embodiment of the invention. The arrangement comprises an input chamber 2001 for the substrate to be arranged and/or prepared for the coating. The substrate to be coated comes to the chamber via the port valve 2004, which can comprise means to recognize the substrate body to be coated for the measures and/or the material thereof. The coating can be made in one main chamber 2002 for a coating. The target material unit is referred also by the plasma generator in the figure for such embodiments in which the ablation is used for the coating. The plume 1802 for a substance of a target material is indicated, which plume is used to coat one side of the substrate. Additionally also another side of the substrate can be coated. In one embodiment, there are several units in same main chamber each arranged to prepare a coating of its own kind on to the substrate for a layered coating structure, but in another embodiment, there are several separate main chambers each for a target substance, to have a better separation/purity between the substances in layers. The output chamber 2003 is arranged and/or equipped to condition the substrate as coated for the output and ready to be used.

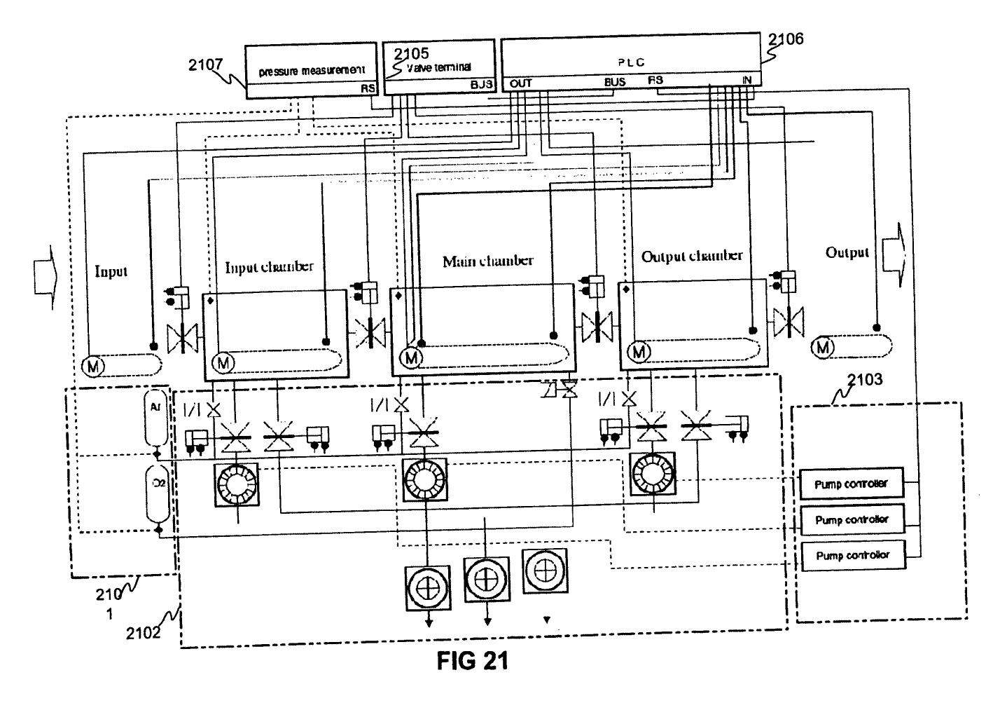

The FIG. 21 illustrates the arrangement embodied in the FIG. 20 as a schematic diagram. The embodiment in figure comprises an atmospheric means 2101 as demonstrated by the Ar and O₂ containers therein. The arrangement comprises a maintaining unit 2102 and the pump controllers 2103 arranged to control the pumps that can be parts of the maintaining unit, as indicated by the lines to each controller. The maintaining unit can comprise also the necessary valves that control the atmosphere and/or the vacuum in the chambers indicated in the figure. The figure demonstrates also the pressure measurement 2107 and the valve controlling 2105 by the valve terminal. The motors of the arrangement (M) can be controlled by the electromechanical PLC-unit 2106, as well as various transducers that are used to detect the position of the substrate and/or the phase of coating in the appropriate chamber. The whole system can be controlled by a microprocessor and a memory arranged to collect the information and to control the system progress in a pre-determined way. Also the pulse control and/or count as well as the count of the beam quality can be made by the microprocessor or several ones.

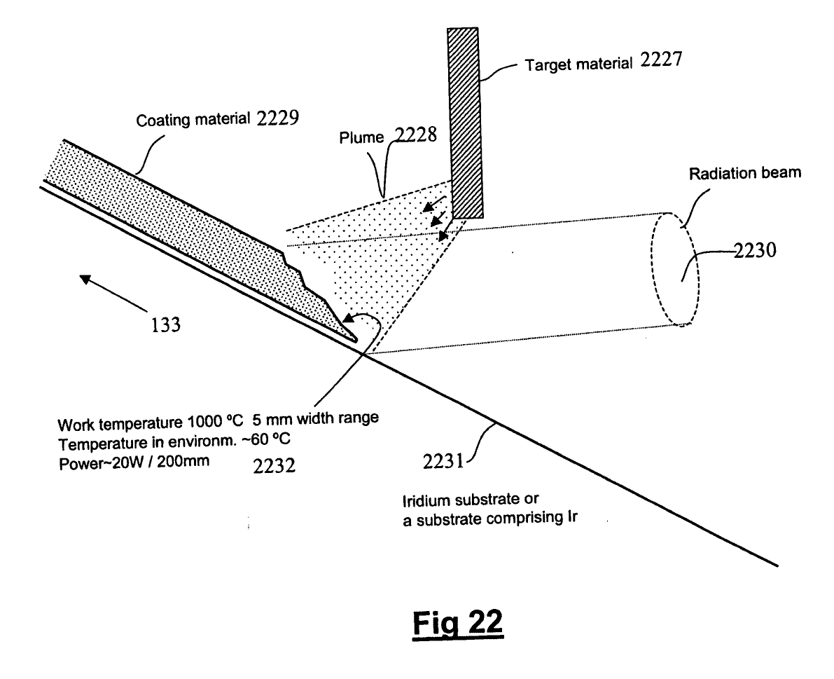

FIG. 22 illustrates making a coating and/or material piece 2229 by an ablation plume 2228 from the target material 2227. The laser beam 2230 can be used to heat and/or to condition the surface of the piece 2229 in order to promote the adhesion of the material from the plume to attached better to the zone 2232, while the substrate 2231 is pulled to the direction 2233, in order to have the process going on steady for a smooth material piece 2229.

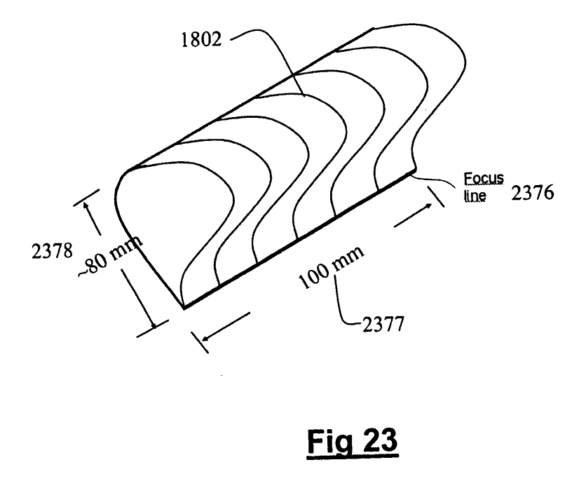

FIG. 23 illustrates a plume 1802 emitted from the target material, when an ablating beam sweeps the target material surface on 100 mm line 2377 on focus 2376. The plume has a dimension 23 of 80 mm as demonstrated in the figure. The plume can be for coating application according to an aspect of the invention to utilise the material from the plume as a second surface modifying beam, but as a material plume, which however originates to the first surface modifying beam influence on the target material.

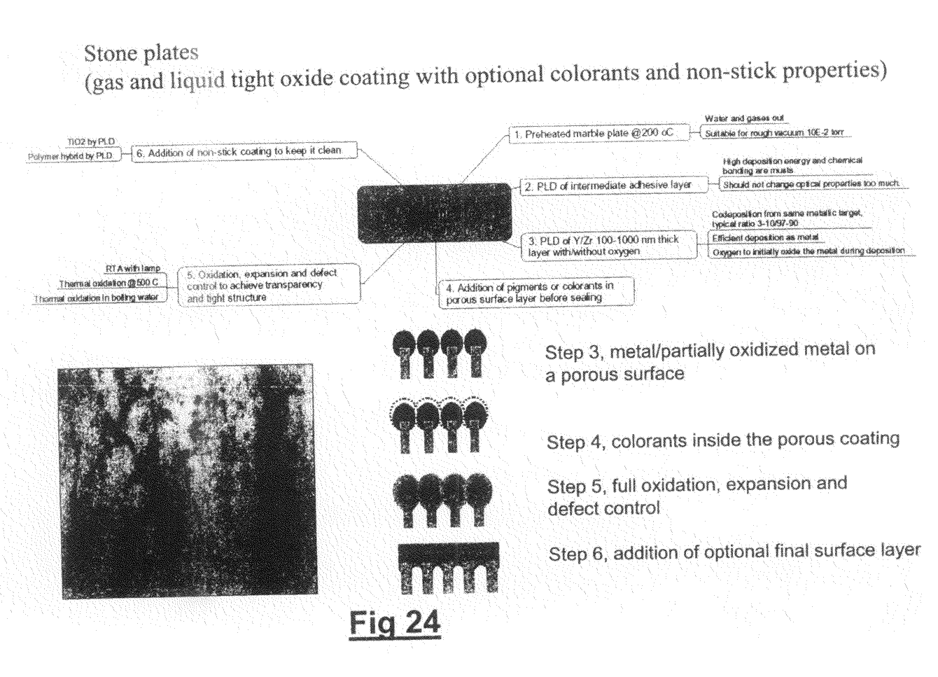

FIG. 24 illustrates a view to a display of a control unit display of a device-embodiment arranged to control a stone or stone-plate coating process, such as to produce marble or like of surfaces. The example indicates therein that marble plate is heated at 200° C. in approximately 1000 mbar pressure to remove gas and/or water from the surface that would be, as present in certain extent, have adverse effect to the coating. Within a PLD can be used for making an adhesive layer. So that necessary deposition energy and/or chemical bonding are assured, but without changing too much the optical properties. Depending on the desired purpose of the surface, a PLD is used to coat the surface by Y/Zr to thickness of 100-1000 nm, with or without oxygen. Also Al/Ti or Y/Al to thickness of 100-1000 nm, with or without oxygen. In an embodiment the co-deposition can be made from the same metallic target so that the ratio of the substances is 3-10/97-90, in the Y/Zr example. Additional pigments and/or colorants can be added, especially if the stone plate is porous, for filling to a desired degree before the sealing of the surface to tolerate gas and/or liquid. This is advantageous for example to marble to be protected against the air pollutants of gaseous, liquid and/or mixed form. In the method, also the defects and/or expansion are controlled by oxidation to achieve transparency/opacity and/or the structure tightness. In order to keep the surface clean a non-stick coating can be used. RTA can be made with a lamp. Thermal oxidation may be used in 500° C., and/or by boiling water in certain temperature and pressure. TiO2 by PLD or a polymer hybrid by a PLD can thus be produced. For instance, a marble appearance with a green stain and/or colour can be made.

FIG. 25 exemplary embodies Laser Deposition Applications in accordance of the invention and the aspects thereof. The figure shows various targets 2513 to be used as the target material. Ensemble of the examples of suitable target materials comprise carbides, nitrides, oxides, non-metallic compounds, carbo-nitride as well as alloys, polymers, silicon, and metals, but also carbon/diamond, to be used individually or in combination, however, not limiting the scope of the target material only to the mentioned.

FIG. 25 embody also several substrate 2516 examples, such as stone, metal, ceramics, glasses, plastics and composites however, not limiting the scope of the substrate material only to the mentioned.

FIG. 25 also embody substrate material utilisation 2517 as coated with target material for manufacturing tools, products and/or parts relating to the fields of semiconductors, component manufacturing, telecom, décor, space technology, turbines, medical, aircraft, weapons, defence and/or military, construction, interior, lining, energy, consumer products, motors, engines, cars, optics, nuclear and/or optical fibres. The manufacturing conditions 2514 in the example of FIG. 25 are indicated to occur for instance conditions of vacuum of 10⁻¹-10⁻¹¹ mbar, and/or in atmosphere 2515 comprising a gas such as for example He, N, N₂, O, O₂, Ar, Ar/H₂, or a combination thereof. Presence of other chemicals may be advantageous in some cases, like in one embodiment water. However, the fields are only examples and thus are not limiting the scope of the fields only to the mentioned.

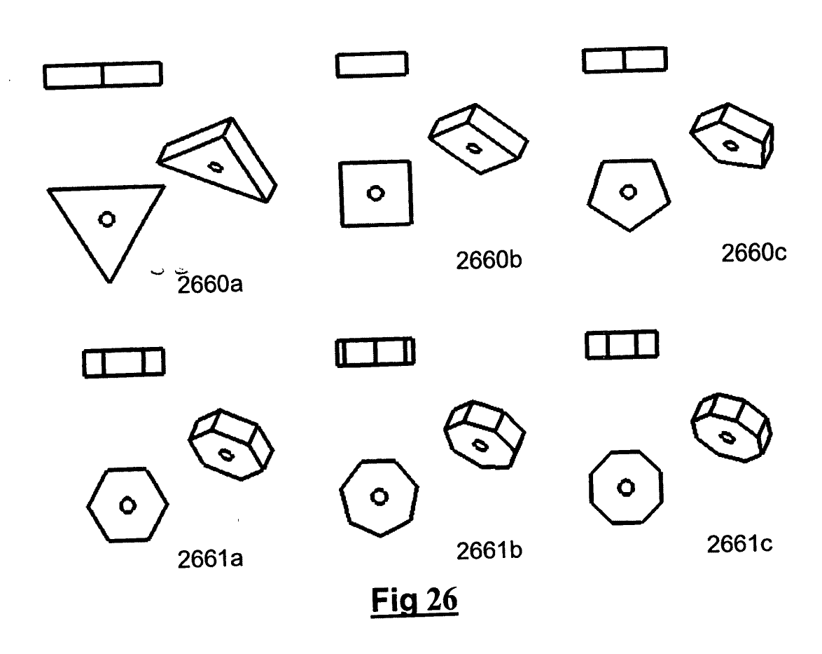

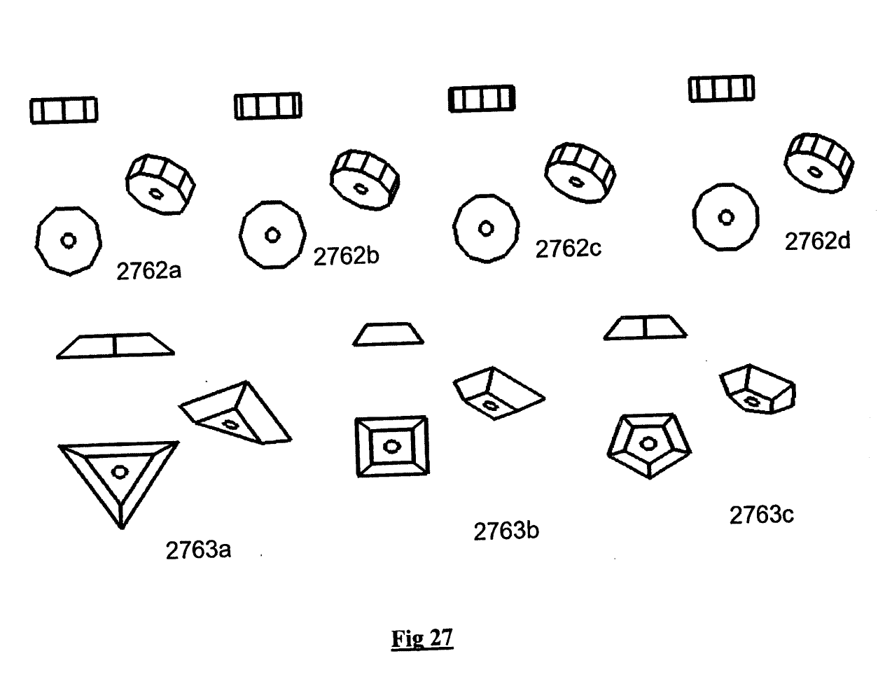

FIGS. 26-30 illustrate several embodiments of turbine scanner according to an embodiment of the invention. The rotation axis is indicated by a circle at the middle of the polygon in the FIGS. 26-30. Although there are shown polygons that approximate a circle as a cross-section, a skilled man in the art knows form the figures that the number of faces is not limited to the shown only. A skilled man also understands from the figures, that although the approximate circle cross-section shown, also such geometries that have a star-like structure are included as embodiments of the invention to the scope of the turbine scanner. Therein in the FIGS. 26-30, turbine scanner part 2660a is triangular, 2660b rectangular, and 2660c is pentagonal. Turbine scanner part 2661a is hexagonal, 2661b has 7 cones and faces, and 2661c has 8 cones and faces. Turbine scanner part 2762a has 9 cones and faces, 2762b has 10 cones and faces, 2763c has 11 cones and faces and 2762d has 12 cones and faces. The above-mentioned in FIG. 26 and are with 0° tilt between the rotation axis and the face. In FIG. 27 there are also tilted faces of the turbine scanner part, shown so that the scanner part has a pyramid or cut-pyramid structure. Such are triangular scanner part 2763a, rectangular scanner part 2763b and pentagonal scanner part 2763c in FIG. 27.

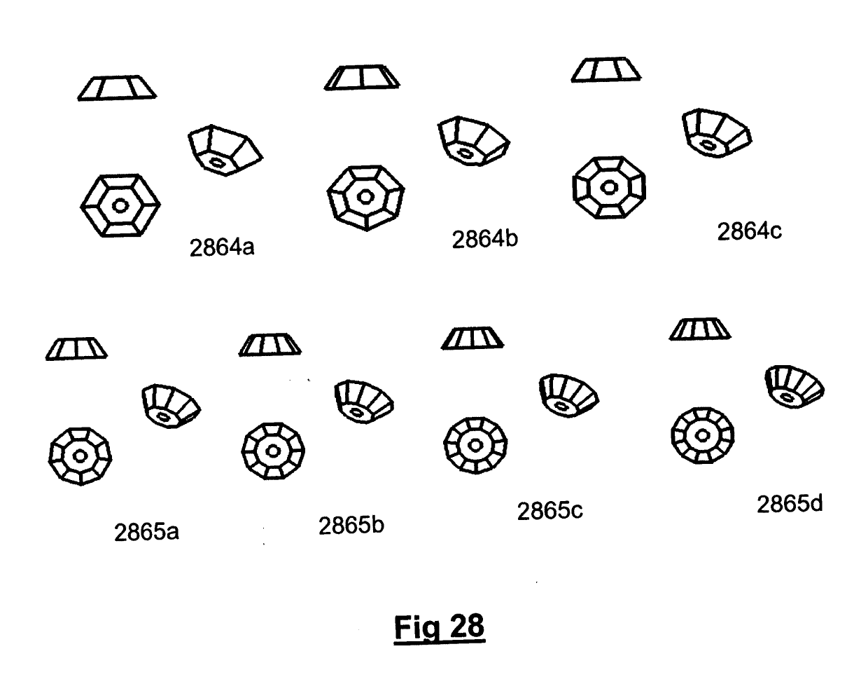

In FIG. 28 the scanner parts 2864a, 2864b, 2864c, 2865a, 2865b, 2865c and 2865d are shown so that the number of the faces and the cones there between is countable for the mentioned parts, each embodying a scanner rotating part with a tilt in a non-restrictive manner.

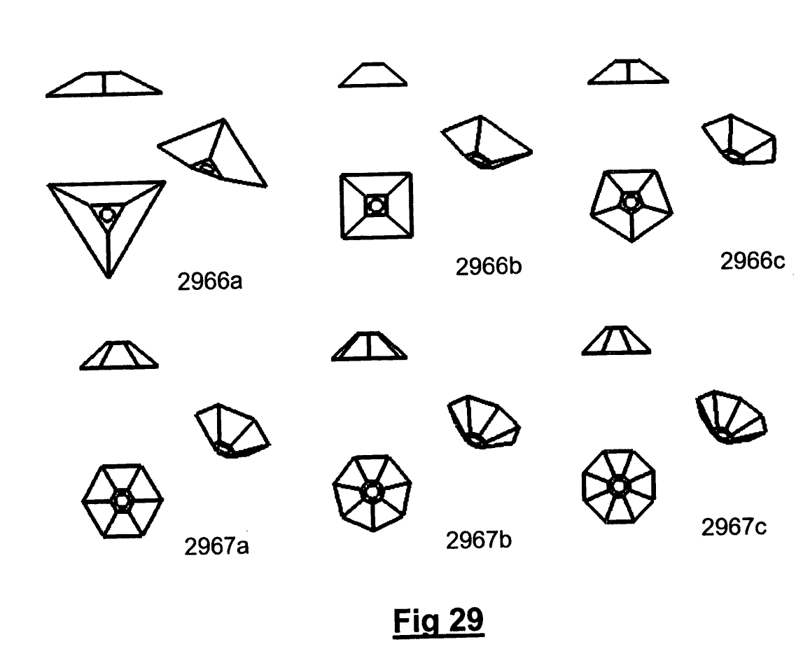

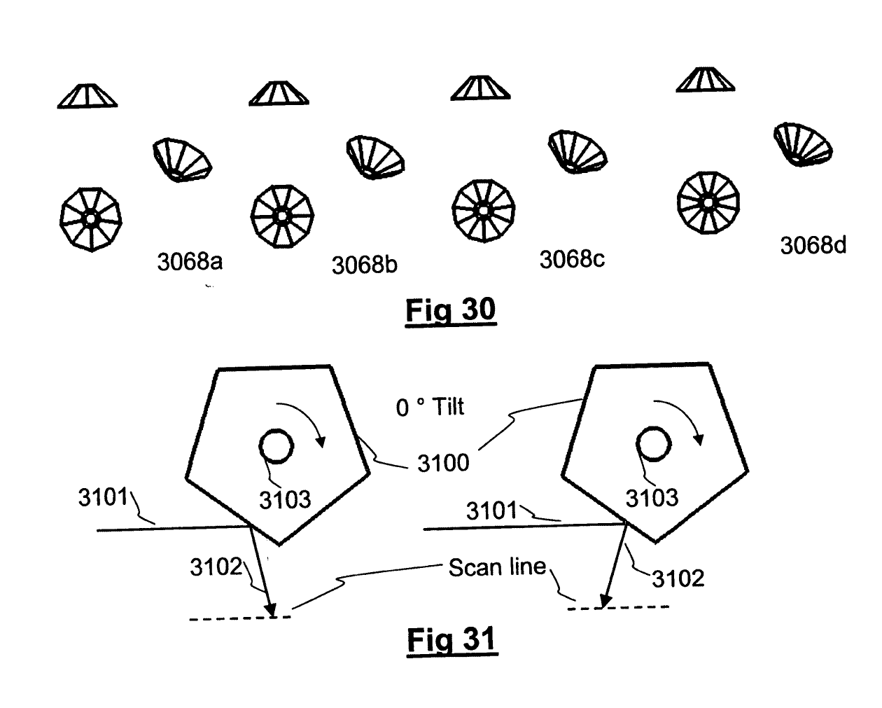

In FIGS. 29, 30 the turbine scanner parts 2996a, 2996b, 2966c, 2967a, 2967b and 2967c as well as 3068a, 3068b, 3068c and 3068d are shown so that the number of the faces and the cones there between the faces are countable for the mentioned parts, each embodying a scanner rotating part with a tilt in a non-restrictive manner.

FIG. 31 demonstrate an optical path during a scan and the scan line, which the incoming radiation beam 3101 draws after the reflection from the scanner 3100 face as a scanned beam 3102 onto a target, during a rotation of the scanner face around the axis 3103. The incident 3103 and reflected 3102 beams are in the same plane perpendicular to the axis 3103 in this embodiment example, whose faces have tilt of 0°. The reflection plane defined by the incident and reflected beam parts is however not necessarily limited only to perpendicular angle to the axis 3103.

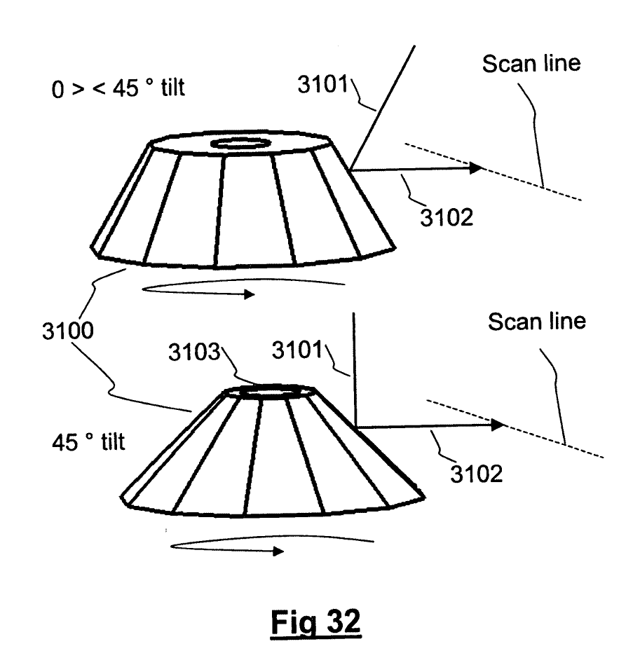

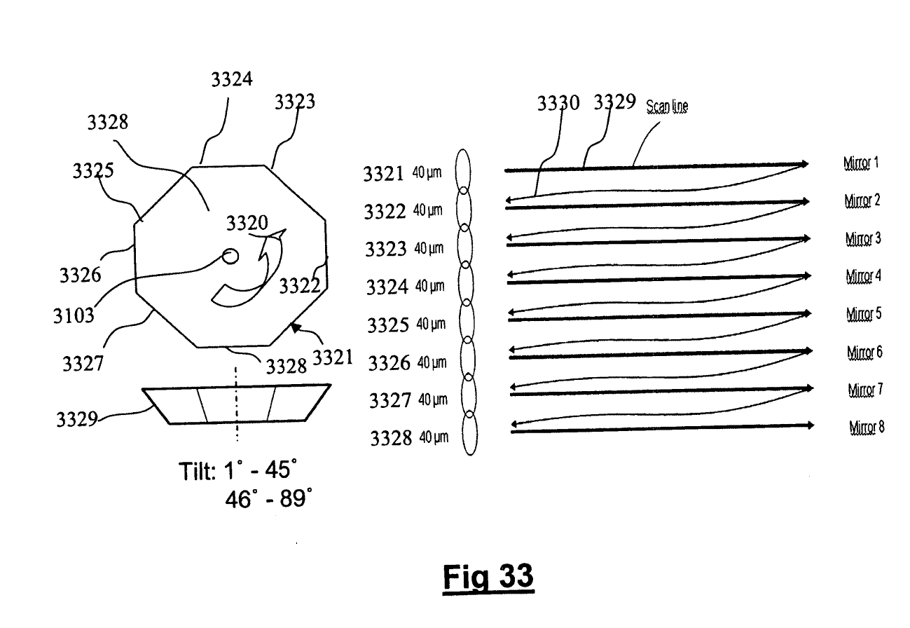

FIG. 32 demonstrate another optical path during a scan and the scan line, which the incoming radiation beam 3101 draws after the reflection from the scanner 3100 face as a scanned beam 3102 onto a target during a rotation of the face around the axis 3103. The incident 3103 and reflected 3102 beams are in the same plane perpendicular to the axis 3103 in this embodiment example. The tilt in one embodiment which is shown as an example, is less than 45° and in another exactly 45° or greater. As the figure demonstrates via the faces of the scanners, the scanner as such is not limited to a particular shown embodiment. Also variable tilt of the individual face belongs to scope of an embodiment concerning a turbine scanner. Another embodiment of the invention comprises a turbine scanner that has mirror faces, which have different tilts from a face to another. In an embodiment each face can be replaceable mirror face, or in another embodiment a solid mirror face. In one embodiment the turbine scanner can comprise the faces so that they form a star-shaped structure, arranged to deflect the incoming radiation. In one embodiment of the invention the mirrors are plane arranged to produce a smooth scan line, and/or focus on the target. In certain embodiments, in which the focus were advantageous to vary from a location of a scan line to another in effective depth direction on the target, the coating properties on the substrate and/or the plume should be a non constant type, a curved faced scanner can be used. In one embodiment the curvature can be the same for all faces. In another embodiment there are differently curved mirrors. In one embodiment the mirrors are curved in a concave manner, but in another embodiment to convex manner. In one embodiment the mirrors are curved only in one direction, for example in a direction defined by the segment as a plane perpendicular to the axis of rotation. In another embodiment the mirrors are curved in another direction in respect to the axis. In a further embodiment a mirror has two curvatures in different directions.

In certain embodiments of prismatic, paddle-wheel type and/or star shaped turbine scanners each mirror may have a sub-structure, so that the beam can be directed to at least two separate scan lines during a scan of the mirror movement from the first edge to the last edge of the very mirror. This can be embodied by such embodiments that comprise several planes having an angle to the neighbour plane.

A turbine scanner according to an embodiment of the invention can comprise a first mirror which is arranged to change direction of radiation beam in a radiation path and a second mirror for the same purpose, but arranged to cool while said first mirror is about to change the direction of the coming radiation in the radiation path. A turbine scanner according to an embodiment of the invention comprises exactly or essentially similar mirrors as an ensemble of mirrors, having at least one mirror, later referred as a first mirror. A turbine scanner according to an embodiment of the invention comprises exactly or essentially similar mirrors as an ensemble of mirrors, having at least one mirror, later referred as a second mirror. The first and second mirror are not necessary identical in an embodiment of the invention. A turbine scanner according to an embodiment of the invention is arranged to be rotatable around an axis, preferably through the symmetry axis of the turbine scanner having a form of polygon or comprising a paddle wheel structure. Because of very large rotation speed in duty expected for an embodiment of the invention, non-symmetric axis may not tolerate the torsion and/or wobbling around the non-symmetric axis in an embodiment. However, although if the material in the bearing or the turbine scanner itself were made sufficiently hard and/or sticky/elastic material, such a non-symmetric rotation may be used for modifying the scan duration, its length at the target, pitch of the successive scans, radiation beam geometry, power at the target, and/or the focus of the beam. Consequently in embodiment, which comprises coating of a substrate, the plume form and/or structure can be utilised.

According to an embodiment of the invention the turbine scanner is embodied as a polygon, which comprises an ensemble of mirrors arranged to form a polygon with faces of which said first and second mirrors are. In an embodiment, said first mirrors have a different tilt angle as said second mirrors in respect to the central axis of polygon. Because of the very high in-duty-speed of rotation, the turbine scanner according to an embodiment of the invention is arranged to rotate by means of a fluid bearing. The fluid can be liquid, however, the drag force resisting the movement may be large, so at least the surface of the bearing may be advantageously covered by gas. One suitable gas is air for an air bearing to be used within the turbine scanner, but in one embodiment also other gases and/or liquids may be used in various forms to minimize the friction-related forces in-duty of the scanner. In an embodiment Helium is used, in such a variant of the embodiment at the-near-zero point temperatures.

It is advantageous to cool the mirrors while off duty by a fluid. The cooling can be arranged by feeding a cooling fluid on the mirror surface, but preferably at the opposite side of the mirror to avoid any deposit slag from the fluid to the surface. This is advantageous if reactions of the mirror surface and the coolant are to minimized also in long term. In an embodiment of the invention, the turbine scanner has an inner-side structure that operates as a pump for a fluid to be used for the cooling. In such an embodiment the turbine scanner piece is made form warm conducting material. According to an embodiment of the invention, the material is metal. According to an embodiment of the invention, the material has diamond structure. When using mechanical bearings instead of air or magnet field based bearings, the fluid can be different than at the mirror surface. Consequently in such embodiments, liquid can be used for the cooling, when the feed is arranged via the hollow space in the axis for instance. According to an embodiment, the cooling is mad by liquefied gas, which is sprayed on the mirror as an aerosol with suitably fine particle size, which particles evaporate and yield a thermal flux that maintains the cooling of the off duty mirrors. In one embodiment, carbon dioxide can be used for cooling of the mirror during a sublimation into a gaseous phase from a mirror surface.

According to an embodiment of the invention the at least one of the first mirrors and/or second mirrors are made of diamond. The skilled man in the art knows very well from the embodiments, that the first and second mirrors are only examples of using different kinds of mirrors in the turbine scanner, and thus a scanner that has more than two ensembles of mirrors at the polygon shape belong to the scope of the embodiment of the invention directed to the turbine scanner thereof.

According to an embodiment of the invention the turbine scanner according to the invention is arranged to form a paddle wheel so that the paddles thereof are mirrors of the turbine scanner, arranged to be rotatable along a circular path around the central axis of said paddle wheel. In a variant of the embodiment each of said mirrors in said paddle wheel are arranged to a sharp angle with a tangent of said circular path. Irrespective has the turbine scanner embodied as such as a polygon or paddle wheel, the mirrors can be arranged so that first mirrors have a tilt angle with said axis of said paddle wheel. According to an embodiment of the invention, the turbine scanner comprises an ensemble of mirrors with a first tilt angle and mirrors with a second tilt angle, however, without any intention to limit the number of the ensembles of different sub-ensembles with such a specific tilt angle. According to an embodiment of the invention a tilt angle is adjustable during the duty cycle to have an extra freedom to the beam at the path. According to an embodiment of the invention, a mirror itself and/or a part of it can be replaced by another one so that it is not necessary to replace the whole scanner itself, for an ordinary maintenance.

According to an embodiment of the invention the mirror surface itself comprises the target material. According to an embodiment of the invention the mirror may be not a mirror in conventional sense, but it can be replaced by a porous material, that allows a diffusion-like feed through from the inner parts of the polygon to the outer surface of the turbine scanner for a gas and/or liquid-like fluid. An advantage of such an embodiment is that the simple structure of the target feed for certain kind of target materials to be ablated, provided that the surface itself with the pores tolerate the radiation beam and the plume direction has been arranged, say, by electric fields for instance to the substrate.

A turbine scanner according to an embodiment of the invention comprises a mirror that has a diamond surface. The diamond structure may be not only at the surface in an embodiment of the invention, but the whole mirror may be made of the diamond. According to a variant of an embodiment of the invention the whole turbine scanner is made of diamond. According to an embodiment of the invention diamond bodies can be made according to the various aspect of the invention. According to an embodiment of the invention the turbine scanner is dimensioned to the same scale as the beam to be deflected. In such an embodiment of the invention the heat transfer and sufficient cooling of the off duty mirrors actually define the lower boarder to the scanner size, which can be down to the millimetre scale and even further down, provided that the material tolerate the radiation beam at the radiation path to be deflected and the consequent heat. An advantage of using small-scale turbine scanners is the lightweight and the rotation speed may be increased as high as the material can tolerate as a whole without breaking by the forces relating to the rotation as such. According to an embodiment of the invention, the turbine scanner rotor is made of aero-gel for a lightweight structure. According to an embodiment of the invention such an aero-gel piece of said rotor is at least coated on the mirror surfaces. According to an embodiment of the invention diamond plasma is deposited into the aero-gel structure to yield a thermal flux from one surface to another across the aero-gel material for facilitating the cooling of the rotor.

FIG. 33 illustrates a prismatic low-faced turbine scanner 3321, but especially the rotor part of it 3321. The part 3321 can be a conventional turbine scanner part, but also a part according to an improved embodiment of the invention. In the example of the figure, the part 3321 has faces 3322, 3323, 3324, 3325, 3326, 3327 and 3328. The arrow 3320 illustrates the rotation of the part 3321 around the axis 3103. The faces are mirrors, each of which in-duty, arranged by its own turn, to deflect the incoming radiation beam via the radiation path and to cool when the mirror is off-duty. Tilt angles of the faces are shown for various embodiments. The FIG. 33 illustrate one revolution of the turbine scanner part in time scale from the first mirror, mirror 1, to the last mirror, mirror 8. The scan line 3329 is indicated on a target, which can be any target material according to an embodiment of the invention, but also any other target material with a sufficient structure to cold ablation. The return of the beam is indicated by the line 3330. The mirrors are indicated by the apparent reference number. Although 40-μm-scan line has been demonstrated as an example, embodiments of the invention are not limited only to shown beam size. The location of the scan line on the target material may be the same in one embodiment for at least two successive scans, but the scan line for two successive scans can be different in another embodiment, if for example, the material is likely to form fragments even in cold-work based on ablation. The number of faces is not limited to the 8, which is only an example in the figure. Faces can be of tens or even hundreds in number, however, influencing to the scan line length.

In one embodiment of the invention number of different scan lines at the target surface can be achieved by variation of the tilt from face to the next face of the turbine scanner, or in another embodiment by changing the face tilt of at least one mirror or several mirrors.

The turbine scanner has an advantage that the beam won't stop one location at the target and thus the yield is rapid and homogenous during a scan resulting a homogenous plume from the target.

The size of the turbine scanner is freely scalable for a skilled man in the art who has read the application text. The embodiments comprise variations of microscopic scaled to macroscopic scale so that in the macroscopic scale according to one embodiment the diameter is about 12 cm and height 5 cm. The distinction of low-faced turbine scanner from a high face turbine scanner can be made by the measures of the height of the mirror in an axial direction in relation to the width of the mirror in a perpendicular direction of the axial direction. If the height and width are essentially the same, or exactly the same such an intermediate embodiment is included to either low- or high-faced embodiment according to the ratio so that if the height is smaller than the width, it is low-faced but if the height is larger than the width it is high-faced.

It is advantageous to use turbine scanner in the radiation path for such systems in which use pico-second laser systems whose repetition rate is above 4 MHz, advantageously over 20 MHz and/or the pulse energy is above 1.5 μJ.

It is advantageous to control the radiation power at the target. Thus, even each pulse can be evaluated and the knowledge on the departures of the pulse/radiation properties from pre-defined values can be used in a feed-back loop for controlling the radiation beam focus, the ablation of target material, substrate coating, and/or the plume formation.

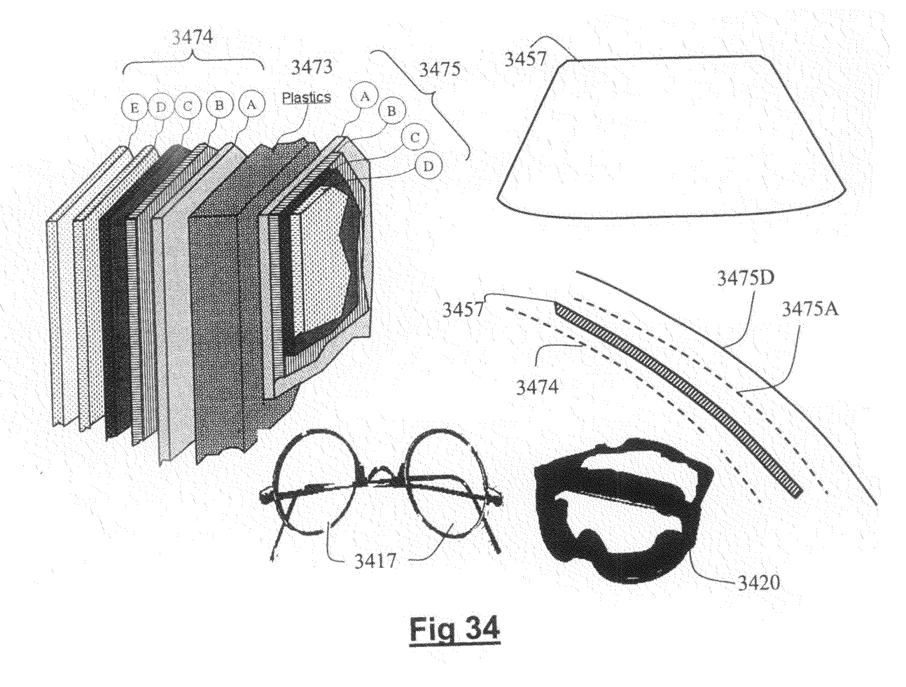

FIG. 34 illustrates a layered structure on a substrate. The substrate 3473 can be any substrate, but the FIG. 34 uses plastics as an example of the material. The layers are indicated at one side by the letters A, B, C, D, E for the layer structure at one side of the substrate 3473. Although there is a similar layered structure 3475 on the other side of the substrate, the number of individual layers is not limited only to the indicated, nor the number of coated sides of the substrate, which can be coated only on one side, or several sides, including possible cavities or inner sides that can act as substrate. The item 3457 illustrates a vehicle's windscreen, but that can be as well a window and/or a winds screen of a boat, ship submarine, motorcycle, aeroplane, or a window of a vehicle or of a building. The substrate can be plastics, glass or a composite. The substrate 3475 can be coated on one surface by a first coating, but optionally or in addition on another surface by a second coating. The substrate can be coated by a third coating, however without limitation to the number of the coating layers at a side. One coating can be solar cell coating, i.e. coating with suitable layers arranged to form a solar cell, which could be transparent according to one embodiment for a range in visible light. The word “glass” refers to window glass of various windows and/or screens made of glass, plastic, a composite and/or a combination of the just mentioned. Some layers are indicated as an example for a layered windscreen. The layers can be in a laminated glass structure. In addition, also bodies of the above-mentioned objects can be coated, including civil used objects as well as military related vehicle bodies. In military applications also stealth related coatings can be made in suitable part. Also sunglasses, spectacles 3417 and/or shields and visors 3420 of various kinds can be coated.

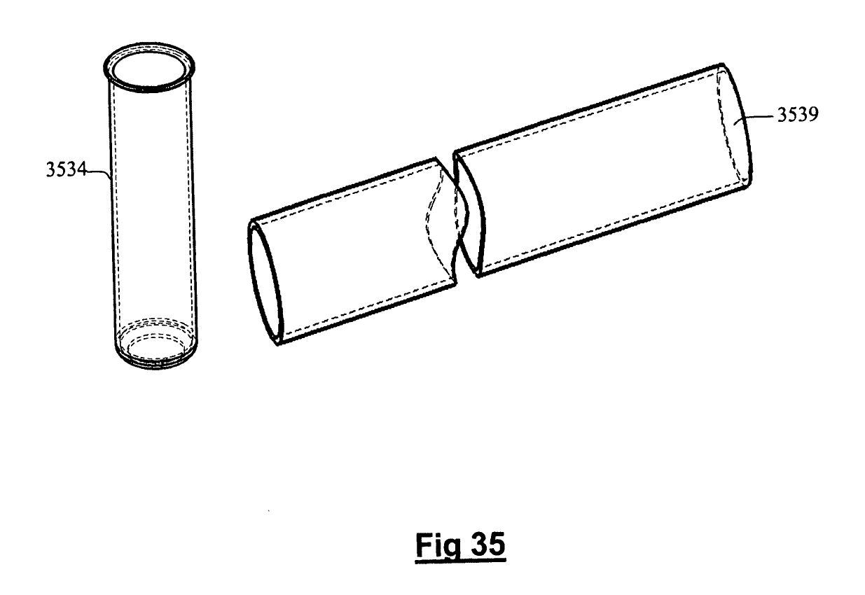

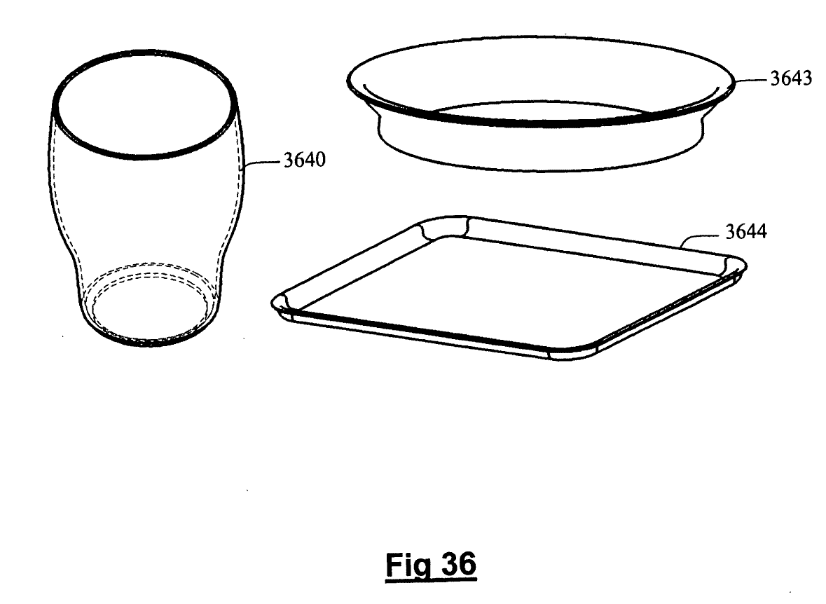

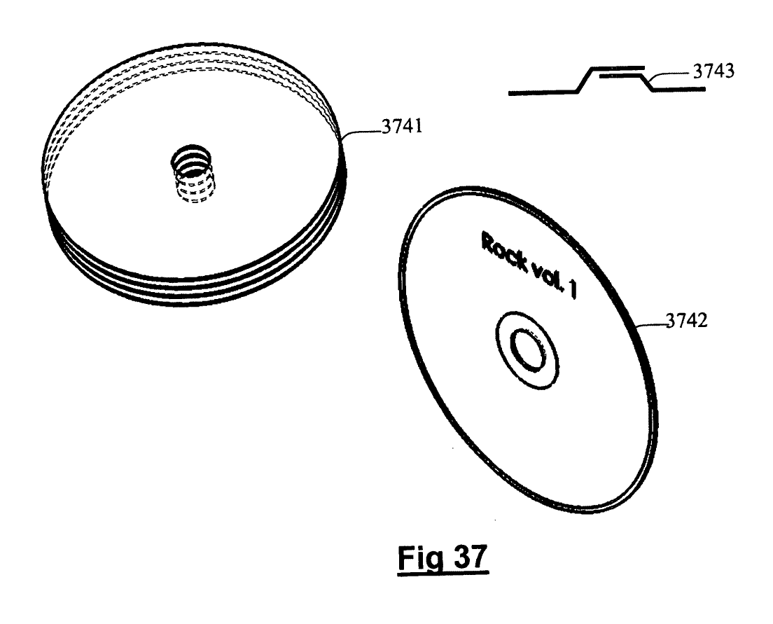

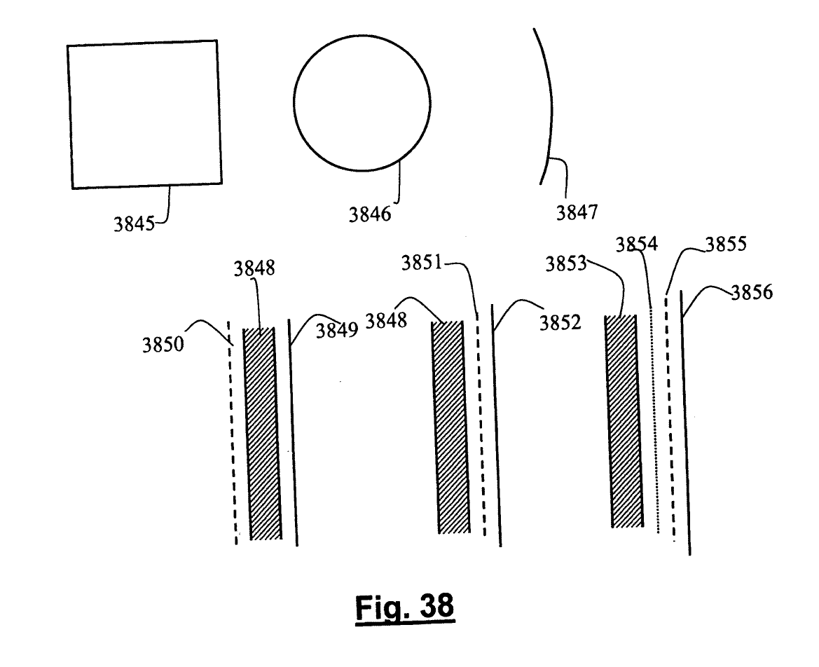

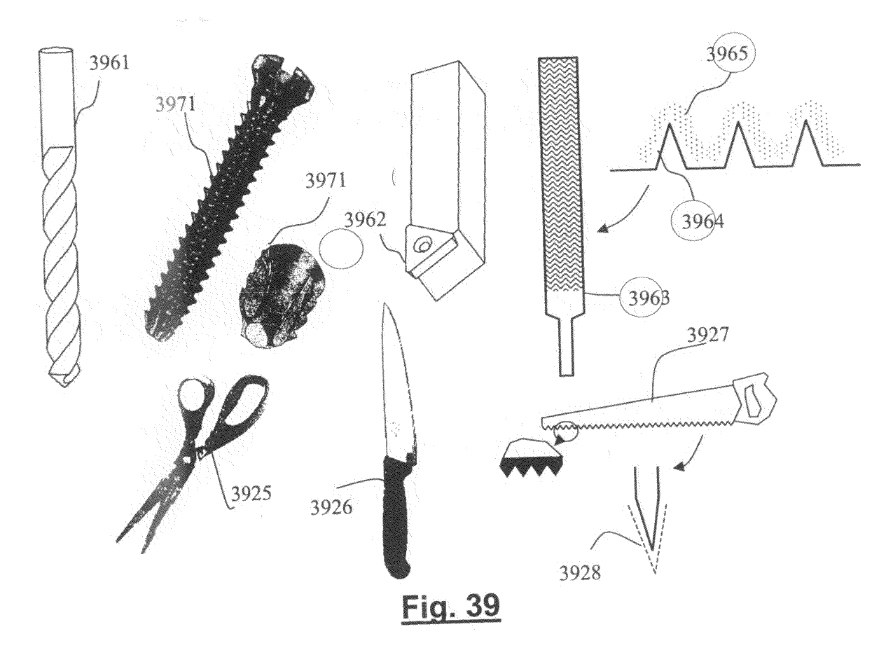

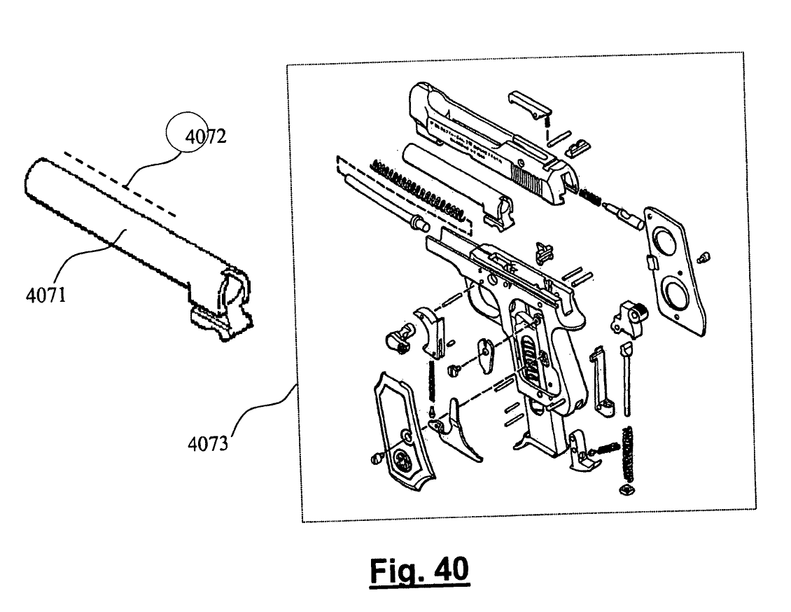

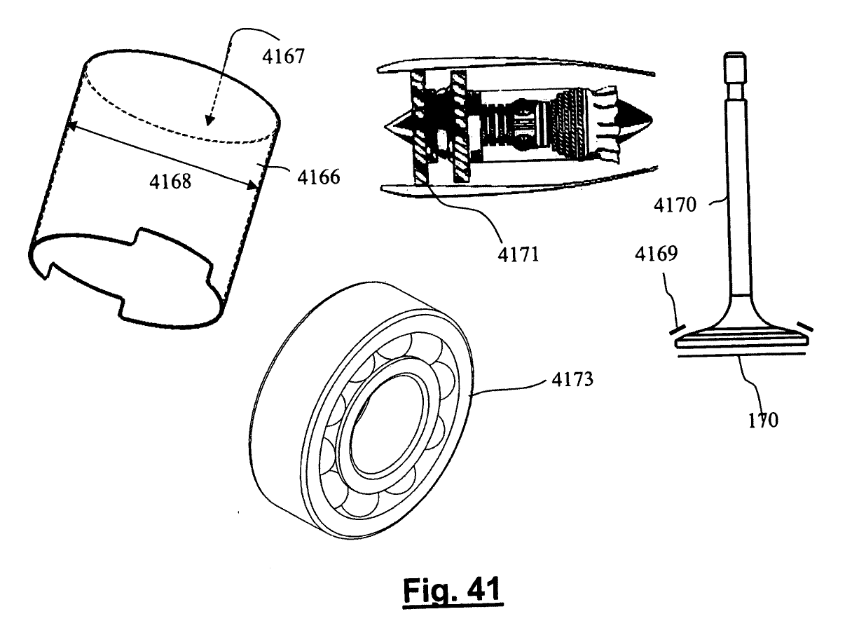

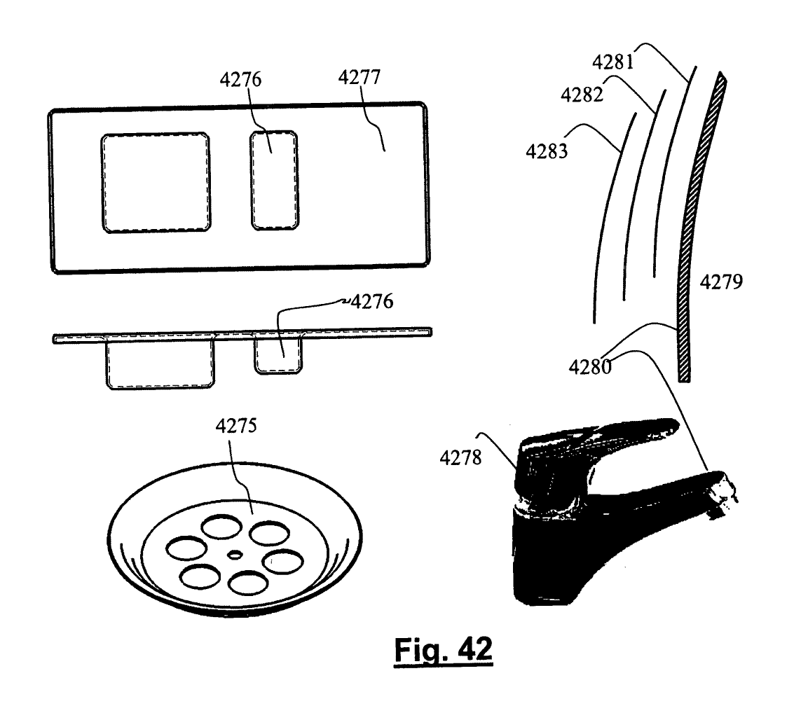

FIGS. 35-52 illustrate examples on several kind of coatings to be made in accordance of aspects of the embodied invention. The coatings and/or carvings can be made according to the method and/or arrangement according to the embodiment of the invention. The processed surfaces can be inner and/or outer surfaces of the bodies.

FIG. 35 illustrates tubular structures 3534, 3539 to be coated according to an embodiment of the invention. Tube can be open-ended 3539 or sealed at least one end one 3534, depending the tube and/or the intention to be used. The tube can be coated inside as shown in the figure and/or also outside, according to the conditions appropriate therein.

The tube can be a part of a material transfer line, such as for instance, water pipe, sewer, gas pipe, oil pipe and/or a connector thereof. The wear-out and/or corrosion exposed parts of the tube can be coated. For instance in heat exchange surfaces the wear and/or corrosion resistant materials can extend the in-duty time for the parts as coated. Suitable materials can comprise carbo-nitride and/or diamond as coated on the surface according to an embodiment of the invention.

FIG. 36 demonstrates coatings of several kinds of vessels. Any glass 3640, plate 3643, saucer 3644 can be coated by using embodiments of the invention. Although the examples relate to certain shape, geometry and/or degree of transparency, the coating examples embodies also vessels and/or jars to be used in domestic purposes, in chemical industry, laboratory related purposes, medical equipments as well as reactors of different kinds in several industries. The material of the vessel as such as uncoated is not limited to any special, but metal, ceramic, plastics as well as glass, or a suitable composition thereof can be used for the substrate in the vessel form.

FIG. 37 demonstrate coatings to be used to coat hard disk parts 3741 of a computer, embodied for optical and/or magnetic saving, DVD, and/or CD-disks 3742, or other media that can be used to carry information, pictures and/or music in any readable form. The reading head of a hard disk can be manufactured and/or have coated in suitable part according to embodiments of the invention.

In the same figure, also the part 3743 demonstrates any electro-mechanical component to be coated at least on the mechanical part that is exposed to wear. Thus, any electrical contactors can be thus provided with a surface that improves the wear resistance, with a suitable electric resistance gained by the substrate material selection in combination with the coating material as doped in the necessary part for the particular purpose. Also thin-film wires can be provided on the substrate, and also with suitable magnetic material on a substrate to be used as a case for a protectable object, an RF-protection can be provided for said object with a coating according to an embodiment of the invention. The components can be of normal electronical component size, but however, they can be so called micro-mechanical elements, in microscopic scale, nano-scale devices or intermediately sized objects of mechanical use and/or electrical components.

FIG. 38 illustrates utilisation of embodiments of the invention for coating substrates to be used for windows and/or mirrors. In the figure, the mirror 3845 comprises a glass layer 3848, behind of which there can be silver, aluminium, or other suitable substance to form the reflective layer. The layer can be self-cleaning layer in one embodiment, polarizing layer, and/or IR-reflective in other embodiments. The layer 3849 at the other surface of the glass layer 3848, can be embodied as a layer structure 3849 suitable for a photo-catalytic reactions and/or as solar-cell-comprising-layer. Such layer can be transparent at a wavelength range of visible light, but arranged to transform other radiation to electricity. The body 3846 can be as a substrate made of metal or other material according to FIG. 25. The body can be coated from one side by a first coating 3851 but also by a second coating 3852 on the other side. The body could be a lens 3847, convex, concave or a combined lens, a spectacle lens, to be coated with a suitable coating. 3854, 3855, 3856 on the lens material 3853.

FIG. 39 illustrates use of embodiments of the invention to coat tools and/or parts thereof. The bore 3961 is just an example in the figure, as well as the edge or blade 3962. They symbolize in addition to bore or drilling means also parts of lathes or any kind of a turning machines. The knife 3926 symbolizes use of coating as various cutting means of various kinds, from a kitchen blade to industrial blades in butcher's and/or bakery use, as manually utilizable or as a machine part. Also blades of scissors 3925 can be coated. Scissor blades are not limited to the FIG. 39 exemplifying a pair of domestic scissors, but also garden scissors are included in to the scope of use for coating as well as scissors like cutting means. The saw 3927 is just an example of serrated blades and/or saws, without any intention to limit the scope only to the indicated form of linear type of serration. The whole saw blade 3927 can be coated, or just a part of it. Also rotating saws can be coated. Saws can be hand operated, motor operated, and/or parts of an industrial machine. Also any handle of any tool can be coated. The item 3963 illustrates file to be coated. Individual spike and/or ridge 3964 is indicated in the figure as a magnification taken from the file, as well as the coating on the file surface 3965 at the ridge. The item 3971 is not a tool as such, but related to bore, so the attachment means with several kinds of spiral structure are also included. Although the item 3971 as indicated in the figure has a screw structure, also nails of various kinds of studs and rivets are included to the coatables by using embodiments of the invention.

In addition to the blades aimed for cutting, also spoons and/or forks as well any dining means can be coated for the wear resistance, to improve cutting performance and/or the appearance to give a certain artistic look.

A tool to be coated, although may be not directly indicated in the figure, according to one embodiment, a hitting means as a hammer or axe, wedge, chain saw or a rotating cutting circle, or rotating file, brush or a cloth made of coated fibre. Although file has been indicate, also sand papers or various means of emery or the kind as well as any grinding means, grinding wheels and/or linearly movable grinders are included into the scope of an embodiment of the invention to coat.

The attachment means in the figure can be normal hard ware store sold products but coated according to an embodiment of the invention. The coating can be used to increase or decrease the corrosion resistance in the environment. In building and engineering environments, generally taken, corrosion as such is not a desired phenomena and thus to be prevented with a suitable surface material protecting the means, but in case of fixing a broken bone there can be situations, in which the attachment means is desired to join into the bone structure without further edges as an example of an attachment means made of material that is to be corroded in sense to join the surroundings. Lower friction, less damage to bone, less failures, no corrosion in the critical parts of the attachment means that would weaken the structure weaker than the surrounding material, and where necessary, easy to remove. The attachment means can be also coated with lubrication-provider type substances to ease the attachment itself.

Also medical tools for surgery, for instance, operate better as coated according to an embodiment, the knives having a better cut-pattern, when for example diamond-coated with an embodiment of the invention. The smooth surface of diamond coating promotes also the hygienic aspects of the tools. So, the forceps, scissors, scalpels, supports as well as artificial parts as joints, for instance, as coated by a diamond coating according to an embodiment, tolerate the use, but also increase the hygiene in surgeries. When a screw for attaching a bone is coated by diamond, the irritation of the tissues of the patient can be minimized. The friction is also lower when mounting a bone with a screw, and thus the potential damages to the bone can be possibly avoided at least in some extent, if not totally.

Other attachment means suitable for the coating are various supports and/or iron angles. The attachment means can be also very specific kind of structures used in spacecrafts, aeroplanes, and/or ships as well as in sub-marines, including also military related attachment means.

FIG. 40 illustrated coated parts of guns of various kinds. Although only barrel 4071 of a pistol is shown having an outer coating 4072, also any other part of the pistol or all the other parts 4073 in suitable part can be coated. The barrel or several barrels of a gun can be coated, optionally or in addition also inside. The smoothness of the barrel decreases the friction and thus heat formation of the barrel, which thus may be minimized. If the ammunition as well has a smooth coating, the matching there between the barrel and ammunition may be improved, which improves the hitting accuracy by the gun provided with such a barrel. This is useful also to improve resistance to wear away the barrel during the use of it, and thus increase the lifetime of it.

The decrease of the friction is useful in military related, and/or other machine guns, appearing as decreased need for cooling so making also portable guns lighter to handle, but also in the automatic weapons in the loading system performance. Although hand guns for civil related as well as military related pistols and rifles are included to the scope of the coating of the barrels and/or other parts, also cannons of various kinds are included. Also revolvers, or parts thereof as well as those of one- or two-shot shotguns are included. Also bazookas, the parts thereof as well as rocket launchers are included as well as the parts thereof to be coated in suitable part. Also the ammunition, the shells, grenades and/or bullets as well as their parts can be coated against corrosion, but also by a lubricant that protects the barrel and/or decreases further the friction, where not desired.

FIG. 41 illustrates use of an embodiment of the invention to coat a motor part. The motor can be actually any kind of combustion related engine. The figure shows a cylinder 4166 surface, which can be a surface 4168 inside, outside and/or other combustion space of the cylinder. Also the piston meant to move in the cylinder can be coated. Any Otto-motors, steam engines, as well as wankel-motor-parts can be coated. Also jet or rocket motors or the parts thereof can be coated. Turbos or turbines can be also coated in suitable part to increase the resistance against the wear out in the operation environment. For example, diamond coating can increase smoothness and thus decrease the friction, and the wear out time can be extended also by using for instance carbo-nitride at the friction surfaces.

Turbine parts 4168 are demonstrated in FIG. 41. Other motor parts are demonstrated by the valve to be coated in suitable part. Also cams, camshafts, crankshafts, chains, gear wheels, spiral and/or conical gear-parts can be coated against the wear out and/or corrosion. The figure shows a ball bearing structure 4173 to be coated by using an embodiment of the invention at least partly if not all the parts. However, also other kind of bearings are also included independently on the shape of the bearing-surface and/or its curvature, so comprising bearings from nano-scaled embodiments up to the embodiments to coat largest bearings, such as those of nuclear power plant generators. Thus all kinds of bearings comprising spherical, cylindrical and/or conical bearings are included to the coatable bearings.

According to an embodiment, diamond coating can be arranged to conduct warmth so that the bearing won't get heated as a usual non-coated bearing. It is also possible to manufacture the whole bearing part from diamond. Even the macroscopic bearing surfaces can be made smooth easily according to an embodiment to meet nano-scale precision of ±30 nm, advantageously ±10 nm, and more advantageously ±3 nm, or within even a smaller range in an embodiment.

Such a coating also avoids micron sized unnecessary and/or harmful particle fragments larger than 70 nm on the bearing surface. In an embodiment, no particles at all are formed on the surface of the bearing. According to an embodiment of the invention any bearing part could be made by the 3D-printing according to an embodiment of the invention.

FIG. 42 illustrates water-piping related coatings to be made according to an embodiment of the invention. The bottom sieve 4275 illustrates sewer related piping as well as other parts relating to the waste water management related parts. The desk 4277 demonstrates the coating to any metal desk, or another desk. The sink of a kitchen desk, domestic, medical and/or industrial desk can be coated as demonstrated by the parts 4277 and/or 4276. The sieve 4275 can be part of such a bowl or sink 4276. The tap 4278 demonstrates coating of a tap or another kind of kitchen/bathroom related water valve, but also any kind of a tap used in industry, medical, and/or foodstuff related applications. So, the tap and/or the sink can be made of metal plastic or ceramics in suitable part as substrate 4280, to be coated by laser ablation generated copper, gold, chrome, or an alloy, and/or finalized with laser ablation. Electrochemical etching could be used in addition as well as catalysts to improve attachment of certain layer on the substrate, if they do not fit without such treatment as such together. In the figure the coating is demonstrated at the outside the tap by the layers 4281, 4282, 4238. However, the number of the layers is not limited, not side of the tap. Although not indicated in the figure also the inside wall 4279 of the tap as substrate can be coated. In the example, the layer 4281 can be an adhesive layer, the 4282 could be a gold layer, and the layer 4283a wear resistant transparent/and or stained diamond layer, so to have the tap for instance coated for a certain appearance. However, the layers can be less or more, depending the appearance and/or degree of resistance against the wear out and/or corrosion desired. Also self cleaning coatings can be used for the coating in the tap water and/or sewer related pipes, connectors and/or valves. Antistatic coatings can be made, and thus for instance oil-refinery related piping can be produced without in-use risk of electric sparks.

FIG. 43 demonstrates coating of a window 4383 made of glass, and/or plastics. The use of embodiment of the invention can be addressed to making a self cleaned 4384 coating. The window can be coated inside, for example against infrared stop coating 4386, but outside with a coating 4387 to tone or stain the glass at the outside. The outer most coating layer could be provided with a photo catalytic layer 4388 to achieve visibility in sufficient level.

The substrate can be an ordinary glass, but also a glass or other substrate material to achieve a laminated structure. One of the layers can be a polarizing layer 4337 to decrease adverse effects of bright light to a pilot or driver, but the layer can be photo catalytic layer 4336 to keep the glass or window clean. It is also possible to manufacture layered window structures on substrate 4338 with a diamond layer 4339. It is also possible to utilise a structure with a plastic layer 4340.

FIG. 44 demonstrates use of an embodiment of the invention for coating a stone and/or ceramic surface 4489. The surface can be inner surface, or a plate outside on the yard, marble or synthetic ceramics, which can be stained 4490 to green, and can be additionally provided with a diamond coating 4491 for increasing wear resistance.

FIG. 45 illustrates use of an embodiment of the invention for coating a metal element 4592. The surface can be stained with a colorizing agent as a layer 4595, after which the surface can be coated by a layer 4594 of carbonitride and/or diamond for increasing the wear resistance and/or corrosion resistance. The element can be a building element for inside and/or outside use to be used for building a house, bunker, other building, tank, car, ship, boat, or other moving vessel as a lining element. In military applications also stealth coatings can be made to protect the objects being observed by radar.

FIG. 46 demonstrates use of an embodiment of the invention for coating of a television 4696 or other similar kind of a display or a part thereof. However the surface to be coated can be an inner surface, and/or an outer surface. The shown example appears to be an EAD 32″, however not restricting the unit by any means only to the shown example. The front surface of the television appears to be of type of having OLED, LCD or plasma TV. A coating 4697, 4699, 4600, 4601 material for a screen substrate 4697 can be selected from the usual materials, but can comprise also diamond coatings and/or photo-catalytic coatings to keep the screen clean and/or unscratched. Also other surfaces on electronic devices can be coated. For instance, ipods, video recorders, DVD-players, record players, CD-players, and/or radio receivers, but also fridgerators, stones, air cleaners with their filters etc.

FIG. 47 illustrates use of an embodiment of the invention for coating of railings 4702 and/or door handles 4703, but also other kind of pullers or handles as well as hinges of several kinds in industry, business and/or for domestic use.

FIG. 48 illustrates use of an embodiment of the invention for coating of lightning elements and/or parts thereof. The mirror 4804 of the light-element can be stained with a suitable coating 4805 for a desired wavelength distribution for instance in a plant house, but also the light bulb itself or other light source can be coated inside or outside of the cover 4806. Additionally, sealed light providers can be made, so that a cover piece 4807, (of glass, plastics, composite or laminated) can be coated to comprise a suitable staining coating. Photo-catalytic coatings are also possible to provide clean optical surfaces for a coated surface, also for other surface, not only for mirror of a lighting device.

FIG. 49 illustrates use of an embodiment of the invention for coating of a wing surface of an air-craft device. The surface can be an inner 4909 surface and/or an outer 4908 surface. Especially, when the inner parts of the wing are to be used for fuel tanks, the surfaces are advantageous to make by an anti-static coating, which can be light and hard, which properties can be achieved by diamond coating made by an embodiment of the invention. The coating made as sufficiently thick can also support the wing structure and thus the weight of the wing can be lighter. Smooth surface arranged to minimize friction of the air decreases fuel consumption as well. So, sufficiently thick diamond coatings can be used, but also with other coatings also in laminated structures to achieve sufficient strength/hardness.

Thus, the wing structure can be made so that the wing structure 4910 has on one side a coating 4912 and on another side a coating 4913, which can be diamond coating. Stiff structures can be thus made, but also arrange them to tolerate hard loads at a bending or alike area 4911. Such areas can be strengthened by the coating so to tolerate better local stresses, such as the motor mounting areas on aeroplanes frames wings and/or other body parts, for instance.

FIG. 50 illustrates use of an embodiment of the invention for coating of carbon-fibre composite piece 5014 by a coatings 5015 and/or 5016 according to FIG. 25. Such a piece can be linear shaft like, but not limited thereto only. The piece can be a plate like structure. In addition, the coating can be made over the whole piece, or to a certain particular part of the piece, which may be a bending part or otherwise active or exposed to wear-out related things in the environment. In embodiments, that are related to bone or similar structures as replacement parts, such parts can be coated to increase the mechanical strength, but also or, or, in addition, to increase chemical resistivity of the structure in the environment.

FIG. 51 illustrates use of an embodiment of the invention for coating of screen part. The screen can be a flexible paper-like screen. The shown example is illustrative and does not restrict the scope of the embodiment only to OLED, LCD, plasma or any other particular screen type only. Also card boards can be manufactured on a flexible substrate by an embodiment. That facilitates new and practical way of providing rollable and/or spiral shaped card boards for electronics. The substrate 5121 can be coated on one side by a layer 5122 for creating a card board pattern, and/or coated on another side by another layer 5123 for creating another card board pattern. The layers, partly or in whole, can be protected 5124 by suitable diamond layer. For instance a touch screen can be provided on a substrate as a coating. Electronic books can be thus made by using such flexible screens, which in part can also be provided with a solar cells operable in IR and/or UV wavelengths, thus leaving a part of wave length range in visible light for the reader's use.

FIG. 52 illustrates use of an embodiment of the invention for coating of an aircraft vessel 5229 and/or a part 5230, 5231 thereof. What ever part can be coated without limitation to only the shown windows or the mounting frames of it and/or gaskets. FIG. 52 illustrates also coating of a part of an air craft. The part shown is a part of landing gear part, as a wheel 5234 or rim 5232 for a wheel or a rim part 5234. Also wheels for trains and car rims and/or tyres can be coated. Rails for trains can be coated to prevent corrosion.

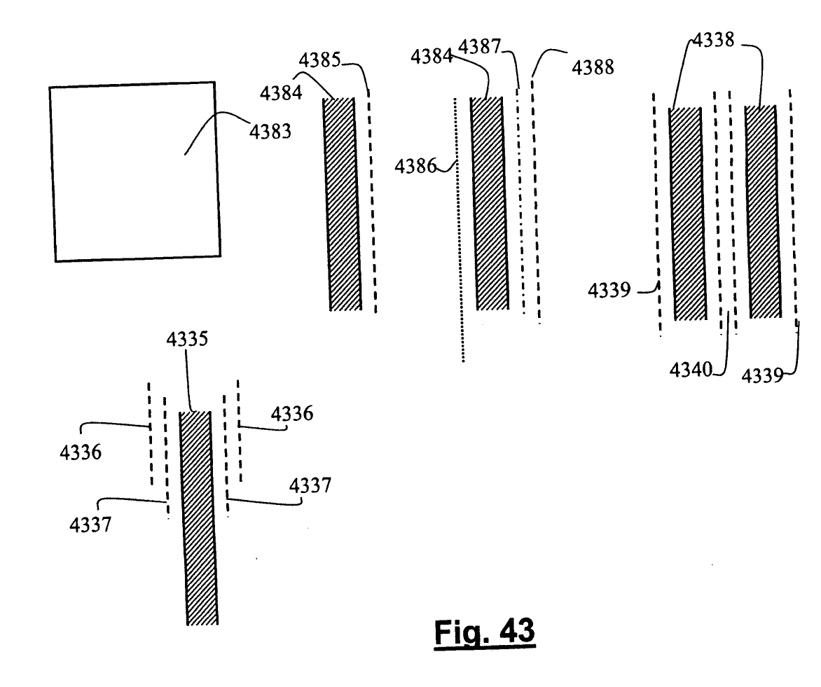

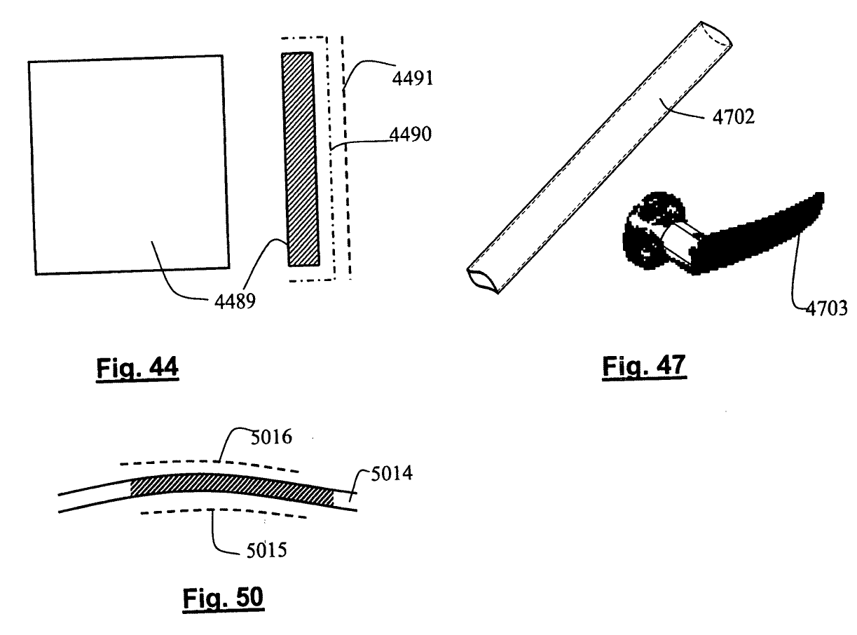

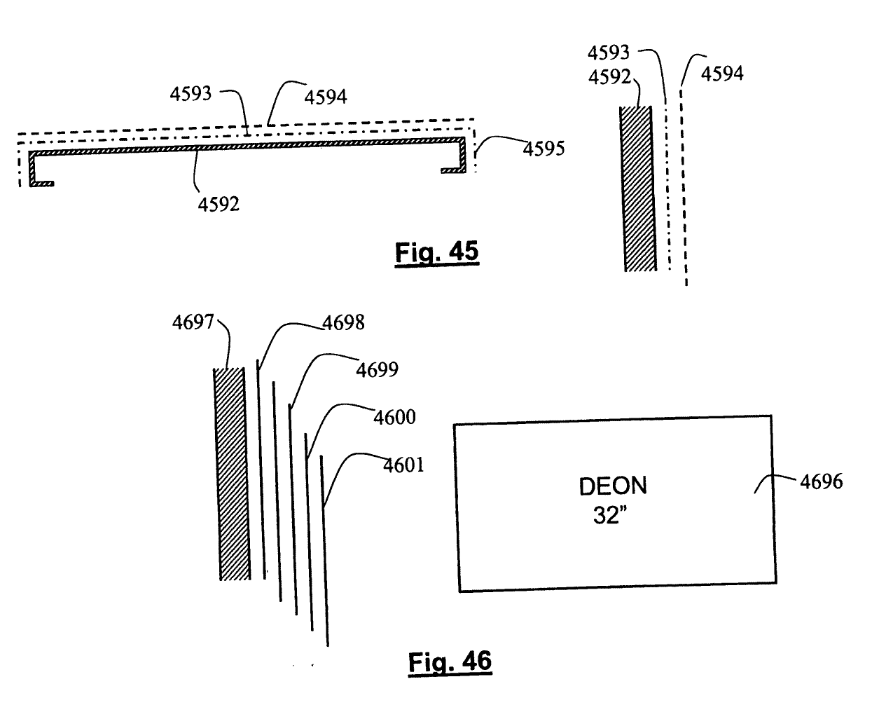

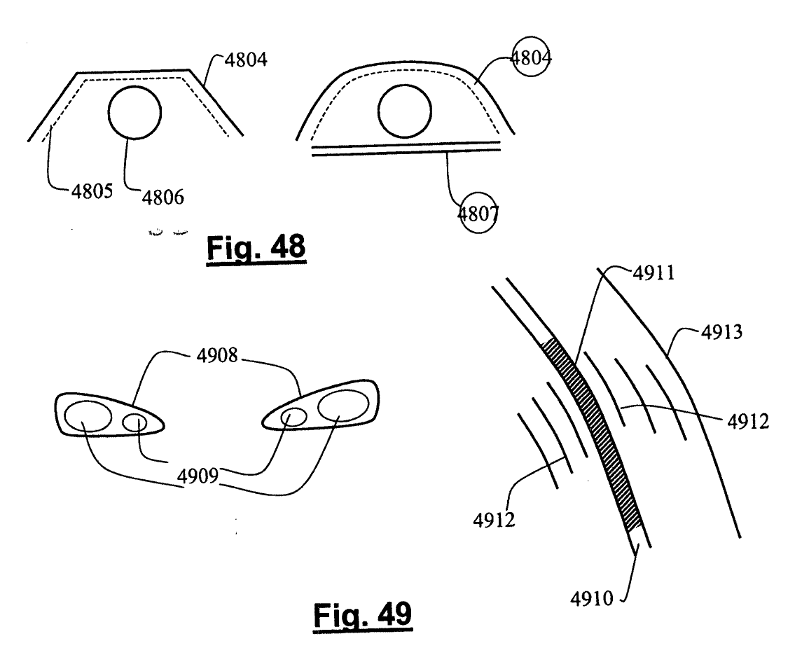

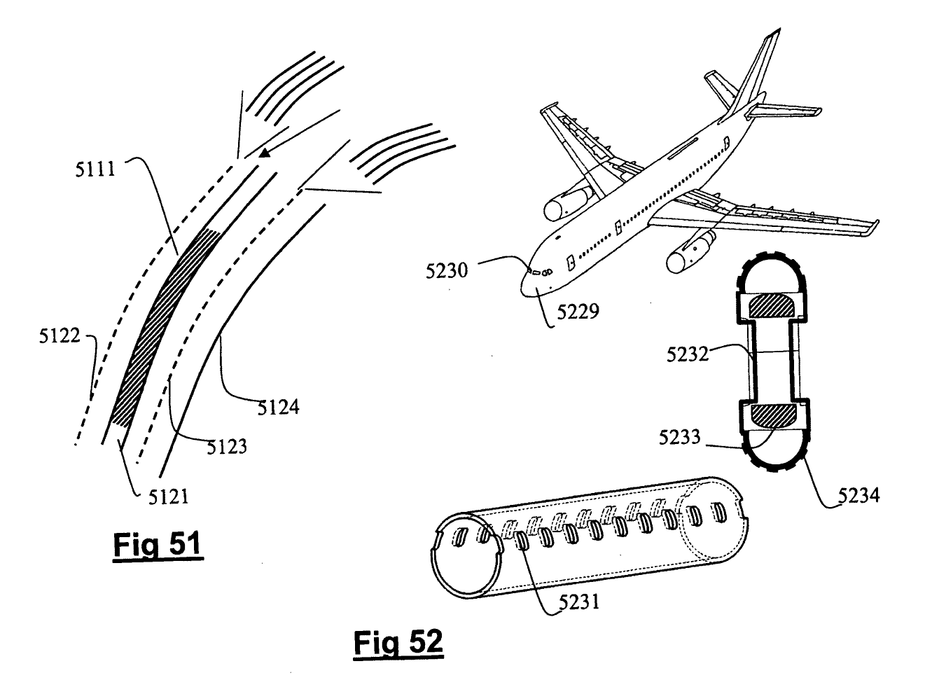

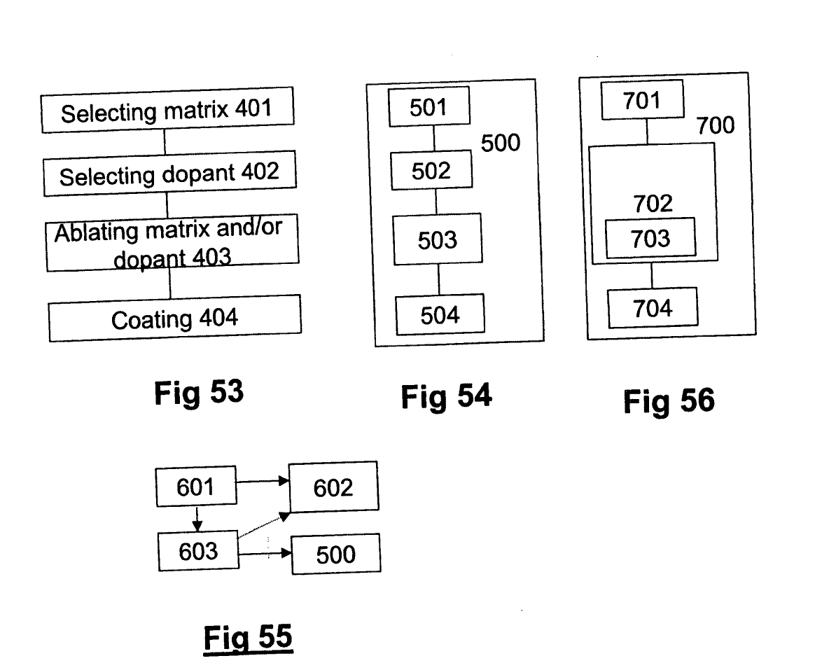

FIG. 53 illustrates coating according to an embodiment of the invention. The coating can comprise substances from the FIG. 25, but also noble gas compounds. The matrix and/or barer 401 are selected, the dopant 402 is selected, the matrix and/or dopant are ablated 403, and the substrate is coated with the consequent plasma. Although very simple flow chart, the steps can be used in multiple times in series and/or in parallel for coating a plurality of substrates with at least one substrate.

FIG. 54 illustrates a printer 500 according to an embodiment of the invention. The printer has, for a 3D-printing, a target holder 501 arranged to hold the target for its exposure to a first surface modifying beam with the effective depth, means 502 to produce the first surface modifying beam and/or a transfer line as a radiation path for transferring said beam along said path on to the target, means 503 to produce a second surface modifying beam with its effective depth, and/or a transfer line for exposing at least one surface of the substrate to a second surface modifying beam, and a substrate holder 504.

FIG. 55 illustrated a copy machine comprising means 601 for acquiring data of a 3D-body on the shape and/or measures and/or recording into a file 602, means 603 for translating the data into control commands for controlling a 3D-printer (for instance the item 500) for printing a copy of the 3D-body with a certain accuracy.

FIG. 56 illustrates a laser system according to an embodiment of the invention. The system comprises a radiation source 701 for generating the radiation for the ablation, a radiation path 702 comprising a turbine scanner 703 for directing said radiation to the target part. The radiation source can be embodied according to an embodiment by several laser sources, which are arranged to ablate target material from a target or a part of such.

A surface processing method according to an embodiment of the invention comprises
exposing a target material acting as a target to a surface modifying beam,
directing a radiation path for the surface modifying beam from a radiation source to the target for ablation of the target material,
vaporizing/ablating target material to effective depth, for a modification of at least a surface in respect of at least one surface characteristic.

A surface processing method according to an embodiment of the invention said characteristic is at least one of the composition, chemical structure, mechanical structure, physical structure to said effective depth. An embodiment of the invention comprises a method step in which a first surface is selected to a target and/or a second surface is selected to a substrate, for modifying of target material from said first surface by a first surface modifying beam. In a method according to an embodiment of the invention the modifying comprises is removal of material from the surface at the effective depth by said first surface modifying beam. In a method according to an embodiment of the invention the method comprises setting a surface of a first body to the target and/or a surface of a second body to a substrate so that a second surface modifying beam is used to bring material on to said surface of the second body. In a method according to an embodiment of the invention the method comprises modifying of said surface comprises addition of material on said surface to the effective depth defined as the layer thickness of said material. In a method according to an embodiment of the invention the method comprises transferring material to a second surface by a second surface-modifying beam so that said material originates to said first surface, as being removed by a first surface-modifying beam.

A coating method according to an invention comprises a surface processing method according to an embodiment of the invention. The surface processing method is applied for a plurality of substances comprising at least one or several substances to be used for the coating. A coating method according to an embodiment of the invention comprises ablating at least two substances from essentially same target part. However, the target part can be different, even a different target can be used. A coating can be made directly form the elements fed into the coating process in the stoichiometric relation of the desired coating composition. According to an embodiment of the invention the first and second substances are ablated in that order, in series, whereas according to a variant of an embodiment, at least one substance is ablated simultaneously at least partly with another ablated substance, in respect of the duration of the ablation of each substance. According to an embodiment of the invention the ablation is made for carving, but according to an other embodiment the ablation is made for making a coating, i.e. the ablated target material is used for the coating formation on a substrate to be coated.

The ablatable material can comprise the coating matrix substance or other kind of a carrier, which can be doped by a dopant. The doping may be made to gain additional features to the substrate surface, and/or to the coating layer. Such an additional feature may be a desired elasticity, Young module, crystalline structure, a dislocation of such and/or tensile strength of the coating and/or substrate surface.

A coating to coated according to an embodiment of the invention, on a substrate, can comprise carbon, as graphite, diamond in amorphous, polycrystalline form or monocrystalline form in a layer. Such layers can be coated even several layers on one by one, especially in such an embodiment in which the coating is used as sliced way for 3D-printing and/or copying.

The substance for the carrier matrix and/or the dopant can be chosen from the elements available in the nature, but is not limited to only them. Suitable substances can be uranium, trans-uranium, earth metal, rear-earth, alkaline, hydrogen, lanthanide, and/or a noble gas, the substance can comprise as a dopant uranium, trans-uranium, earth metal, rear-earth, alkaline, hydrogen, lanthanide, and/or a noble gas. Other suitable dopants are dopants from boron-group (IIIb), dopants from carbon-group (IVb), dopants from nitrogen-group (Vb), dopants from oxygen-group (VIb), and/or dopants from halogen-group. However, a skilled man in the art knows form the current embodiments, that all possible permutations and variations may be not as advantageous for a coating as the others. For example, dopants that form unstable and/or poisonous mobile compounds are not desirable as such as such compounds for all the purposes in the scope fitting into the scope of the embodiments.

According to an embodiment of the invention the coating method can be used to coat several kinds of objects. The surfaces to be coated can be inner and/or outer surfaces of a body. The bodies can be even nano-scaled bodies, machines or parts thereof, as well as macroscopic bodies such as buildings, or intermediate sized bodies.

The coating can be illustrates for some examples on the bodies suitable for coating, however, without intention to limit the scope of the embodiments only to the mentioned examples. A coating according to an embodiment of the invention can be used for the body and/or lining structure of an air-craft vessel, ship, boat, sailing ship or a part thereof, vehicle, or space-craft-vessel, to a surface of a motor and/or a part thereof for an air-craft vessel, ship, boat, sailing ship or a part thereof, vehicle, or space-craft-vessel, to coat a surface of a lining structure and/or a part thereof for an air-craft vessel, ship, boat, sailing ship or a part thereof, vehicle, or space-craft-vessel, to coat a surface of a body, which is tool and/or a part thereof, to coat a surface of a body, which is a piece of furniture aimed to domestic and/or industrial use, to coat a surface of a body, which is a vessel, dish, holder, receptacle, tank, vat, jar, can, pot, bowl, container; tray, bin, trough, tub and/or barrel, to coat a surface of a body, which is aimed to be used in kitchen and/or industry comprising metallurgical industry, food industry, medical industry, chemical industry, painting and/or pigment industry, semiconductor industry, to coat a surface of a body, which is kitchen-related body, reactor, reactor for a chemical reaction, and/or transfer line of material, to coat a surface of a body, which is one of the following:
a transparent plate of glass, plastics, composite or a laminated structure,
opaque plate of glass, plastics, composite or a laminated structure,
solar cell and/or part thereof, and
a combination of the mentioned of.

A coating according to an embodiment of the invention can be used for to coat a surface of a body, which is a building element for a building for housing and/or other building, to coat a surface of a body, which is a building element for a building for housing and/or other building composing of natural and/or non-synthetic material originating to nature, to coat a surface of a body, which is a toy or a part thereof, to coat a surface of a body, which is a watch, clock, mobile, PDA, computer, display, TV, radio, or a part thereof of the any mentioned, to coat a surface of a body, which is a casing and/or a shell, or a part thereof of the any mentioned, to coat a surface of a body, which has a fibrous composition at least partly, to coat a surface of a body, which is thread, yarn, chord, filament, wire, string, solid conductor, strandline, rope, to coat a surface of a body, which has a web structure and/or has a textile structure, to coat a surface of a body, which is one of the following: fibrous filter, industrial textile, textile for a cloth or paper, to coat a surface of a body, which is wave-guide for electromagnetic radiation, to coat a surface of a body, which is made of diamond at least partly, to coat a surface of a body, which is has a different composition before the coating than after the coating, to coat a surface of a body, which comprises means for practicing sports, coat a surface of means, which comprises means for practicing sports, to coat a surface of a body, wherein said means are means for skiing, slalom, snow boarding, skating on ice or ground, cradle, sledge, sleight, playing games with at least one stick, to coat a surface of a body, wherein said means are throwing, shooting, sliding, gliding, scrolling or bowling, to coat a surface of a body, which is cycle or a part thereof, chain, bearing, or another part of the just mentioned, to coat a surface of a body, which is a piece of jewelry, decoration, art-work or a copy thereof, to coat a surface of a body, which is a micromechanical element, to coat a surface of a body, which is a semiconductor, to coat a surface of a body, which is a insulator for electricity and/or warmth, to coat a surface of a body, which is a conductor for electricity and/or warmth, to coat a surface of a body, which is spare part of human being and/or animal, to coat a surface of a body, which is a joint surface, to coat a surface of a body, which is an fixing means, as a rivet, stud, screw, nail, hook or nut, to coat a surface of a body, which is at least a part of a radiation path, to coat a surface of a body, which is a turbine scanner, or a mirror thereof, to coat a surface of a body, which is a plastic film, in product form of sheets and/or web, to coat a surface of a body, which is an optical element, to coat a surface of a body, which comprises a lens, prism, filter, mirror, an attenuator, polarizer or a combination thereof of the just mentioned, to coat a surface of a body, which is spectacles or contacts, to coat a surface of a body, which is bond, stock or another paper of value, or means of payment, to coat a surface of a body, which is a container for storing a substance, to coat a surface of a body, which is a container for storing hydrogen and/or releasing hydrogen, to coat a surface of a body, which is a container for storing hydrocarbon and/or releasing hydrocarbon, to coat a surface of a body, which is a container for storing nuclear fuel and/or an element thereof and/or to coat a surface of a body, which is a substrate body to be coated with an UV-active coating. According to an embodiment of the invention optical elements can be coated in a precise manner, to comprise coatings that have layers arranged to form the optical properties of optical element as uncoated.

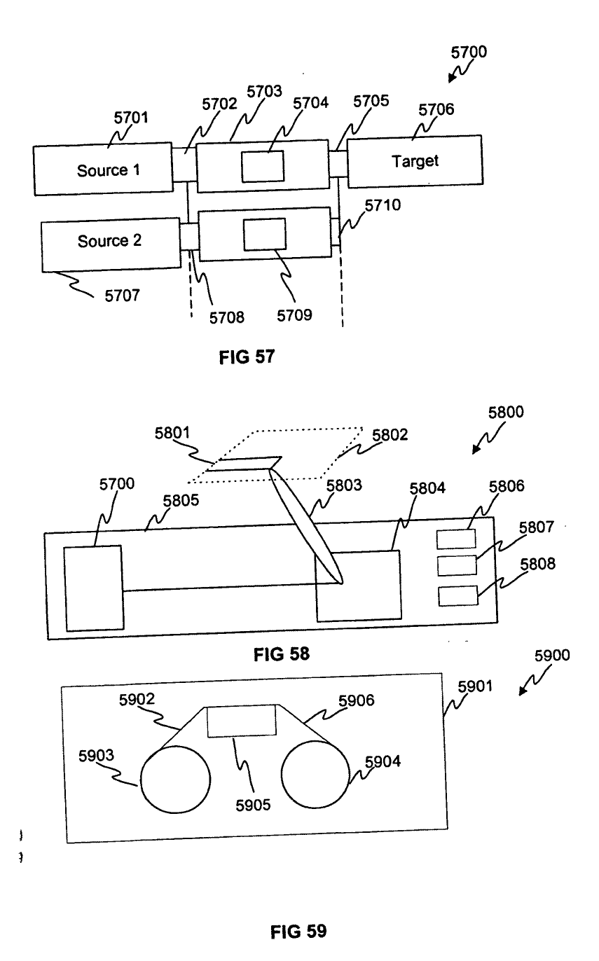

FIG. 57 illustrates a radiation source arrangement 5700. The example shown comprises a radiation source 5701 and/or another radiation source 5707. The number of the sources as such is not limited only on or two. In the arrangement, there is also indicated the target 5706, which can be target material according to an embodiment of the invention. FIG. 57 also illustrates radiation path 5703 as arranged to guide radiation from a radiation source 5701 to the target 5706, to used for ablating the target material. The path comprises a scanner 5704, but the number of scanners per path is not limited to the shown only. The figure illustrates adapter 5702, 5705 arranged to adapt the path 5703 to the source 5701 and the target 5705, respectively. The adapter can comprise an expander, contractor and/or a correction optics parts, which are necessary for the focussing in such embodiments, in which the geometrical beam shape is necessary to change in the path from the source to the target.

FIG. 57 also embodies such variations of the arrangement 5700 in which there is also an additional source 5707 to be used in parallel and/or in addition to the source 5701. The additional source can be exactly the same according to one embodiment but according to another a different one. According to one embodiment, the source is a heater. The adapter 5708 can be the same as 5702, but is not necessary such. It can be also an integrated adapter as an expander. The scanner 5709 can be same as the scanner 5704, but is not limited only thereto. The scanner is advantageously a turbine scanner according to an embodiment of the invention. According to the way of drawing, the adapter 5710 is arranged so that the radiation from source 5707 arrives to the target 5706, as the radiation from the source 5701. The arrangement do not necessary need the adapters at all, provided that the geometry of the beam directed via the scanner is sufficiently uniform and/or in correct focus, above, beneath or the on the surface of the target material or its base. The radiation of the source can be in one embodiment directed to several targets, although only 5706 shown as an example.

FIG. 58 illustrates a target material unit 5800 arranged to provide target material for the coating related embodiments according to the aspects of the invention that relate to the coating. Although the target material unit has the casing 5805 in the example to cover the radiation source arrangement 5700 as well as the target 5804 in the same cover, it is not limited only thereto. The figure illustrates the beam 5803 as a material plume of the ablated target material. The plume 5803 can be used to coat the substrate 5802 by the coating 5801 that is already attached on the substrate. Such a target material unit can be utilised in embodiments of the invention in suitable part, for instance in 3D-printer to print coating layers, as well as in the copy machine. The unit 5800 in FIG. 58 comprises advantageously means to heat the target to the correct temperature. According to an embodiment of the invention the heating means 5806 is implemented by a laser and/or by an RF-source. According to an embodiment of the invention the target material unit comprises a pump 5807 arranged to condition the ablation/coating according to the example in FIG. 25, for instance. The atmospheric means 5808 in figure are arranged to condition the composition of the atmosphere in the target material unit for the optimum of the ablation of the target and/or coating of the substrate. The target material unit can comprise also means for catch dust and/or fragments if any, (not shown). Such means can be electrostatic precipitator means arranged to collect potential target material fragments and thus to improve the quality of the coating. The field can be arranged according to the mobility of the constituents for the minimum disturbance to the plasma plume 5803, but sufficient to collect solid/liquid particles.

FIG. 59 illustrates a ribbon like feed module 5900 of target material in a target material unit. A reel 5903 is arranged to give target material 5902 for the use as target, optionally or in addition to the heating by the heating means 5905 at the ablating area. The used target material ribbon 5906 is collected with the potential residue on the reel 5904. According to one embodiment the module is one time use only module, but according to another embodiment the module is re-circulatable and the ribbon acting as the base can be coated again for the next use.

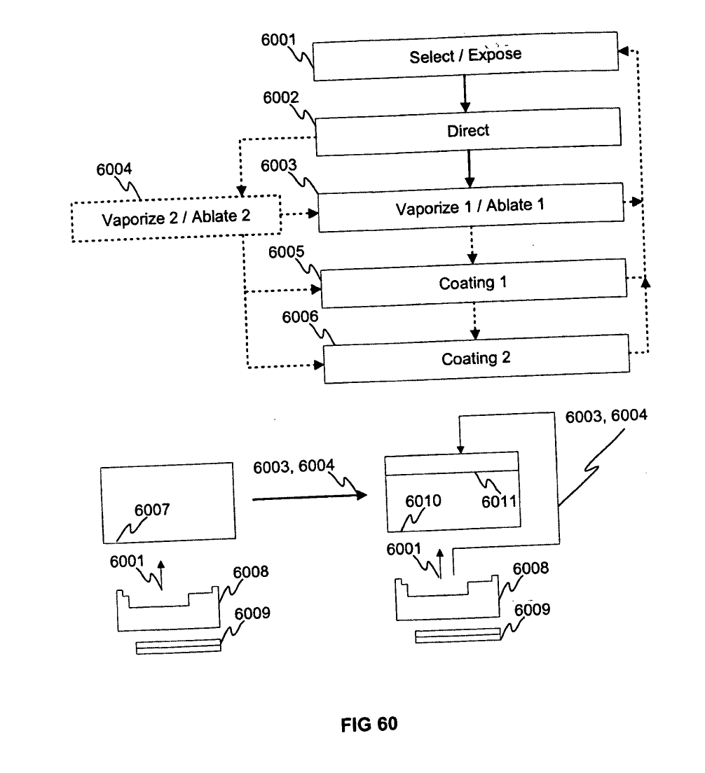

FIG. 60 illustrates a coating method according to an embodiment of the invention. The method has phase 6001 of selecting and/or exposing the target, substrate and/or the coating. According to one embodiment of the invention the target can comprise a constituent of the coating, but part of the coating can be formed by the atmosphere at the substrate, and/or the substrate surface constituent or several. According to another embodiment of the invention the target material is the same as the coating. A radiation beam is directed to the selected target material in phase 6002 in order to expose a target material to the radiation. According to an embodiment of the invention there can be also another target material to be ablated. Although drawn in parallel to phase 6003 the second ablation phase 6004 is not necessary a parallel phase, but can be a serial phase according to one embodiment. Certain optionality of the coatings, related not only to the different aspects of the invention, is illustrated by the dashed lines. The coating phase 6005 can be used as only coating phase according to one embodiment, but the second coating phase 6006 illustrates that in another embodiment there can be several phases of coating. According to an embodiment of the invention after each ablation and/or coating the method comprises a phase of checking if all the coating layers were already made. That is illustrated by the arrows directed as shown in figure backwards from higher reference numerated phases to the lower reference numerated phases. The freedom to select of a coating 6011 for a phase 6003 and/or 6004, substrate 6010 and/or target material 6007 is illustrated by the periodic system of elements 6008, 6009. However, that is not limiting the said materials as such only to elements, although the target material is ablated. Also compounds of the elements can be used.

The substrate to be coated with a coating, according to an embodiment of the invention, can be any solid body from the patent class of human necessities.

3D-printer according to an embodiment of the invention comprises a target holder for holding a processable surface for exposure of said surface to a surface modifying beam to an effective depth thereof, means for producing the surface modifying beam and/or radiation transferring path to direct said second surface modifying beam to the target, means for producing a second surface modifying beam and/or a second radiation transferring path to direct said second surface modifying beam to the target, and a substrate holder for holding said substrate for exposure of said surface to a second surface modifying beam to an effective depth thereof.

3D-printer according to an embodiment of the invention comprises means to produce a surface-modifying beam as an ablating beam to stylization of the print. According to an embodiment, the 3D-printer comprises controller means arranged to control the printing of the 3D-body slice by slice, each slice with its effective depth, wherein said second surface modifying beam is a material plume. According to an embodiment, 3D-printing may need also carving by cold-ablation. Basically there are two options to implement 3D-printing. A first way for the implementation is to select a starting piece sufficiently large for the printed body and to sculpture pr carve the print. Another implementation is a coating related approach to produce and direct layer by layer the second surface modifying beam as the plume to form the print.

3D-copy-machine according to an embodiment of the invention comprises at least a 3D-printer according to an embodiment of the invention. However, although not all parts are described, advantageously such a copy machine further comprises first means to define and/or formulate data of a 3D-body on its shape and/or dimensions for recording into a file, second means to convert said data to control commands for controlling a 3D-printer. According to an embodiment of the invention said first means comprise optical means for UV, visible light and/or IR. Such first means can be implemented also so that they comprise X-ray tomography and/or acoustic means. The shape and measures can be detected by using interference. Especially with the nano-scaled bodies to be printed and/or copied, the wavelength should be selected appropriately for sufficient resolution of the details. Thus, the relative errors of nano-scaled bodies may be larger than those for macroscopic bodies, or hose of intermediate bodies to be printed and/or copied.

Manufacturing method of target material according to an embodiment of the invention comprises a phase of selecting and/or exposing a film and/or a sheet like base to a material plume of the ablatable target material for coating a part of the base at least on one side with said target material. According to an embodiment of the invention the method comprises utilisation of a mechanical shaplone for providing the target material a shape feature. The shaplone can be implemented in mechanical way, which however may lead to significant material losses, shown in the product price. According to an embodiment of the invention, the method comprises providing the base markings for the target material for giving a shape feature with at least a pitch in one direction and/or two directions. According to an embodiment of the invention said markings are electric markings; magnetic markings or the markings comprise a thermal markings. Said markings can be provided as seeds onto locations on the base for a heterogeneous nucleation and/or a following condensation to be used for the formation of the target material into certain predefined form. However, when an exact form desired for the shape feature, the method comprises a stylization phase of forming the target material formations on the base. In the manufacturing, a target material unit according to an embodiment of the invention can be used.

According to an embodiment of the invention the target material is pre-heated before and/or during the ablation. The heating can be made by a heater arranged to operate in RF and/or IR frequencies. According to an embodiment of the invention the heating is arranged to occur by a laser with a lower power than the ablating beam. The heating can be arranged in one embodiment for the whole target material that is supposed to be ablated during the ablation event, but in another embodiment a pre-heater beam precedes the ablating beam on the part of the target material to be ablated. According to an embodiment the pre-heater beam is arranged to over lap at least partly the ablating beam. According to another embodiment of the invention, there is a relaxation time arranged according to the material to be ablated therebetween the pre-heating of the spot of the target material and the ablating beam. An advantage is gained by the heating of the target, which can be of various forms, for example film, ribbon, foil, plate, belt, rod or a combination of the just mentioned. One advantage seems to be that the structure of the surface that is made by the beam and/or the coating by the ablation can be better controlled with a pre-heating. The coating structure can be more advantageous in 3D and/or a higher quality. The preheating can be utilised for several targets, but especially for carbon and related derivatives as target, but also for oxides. The derivatives refer to compounds of carbon, such as carbides as well as carbo-nitrides in various forms, but also to graphite in various forms, sintered carbon, pyrolytic carbon. However, the said examples are not intended to limit the target material only to said examples, with the pre-heating of the target.

### EXAMPLES

### Example 1

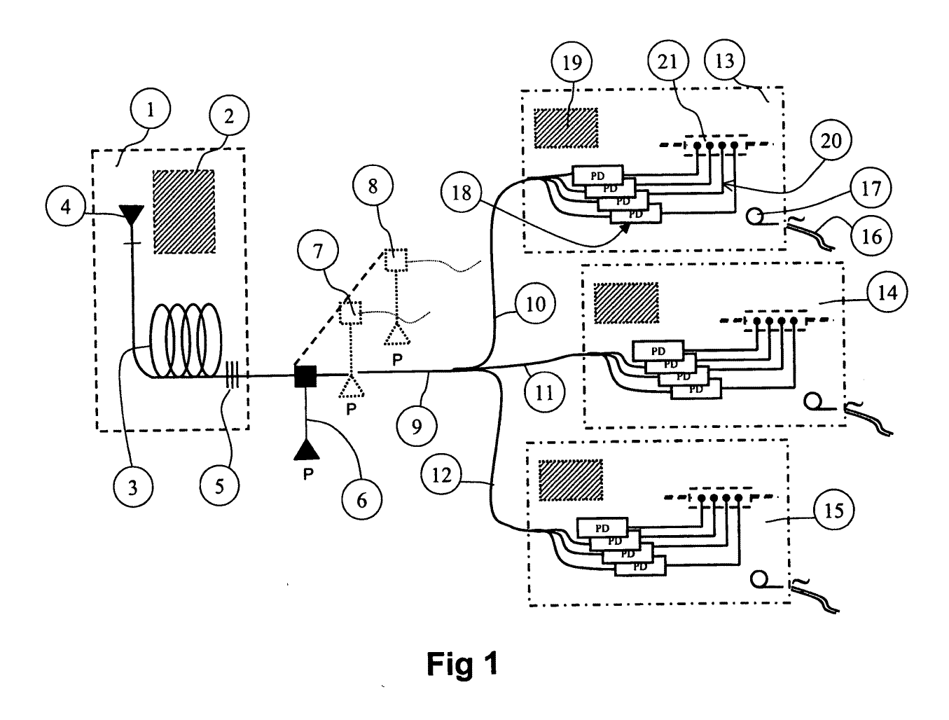

FIG. 1 illustrates a fibre oscillator (3) and a preamplifier (2), but also formation of an incident laser-light with a diode (4) and sesam-grid (5). The new laser system is a phased-diversified-amplified-direct-mode laser system (-laser system). This is the pre-amplifier unit (1) of the PDADM-laser system, which unit defines the pulse length, pitch, power, and other features of the radiation).

It is actually a digitally controllable control centre arranged to control the whole radiation source arrangement. The radiation source arrangement is completely fibre-based laser system.

The second phase laser-pulse gain/amplification (6) resides in the same central unit (1), so that even several parallel amplification units (7) and (8) can be in duty, as depending on the number of desired working spots and/or targets the laser pulses are addressed to as amplified.

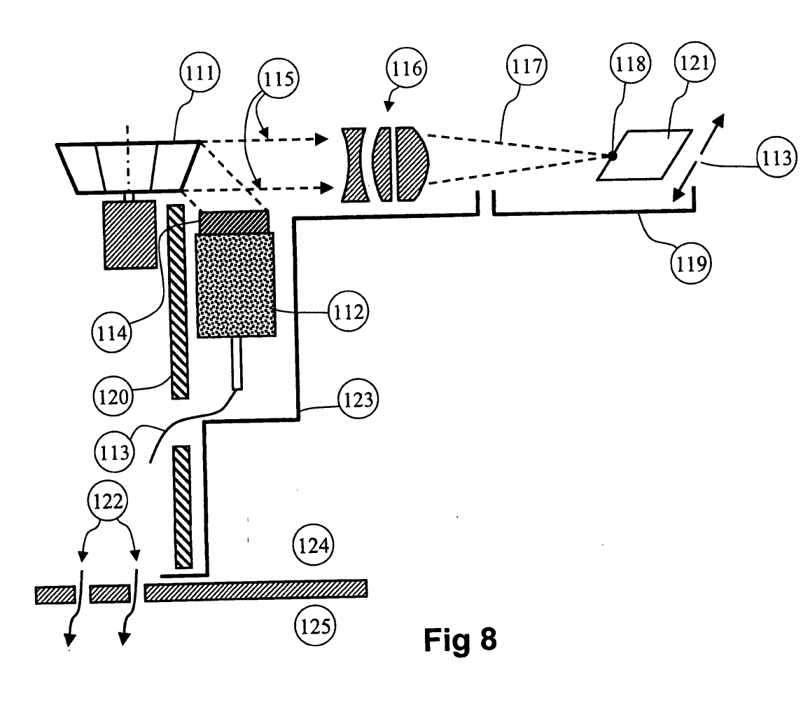

A low powered laser pulse (as a light pulse) (9) is further directed via a divider, say, to three directions (10), (11), (12), according to the example of the figure, to be addressed to separate working spots (13), (14), (15), which can be selectable for example according to FIG. 8.

Diode-pumps (18), i.e. the means to form the high-power laser pulses as optimized, can be a single radiation source in the radiation source arrangement, or there can be several ones, similar or different ones, but arranged as to receive a low-power laser-light pulse as conducted therein.

In a diode-pump (18) a low-power and low grade laser light pulse is amplified and transformed to a high-power and high grade laser-light pulse, that can be directed to a turbine scanner via an optical expander (21) for the pulsed laser light.

From the diode pump, a laser pulse can be conducted via a short power-fibre (29) to an optical beam expander, or the optical pulse expander is directly a part of the diode pump (18) itself.

An important feature to an embodiment of a radiation source arrangement concerning a fibrous laser light based arrangement is that, that a large laser-power generating diode-pumps (18), the power-amplifiers, are placed directly to the targeted working-spot according to FIG. 8 and a low-power laser pulse has been conducted from a common control centre to the location where the pulse is amplified to the final power level, to be used in the location.

Such a disclosed embodiment of the invention appears to be a diode-pumped fibre-laser, but having the power-amplifiers comprising the diode-pumps as located as a part of a vaporization/ablation system, contrary to conventional laser units, at the date of the priority of the current application, not to the parts of such conventional laser units.

Thus, high-power laser pulse transference fibres as well as optical connectors for the same are not needed anymore, at least the need appears to be remarkably diminished if not completely ceased. Thus, the laser ablation processes according to the embodiments of the invention suffer less the major problems of the power transference, not to mention the escalation of the current high-power fibres operated with the powers that are intended to be used in the new laser systems.

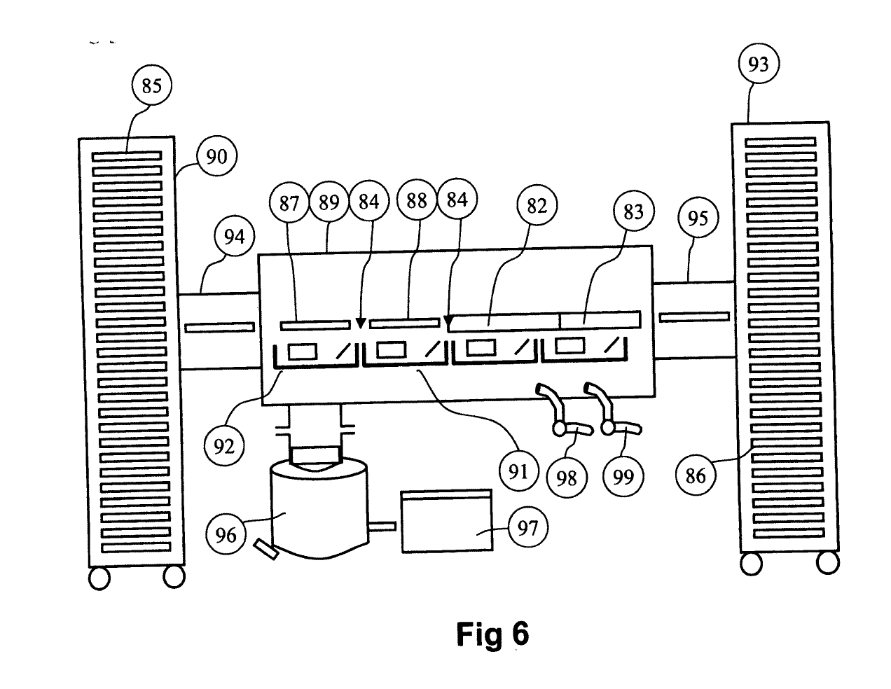

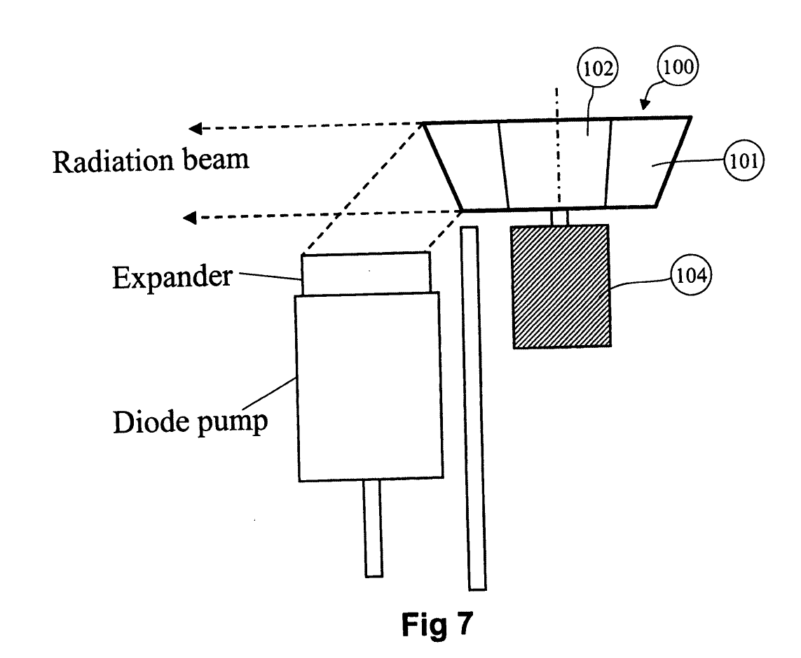

An important feature to the operating of the new radiation source arrangement as embodied as a laser system is that, the laser system is based on Modulated Oscillated Power Amplifier (MOPA). i.e. diode-pumped fibre-lased laser arranged to bring up the high laser-power at the working spot, for instance at a vacuum evaporation/ablation device (89) according to FIG. 6, as a part of a vaporization cassette (90) and (91). So, the embodied example of the laser system in question comprises the minimum, if not completely lacks, of such an optical fibre and/or connectors for the transference of high power laser pulses. The PDAD-based laser system produces the high-power laser pulse therein where it is to be used, at the targeted location.

### Example 2

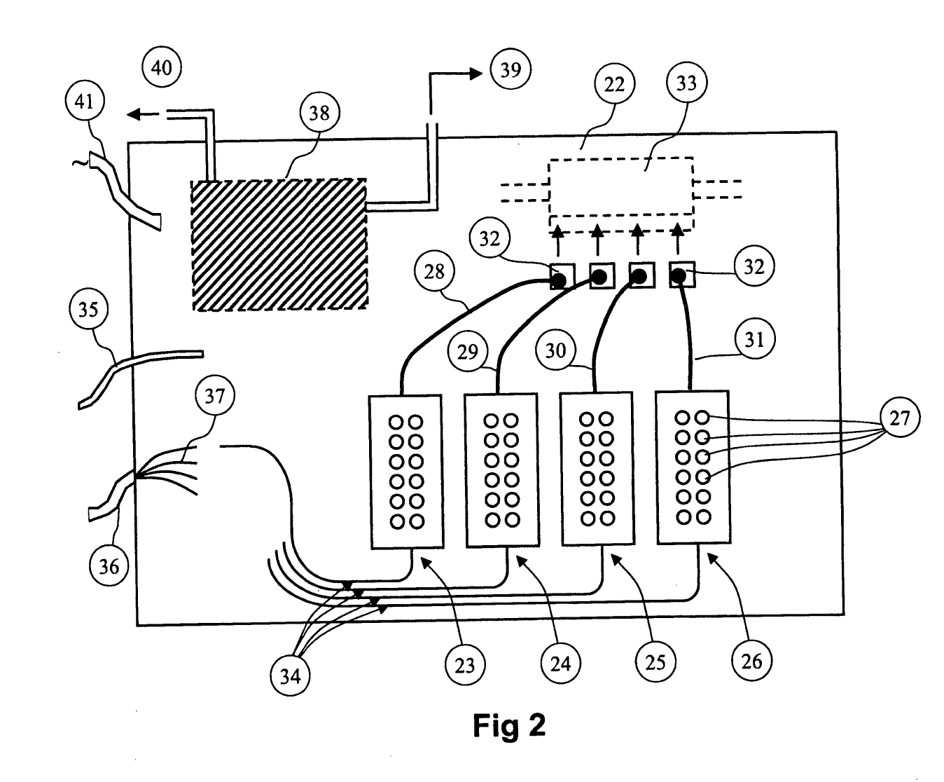

FIG. 2 illustrates a part of a radiation source arrangement as embodied as a laser related embodiment. In the embodiment, the power-amplifiers, as diode-pumps, are located into a vaporization/ablation system as a part of it, so that high-power laser pulse transference fibres as well as optical connectors for the same are not needed, at least the need appears to be remarkably diminished if not completely ceased. In this example the diode-pumps are in the vacuum vaporization/ablation device. In addition, in the embodiment according to FIG. 2, the optical expander is connected to a diode-pump via a high-power fibre.

### Example 3

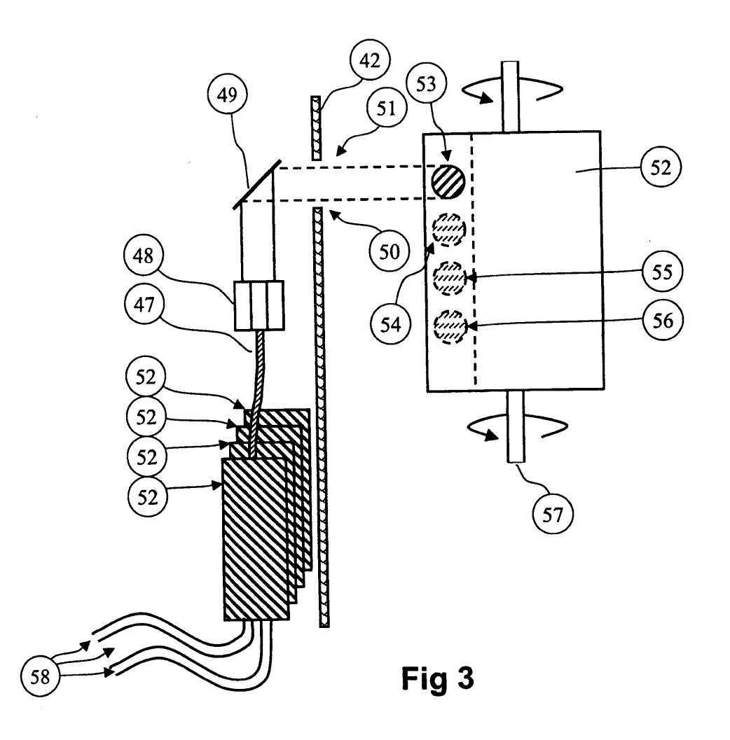

FIG. 3 illustrates a part of a radiation source arrangement as embodied as a laser related embodiment. In the embodiment, the diode-pumped laser power is directable to a turbine scanner. An extremely large pulsed laser power has been produced, but consequently, the scanning is not possible from a single mirror area, the scanning is implemented by several mirror areas.

Thus, FIG. 3 illustrates a situation in which an extremely large pulsed laser power has been produced and conducted with an optical fibre (47), or more advantageously straightly directed into laser beam/pulse expander (48) from which the expanded laser-beam (50) and (51) is directed to a turbine scanner (52) that rotates around its own central axis (57).

Thus, each diode-pump-produced-and-expanded laser-beam (51) and (52) produce its own laser beam reflection surface (53), (54), (55) and (56).

The reason for the manner of procedure relies in that, if four high-power diode-pumped laser beams were directed immediately to the scanner (52) as a one laser beam, the scanner were damaged. The location (58) shows in general, feeding a pre-amplified low-power laser pulse to a diode-pumps (52), the optical power-amplifiers, and (42) shows in general an electric circuit board.

### Example 4

It is an extremely high-power laser pulses produced also in this example, but because the scanning of using just one mirror area is impossible, the scanning is made by several mirror areas.

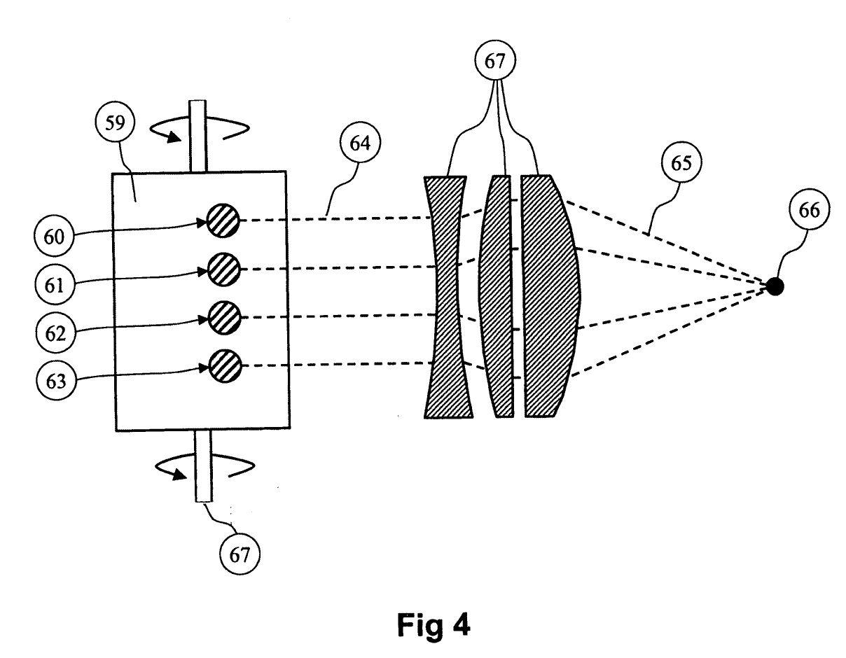

FIG. 4 thus illustrates a consequence from the operation of FIG. 3, wherein four separate laser beams (64) are focussed (65) into a common point (66) by optical lenses (67).

FIG. 4 further illustrates how four separate laser beams (60), (61), (62) and (63) are directed to a single scanner (59) that is rotating around its own central axis (67) and how four separate laser beams are focussed into a single point.

### Example 5

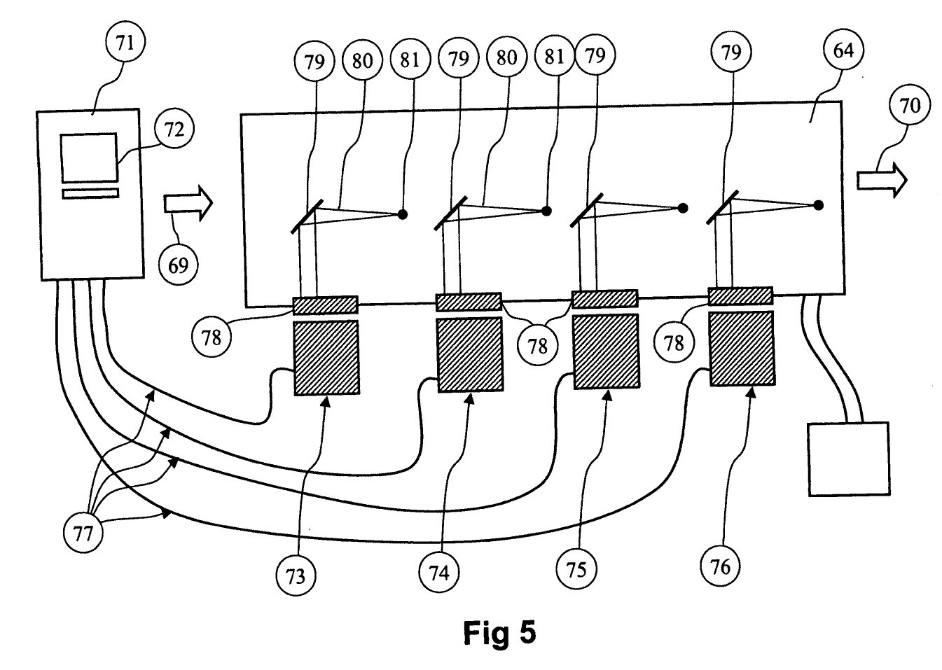

Example 5 is shown via the FIG. 5, so illustrating a manufacturing device for a working piece, in which a device the coating is arranged to occur in a controlled volume, as embodied as a vacuum, a volume in over-pressure, or a volume with a certain pre-defined composition of constituents in gaseous phase.

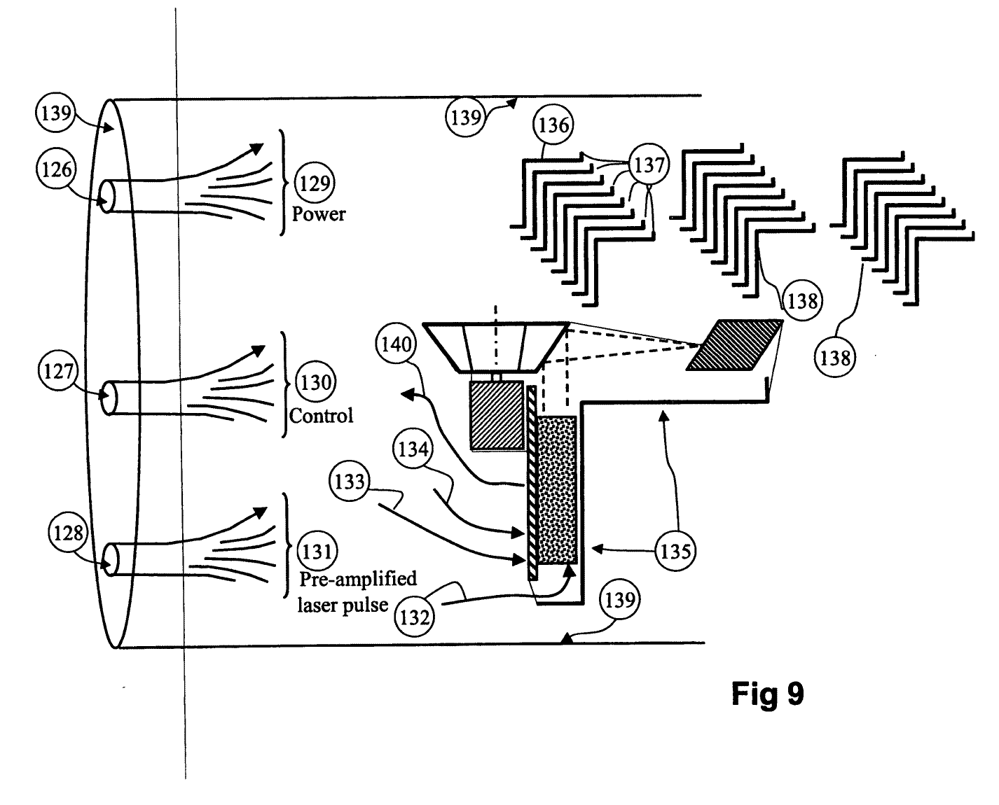

Operation is similar to the already described embodiments in suitable part, but differs from the related examples in that that for example in FIG. 9 the vaporization cassette system is entirely inside the controlled volume, but in operation according to FIG. 5, the vaporization cassette is divided into two parts so that one part is outside the controlled volume (64).

Central unit (71), comprising the pre-amplifiers, power-feed and the control units (72), is the same as the previously embodied, and from the central unit (71) there are lines lead to the vaporization cassette system.

In this embodiment example according to FIG. 5, the diode pumps, the optical power-amplifiers (73), (74), (75), (76) are located outside the controlled volume (64), as well as the optical laser beam expander and the scanner (78).

The expanded laser beam is directed via the mirror (79) so that it (80) is contracting, for the focusing onto/into a desired location of the target (81).

In this application of FIG. 5, as illustrated for example in accordance to the application of FIG. 9, it is the same technology utilising the PDAD-laser-system to produce the final large laser power at the in-use location, by the diode pumps, the optical power-amplifiers that are integrated in the example into the vaporization cassette system.

In the new method, it is actually at least two related ensembles of inventions, first the PDAD-laser-system itself, and second the use of it in combination of material production and/or coating within a controlled volume comprising vacuum or a pre-defined and controlled gaseous atmosphere, as applied for example to coatings comprising diamond, sapphire, silicon carbide, carbo-nitride etc.

In addition, a novel aspect of certain embodiments is that even more than one vaporization cassette systems can be addressed to utilise a single production volume, as embodied as a vacuum volume for example.

### Example 6

Example 6 deals with a vacuum vaporization/ablation arrangement and/or a related apparatus illustrated in FIG. 6. The device is capable for coating with metals, their oxides, boron, its compounds, nitrides, ceramic compounds and/or organic substances, directly. Also new compounds are possible to be made in the working process. Combining an element to another like aluminium to oxygen, alumina (Al₂O₃) can be made for coating the working piece.

The apparatus is easily as such applicable for diamond production directly from carbon by vaporization/ablation. Additionally, derivables of diamond can be manufactured, such as nitride-diamond, which is an example of a compound that is harder than the natural diamond, or completely new compounds can be brought up, such that has not been commercially available before, or have been very difficult to be manufactured in a technical sense.

A novel embodiment as an apparatus is based on diversified feature of the laser system, wherein the laser beam itself is brought up in its complete form at the targeted area.

A novel embodiment of an apparatus is based on a full fibre semi-conductor diode-pumped laser system, having a diversified structure so that the laser beam itself is brought up in its complete form at the targeted area, which is situated into a vaporization cassette system as a part of it, so facilitating the manufacturing device of the working piece.

The shown manufacturing device of the working pieces as indicated in the FIG. 6, can be very large in size, for example the vacuum chamber (89) itself can be even 5 m long, and comprise even 20 pieces (91) (92) of vaporization cassettes, each typically comprising a laser of 100 W or larger in power as a pico-second laser embodiment. However, the shown measures in this example are only illustrative and thus not binding.

The device is applicable for instance to issues of cold-ablation techniques, i.e. to pico-second, atto- and/or femto-second laser applications using extremely large pulsed energies ˜5-30 μJ/30 μm spot, so yielding so large a power level per pulse as 200 kW-50 MW.

In laser ablation a great importance emerges from the angle in which the laser beam meets the target material to be ablated, especially for the plume, and/or the angle of direction into which the plume is propagating when formed. Typically the ablatable target can be round and can additionally rotate around its own central axis in one embodiment, but the final yield of the ablation, in respect of the plume, target material, and/or a coated substrate may be not so smooth and high graded as in such an embodiment of this application that utilizes a vertical and/or linear movement (119) (FIG. 8) for the target (112).

If the situation appears to be according to FIG. 6, so therein in duty 4 pieces (91) and (92) of vaporization cassettes, which in addition, but not limited to that only, can be oppositely placed to each other so that the product to be coated is arranged to pass through the active coating area in such a way that each side of the product is to be coated at the same time.

If the products are in a horizontal position (but not limiting to that only), when fed through the pair of vaporization cassette, one of the laser beams advantageously can be directed form below and the other beam above, each directed to its own target as turned 90°, so that the laser beam hit perpendicularly to a target, so yielding a plume of the target material as plasma towards the working piece.

It is difficult to understand that how such a laser ablation application described above were made with completely free propagating laser beams.

### Example 7

PDAD-laser system according to the example 7 and an embodiment of the invention is illustrated in this example, which comprises in the embodiment a solidly integrated expander and/or correction optics attached to a diode-pump arranged to produce the radiation to be directed to a turbine scanner.

### Example 8

FIG. 8 illustrates a PDAD-laser system comprising a diode-pump (112) arranged to generate a high power laser pulse (115) into the working target, which is inside a vacuum chamber (124) as a part of the vaporization/ablation system itself, which comprises a path or an improved path according to an embodiment of the invention, so comprising a turbine scanner (111), and the necessary optics comprising the collector lenses (116) and the vaporization cassette (119), in which the laser beam is directed and/or focussed into/onto the target (121) itself In such case, the diode-pump (112), in which the high-power laser beam has been brought up, has been fed only by a low-power pre-amplified light pulse via an optical fibre. The produced high-power laser-light is expanded within the diode-pump (112) immediately so that the light can be scanned with a turbine scanner (111) and/or the collimating/focussing lenses onto/into the target. The turbine scanner (111) and the motor rotating it, diode-pump (112) and the necessary electronics are situated onto a common circuit board (120), which has been situated into a multi-operational body (123). A system according to FIG. 8 has been situated for example inside (91) (92) into a vacuum evaporation/ablation arrangement (89) according to an embodiment shown in FIG. 6.

### Example 9

An operating principle of according to a method of an embodiment the invention has been shown also in FIG. 9, wherein a typical case according to the FIG. 6 is illustrated for producing the work-pieces. It is important for the example that there are more than one vaporization cassettes (135), which feature has been depicted in more detail in FIG. 8 in the production apparatus (For example, FIG. 6). The work processes are identical in the vaporization cassettes (135), (136), (137) and (138), independently on the exact number of said cassettes but, also from the repetition rate [Hz], pulse length and/or pitch [ns, ps, fs, as], pulse energy [J], pulse power [W] etc. However, situations can occur in a variant of an embodiment of the invention that substances are used in the vaporization processes, which need individual parameterization of the quantities above for each or some vaporization cassettes (136), (137) and (138) if common parameters are not applicable.

In the novel method according to an embodiment of the invention, the pulse power and/or pulse-energy can be adjusted or controlled vaporization cassette specifically. An advantage of that is that the adjustment does not necessary influence on the PDAD-system at all. The adjustment can be made by adjusting or controlling the diode-pump, the power-amplifier output power, and in said method the power of the power-amplifier is not limited as such at all to any specific, so each power amplifier can be thus adjustable individually and independently for each diode-pump, however, not limiting the adjustment only to that.

Identical in association to the work-process means that the work-process as such is made always with a same vaporization cassette, and that parameters which are essential for the detailed process taken as a whole are constants, such as the repetition rate [Hz] and or pulse length, but also the pitch. In an embodiment of the invention, the whole preamplifier and controlling unit are common to all vaporization cassettes at each working place with the target/substrate, the repetition rate [Hz], pulse length and/or the pitch are a constant in suitable part for such a unit, but in another embodiment the number of units is dependent on the number of repetition rates, the number of the pulse lengths, and/or the pitch between two successive pulses. Thus, keeping the device or apparatus specific properties as constant as possible, however not limiting modular applicability of extending or deducing the arrangement, method and/or system according to an embodiment of the invention.

Further on the FIG. 9, according to the indicated operation principle therein, the working points, the vaporization cassettes (135), having each a working width of 150 mm, for example, but without limitation to the mentioned only, can be mounted operationally in parallel and/or in series, respectively say, for example only, five of (136) and ten of (137). In addition or optionally, the same system can comprise the same parts (136) and (137) comprised by a wholeness (138). The vaporization cassettes should not be limited according to any of the details of this example only, but the given details should be understood as an example from which a skilled man in the art can see many ways for implementation for an embodiment without leaving the scope of the example.

Providing a production device for a purpose of certain product manufacturing, keeping the device as economic to manufacture, and to comprise scalable modularity to any reasonable size, the device should be made for such a respect that the components and the parts such as the vaporization cassette, pre-amplifier, controller are sufficiently identical so that the system size can be scaled by simply adding units into the system comprised by the production device.

For instance, the central unit of a PDAD-laser system, which can be situated wherever in a reasonable place for the optimum operational aspects in consideration, even at a distance of 20 m, even in a different room, the central unit can be comprised so that at least the power sources for the diode-pumps, for the power amplifiers, are situated into where ever advantageous location but so that a line (126) leads from the central unit to each working point, as the divided at the working volume (139) to each working point with target/substrate, for instance to fifty parts (129). The controlling unit for the whole laser system to control each radiation source can comprise as many controllers as radiation sources with the appropriate path to control, but in another embodiment at least some radiation sources are controlled as a group, and some others as independently on each other, so to gain a freedom to control the various radiation sources and/or the related optical path components.

So, for instance the operation of 10 vaporization cassettes can be controlled by a feed-through (127) having 22-terminals as a constant arrangement for a certain number of cassettes, but the controlling can be made normally by a single light cable leading the signal to each controllable vaporization cassettes. Equally well, a Bluetooth, IR- or any other data transfer format known as such can be applied to the control media.

A vaporization cassette (135) comprises electronic circuit board (FIG. 8) (120) on which any data transfer component can be situated, if needed.

The light fibre (128) is most advantageously in FIG. 9 branched at the working point (139) inside the working space to the parts (131), for instance to 20 separate branches. It is shown additionally in FIG. 9 that each vaporization cassette (135) receives a line (134) that provides the energy for the vaporization cassette for its operation, a line for (138) the control and/or the line (132) for pre-amplified laser pulse. The lines (132, 134, 138) shown can be separate lines individually or in combination, or the lines can be integrated into one line.

Additionally, a line leads from each vaporization cassettes (135) to, for providing, the central unit with information on the state, results from the vaporization process, phases, etc process parameters, and/or alarms that relate to the operational aspects of the cassette, etc.

Thus, the laser pulse of the each diode-pump is so strong that it is not possible to deliver it via a known fibre from the diode-pump to the target, but the each diode-pump can be controlled by a low-power laser beam.

Thus, according to the PDAD-principle the large radiation power in pulsed form is produced at the very location of the use, i.e. by means that are integrated into the vaporization cassette, FIG. 9 (135).

Thus, also two generic problems of a fibre-lasers are eliminated, namely the fibre and the connector, so the optical laser pulse need not to go via the fibre nor through optical connectors, which are not needed in a system according to the embodiment of the invention concerning the PDAD-system.

### Example 10

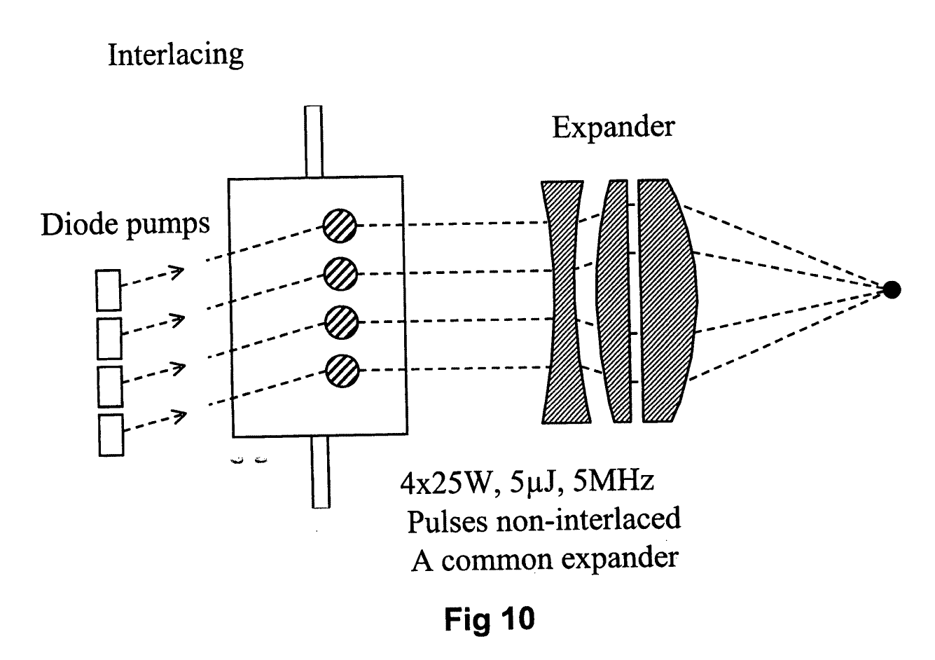

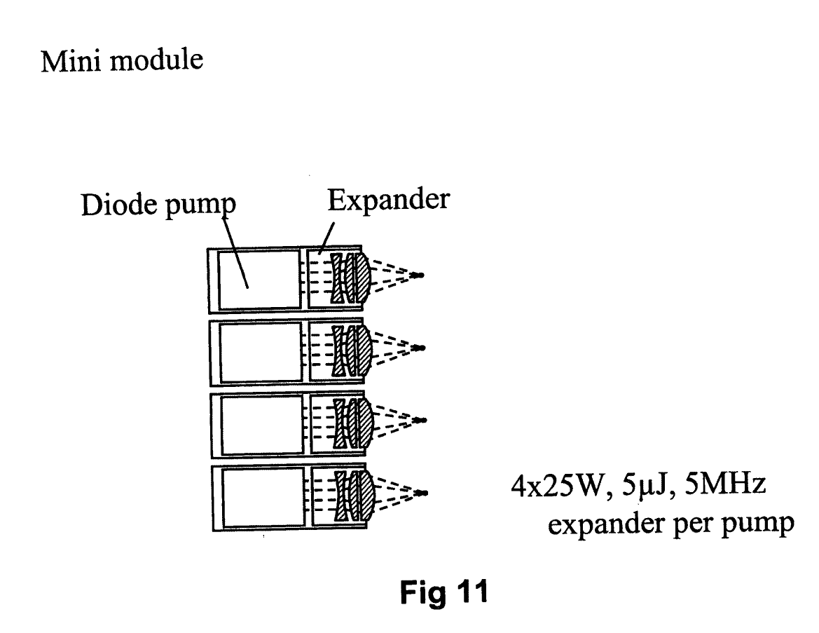

Example 11 illustrates a radiation source arrangement according to an embodiment of the invention, comprising several diode-pumped laser beams each directed via a turbine scanner and a expander to a vaporizing/ablation target (FIG. 10).

### Example 11

Example 11 illustrates a diode-pump set according to an embodiment of the invention, comprising for each diode-pump its own optical beam expander. Such a mini-module structure can produce for separate laser beams.

### Example 12

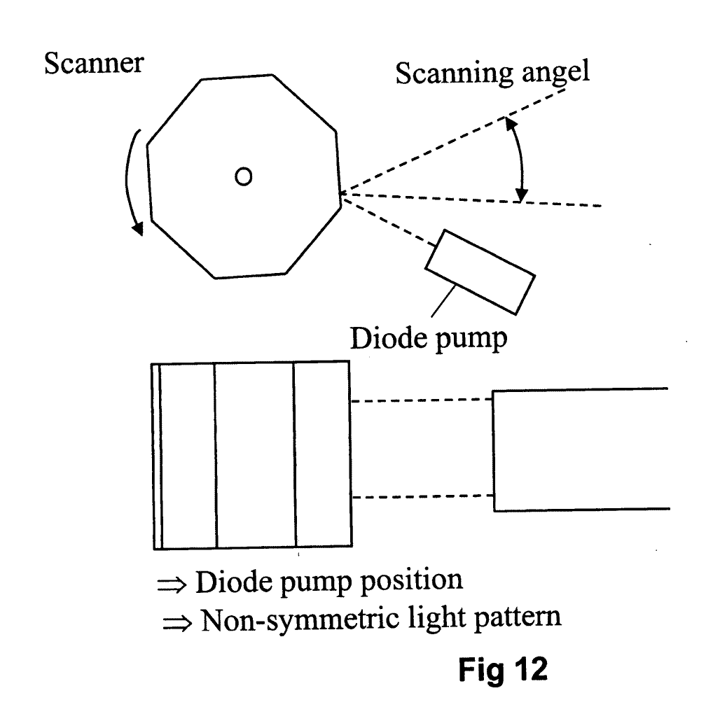

Example 12 (FIG. 12) illustrates asymmetric light pattern generation.

### Example 13

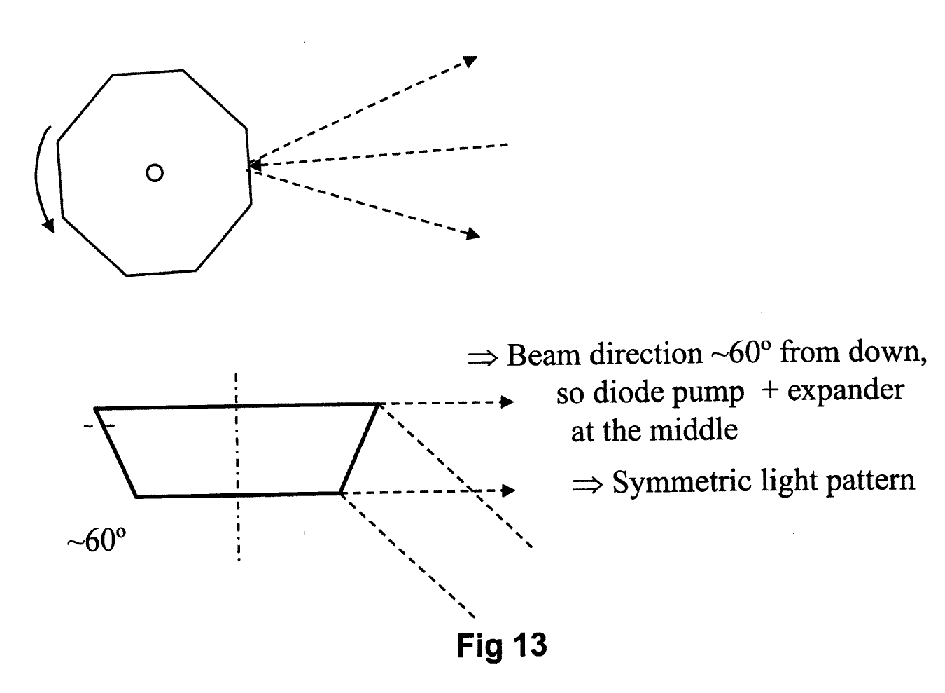

Example 13 (FIG. 13) illustrates symmetric light pattern generation. According to an embodiment of the invention the diode-pump can be located outside of the vacuum vaporization/ablation device, whereas the turbine scanner, correction optics and/or the target material are inside the device. However, a skilled man in the art knows from the embodiments of the invention that there are many ways to implement the device into the same cover as a device, however, without leaving the scope of the embodied and so claimed arrangements.

### Example 14

An optical surface has been cold-worked with an arrangement of a vacuum vaporization/ablation arrangement according to an embodiment of the invention, according to the first, second or third aspect of the invention. Such an optical surface can be actually almost any optical surface as manufactured with the help of an embodiment of the invention. Scope of optical surface in this example includes lenses of various kinds, irrespective their shape are they concave, convex, or halfly either or, or both. Scope of optical surface in this example includes also plate-like at least partly transparent, clear or opaque windows or like that pass through electromagnetic radiation. Scope of optical surface in this example includes also mirrors and/or screens. Scope of optical surface in this example includes also surfaces of prismatic objects, Fresnell-plates, grids of various kinds, television tube surfaces or display screens etc.

### Example 15

A blade has been cold worked with an arrangement of vacuum vaporization/ablation arrangement according to an embodiment of the invention, according to the first, second or third aspect of the invention. Scope of blade in this example includes at least any blade, irrespective is it a domestic knife in kitchen or in garden, industrial part of a cutting device in textile, paper factory, or consumables factory like butchers and/or bakery or a tool in forestry for cutting tree or timber. Scope of blade includes also blades that have shape of linear and/or curved, with, or without serration. Rotating blades are also included into the scope of blade. Shaving blades as well as swords and axes are included into the scope of blade.

### Examples 16

A transformer has been made by cold-work with an arrangement of vacuum vaporization/ablation arrangement according to an embodiment of the invention, according to the first, second or third aspect of the invention. Scope of transformer includes in this example at least any transformer suitable for utilization of the aspects. Transformers that transform for instance electromagnetic radiation to electricity or vice versa with help of a coating are included into the scope. Solar cells, heating elements or Peltier-elements, irrespective the transparency or not, feature of opaque or clear are included into the scope of example 16. Membranes that bend, by radiation, heat, and/or electricity are included into the scope of transformers, irrespective are they micro-mechanical elements or macroscopic elements that comprise a bending/oscillating part or not. Also surfaces that comprise a coating manufactured according to the first, second and/or third aspect of the invention for a self-cleaning feature by a film, irrespective are they window like or mirror like and irrespective on the fact are such surfaces transparent or not, are the surfaces opaque or clear, they appear in the scope of this example.

### Example 17

A vessel has been made by cold-work with an arrangement of vacuum vaporization/ablation arrangement according to an embodiment of the invention, according to the first, second or third aspect of the invention. Scope of vessel includes in this example at least domestic and/or industrial vessels from a tea cup to a reactor of a chemical factory. Also transfer lines for transferring a fluid are considered into the scope of the vessel in this example. The coating can be made on to a outer, and/or inner surface of the vessel. The coating can be a wear resistant improving, but also act in addition or optionally for increasing the radiation tolerance of the vessel, chemical tolerance of the vessel and/or increasing the cleaning efficiency when the vessel is to be cleaned. Into the scope of this example belong a vessel that has a roughening made by the second aspect of the invention, for a certain appearance or for a purely to a technical aim, for bonding a part for example. Into the scope are included in this example also boats, ships submarines, flying devices, motor driven vehicles like busses, trucks, lorries, cars and trains and/or parts thereof as well as military vehicles such as related cars and tanks.

### Example 18

A tool has been made by cold-work with an arrangement of vacuum vaporization/ablation arrangement according to an embodiment of the invention, according to the first, second or third aspect of the invention. Scope of tool includes in this example at least any hammer, screw driver, wrenches or alike as of solid or adjustable capacity, saws, chain saws, drills, rotovators, cutters, scissors, blades. Into the scope of tool are also included ropes, chains, nails, spikes, and screws, as well as bolts and/or nuts but also studs and rivets, and mechanical bearings and hinges for any kind for medical, domestic or industrial use.

### Example 19

A medical replacement part has been made by cold-work with an arrangement of vacuum vaporization/ablation arrangement according to an embodiment of the invention, according to the first, second or third aspect of the invention. Scope of medical replacement part includes in this example at least any medical replacement part of bone, which part comprises a surface made according to an embodiment of the invention. Also individual tooth and/or teeth are included into the scope with the coating. Artificial joints and hinges are in the scope, with an surface coating that is wear resistant for the purpose. The coating can increase the mechanical wear-resistance, but also chemical wear resistance in the mounted environment of each such part. The coating can enhance also bone/cement attachment for a replacement part. On other hand, surfaces that are manufactured for such a replacement part that is planned take part for potential bone formation in an ossifying process can be suitably roughened and/or coated for the optimization of the ossifying. The parts can be provided with a surface coating that a tissue next the part can attach easily. Into the scope of medical replacement parts are also included ropes or alike, chains, nails, spikes, and screws, as well as bolts and/or nuts but also studs and rivets, and mechanical bearings and hinges for any kind. Stents, or artery parts, made with or without a coating are also included into the scope of this example, as well as replacement parts of arteries as coated in suitable part are also included. Embodiments of the invention according to the first aspect, second aspect or third aspect of the invention can be used to produce texture surface with coating on a surface or a certain part thereof, not only to medical replacement parts but also to, say, electromechanic-related and/or optical surfaces or any surface suitable for the coating.

### Example 20

An electro-mechanical part for an electronic device has been made by cold-work with an arrangement of vacuum vaporization/ablation arrangement according to an embodiment of the invention, according to the first, second or third aspect of the invention. Scope of the electro-mechanical part includes in this example at least electric component or a circuit made of such, made by means of a semiconductor substrate in a suitable lithography according to the first and/or second aspect of the invention. Into the scope are included also resistors, that can be made with a suitable material as a coating, directly onto a substrate with a lithographic pattern and/or onto a separate substrate body made of an insulator. Into the scope are included also capacitors provided with the coating on a plate and/or insulation for aiming to improved leak current behaviour, characteristic in the frequency response, operating voltage, and/or mechanical size, for example. Especially beneficial are adjustable electro-mechanical components like potentiometers or alike that can be manufactured with wear resistant coating materials. Beneficial are also motor bearings. Insulators of various kinds are included into the scope of this example, provided that the insulating material has been formed for aiming to improved leak current behaviour, characteristic in the frequency response, operating voltage, and/or mechanical size, for example.

### Example 21

A magnetic composition is made by cold-work with an arrangement of vacuum vaporization/ablation arrangement according to an embodiment of the invention, according to the first, second or third aspect of the invention. Scope of composition includes in this example at least composition in a form of a thin and/or thick film or other kind of a coating, but also pieces, that have essentially a 3D-form. According to example, any material used for any conventional magnet can be ablated into a plume, another such material and/or several ones can be ablated each forming a plume in the ablation of suitable target. The plumes can be separate in one embodiment but can be mixed in another variant, at least partly. The target material selection, as well as the ablation rate of the materials can be use for the composition of the final material that have magnetic properties. The film could be a layered structure comprising just one layer or several layers. Each layer can be made of its own composition and/or structure. The layers can be made on a plane plate and/or onto a curved geometry. The curved geometry may be a bead geometry or a cylindrical geometry. Magnetic field can be present during the film formation from the plume at the surface to be coated.

### Example 22

Example embodies a laser arrangement according to an embodiment of the invention. The mentioned parameter values are examples, and are thus not restrictive only to the mentioned values. The turbine scanner as embodied is only an example, and thus not restrictive.

| | | |
|---|---|---|
| Diode-pumped fibrous laser | A | over 10 W |
| system | PICO-SECOND LASER | advantageously, 20 . . . 1000 W |
| | | pulse energy 2 . . . 15 μJ |
| | | repetition rate 1 MHz, |
| | | advantageously. 10 . . . 30 MHz |
| | | or higher |

+

| | | |
|---|---|---|
| Smooth operated, | B | Velocity 0 . . . 4000 m/s, or |
| linear beam movement, | TURBINE SCANNER | higher, |
| high laser power, | | typically 50 . . . 100 m/s or |
| vacuum and/or atmosphere | | higher |

+

| | | |
|---|---|---|
| Repetition 100%, | C | Material thickness a) below, |
| High quality, | Film and/or lamel target | b) the same or |
| High laser power | feed | c) larger than inside |
| | | the focus |

+

| | | |
|---|---|---|
| Layer-structures, each layer | D | control rang 0.5 . . . 15 μJ |
| formed from the same or different | AUTOMATIC PULSE | fast, max 1 μs |
| materials | ENERGY/POWER CONTROL | pre-progammable, |
| | SYSTEM | quality control even to micro- |
| | | scale |

+

| | | |
|---|---|---|
| Integration to the laser system | E | Whole work width operation |
| possible | INTEGRATED PLASM | pulse precison |
| | INTENSITY MEASUREMENT | quality control even to micro- |
| | | scale |

+

| | | |
|---|---|---|
| The shorter wave-length the | F | 1064 nm, |
| better yield | LASER RADIATIOIN | 293 . . . 420 nm, |
| | WAVE LWNGTHS | 420 . . . 760 nm |
| | | other wave lengths |

+

| | | |
|---|---|---|
| Operation applicability according | G | Choice according to the cleanliness, |
| to the embodiement | VACUUM, GAS- | reactivity, coating rate, |
| | ATMOSPHERE, FREE | and/or the economics. |
| | SPACE | |

Pico-second laser system (A)+Turbine scanner (B)+target feed (C) as lamels or film yield high quality products and/or surfaces of large amounts. The products can be of single crystalline diamond and/or silicon to be used as a substrate for semiconductor industry for instance, produced in vacuum, or in a gas atmosphere.

The coating can be formed on a surface of any kind, as demonstrated in FIG. 25. For example, on metal, plastics and/or paper. In one embodiment the coating has a coating layer thickness of 5 μm. The semiconductor material can be a silicon as pure or as a compound, but in a flexible form, suitable into use of electronics, micro and/or nano-electronics. The points D, E, F and G help the manufacturing of high quality products in industrial scale, repeatable and promote the quality control.

1. A path of radiation transference for guiding electromagnetic radiation, characterized in that said path comprises a turbine scanner arranged to guide said electromagnetic radiation, in a radiation geometry, from the radiation source to the target of the radiation, said radiation being transferred as pulsed high-power laser beam pulses.

2. The path of radiation transference for guiding electromagnetic radiation, according to claim 1, characterized in that said path comprises a beam expander.

3. The path of radiation transference for guiding electromagnetic radiation, according to claim 1, characterized in that said path comprises a correction optical means arranged to correct the beam geometry at the path.

4. The path of radiation transference for guiding electromagnetic radiation according to claim 3, characterized in that said geometry is a focus geometry.

5. The path of radiation transference for guiding electromagnetic radiation according to claim 3, characterized in that said geometry is the geometry in which the beam is arranged to hit the turbine scanner part.

6. The path of radiation transference for guiding electromagnetic radiation according to claim 3, characterized in that said geometry is the geometry in which the beam is arranged to hit the target.

7. The path of radiation transference for guiding electromagnetic radiation according to claim 3, characterized in that said radiation geometry comprises at least a first geometry for the radiation at the radiation source and a second radiation geometry for the radiation at the target.

8. The path of radiation transference for guiding electromagnetic radiation according to claim 3, characterized in that said turbine scanner is arranged into such a radiation geometry in said path that the beam from the part between the radiation source and the turbine scanner is directed to another direction than an emitting plume arranged to form from said target by said radiation.

9. The path of radiation transference for guiding electromagnetic radiation according to claim 3, characterized in that said first geometry is different than said second geometry.

10. A radiation source arrangement, characterized in that said arrangement comprises at least one or several radiation sources and that each radiation source has an optical path according to any of the claims 1-9.

11. A radiation source arrangement according to claim 10, characterized in that said arrangement comprises at least two radiation sources having at least partly same optical path.

12. A radiation source arrangement according to claim 10, characterized in that said arrangement comprises at least two radiation sources having the same target area at the target side of the optical path.

13. A radiation source arrangement according to claim 10, characterized in that said arrangement comprises at least a first radiation source with a first feature and a second radiation source with a second feature.

14. A radiation source arrangement according to claim 13, characterized in that said first feature is at least one of the following:
(i) the wave-length characteristic to the radiation source,
(ii) on-duty pulse length,
(iii) length of off-duty period between two successive pulses,
(iv) repetition rate of the on-duty occurrences,
(v) radiation intensity,
(vi) energy and/or power per pulse,
(vii) polarization of the radiation,
(viii) a radiation geometry, and
a combination of at least two or more of the features (i)-(viii).

15. A radiation source arrangement according to claim 13, characterized in that said second feature is at least one of the following:
(i) the wave-length characteristic to the radiation source,
(ii) on-duty pulse length,
(iii) length of off-duty period between two successive pulses,
(iv) repetition rate of the on-duty occurrences,
(v) radiation intensity,
(vi) energy and/or power per pulse,
(vii) polarization of the radiation,
(viii) a radiation geometry, and
a combination of at least two or more of the features (i)-(viii).

16. A radiation source arrangement according to claim 13, characterized in that said first feature is at least partly different than said second feature.

17. A radiation source arrangement according to any of claims 10-16, characterized in that said arrangement comprises at least a laser in a plurality of lasers comprising at least one laser that is a diode-pumped laser or other than a diode-pumped laser.

18. A radiation source arrangement according to any of claims 10-16, characterized in that at least one of said radiation sources is arranged to produce radiation having a wave length in range which wave length is at least one of the following:
wave length range between a radio wave-length and an infrared wave length,
wave length range in infrared,
wave length range of visible light,
wave length range of ultraviolet,
wave length range of X-rays,
wave length range of gamma-rays, and
an intermediate wave length range between any just mentioned two wavelength ranges.

19. A radiation source arrangement according to any of claims 10-18, characterized in that it comprises as a radiation source a pulsed-laser suitable to hot-work, as a micro- and/or nano-second laser.

20. A radiation source arrangement according to any of claims 10-18, characterized in that it comprises as a radiation source a pulsed laser suitable to cold-work, as a pico-, femto- and/or alto-second laser.

21. A radiation source arrangement according to any of claims 10-18, characterized in that it comprises as a radiation source a pulsed laser for which the pulse length is defined as the time there between of the switch-on and switch-off of the laser.

22. A radiation source arrangement according to claim 21, characterized in that it comprises a continuously operated laser.

23. A target material, characterized in that said target material is arranged to be vaporizable and/or ablatable by radiation of a radiation source arrangement according to a claim 10-22.

24. A target material according to claim 23, characterized in that said target material has product form of powder refined by ablation by radiation of a radiation source arrangement according to a claim 10-18.

25. A target material according to claim 23, characterized in that said target material has product form of liquid or solution, as refined by ablation by radiation of a radiation source arrangement according to a claim 10-22.

26. A target material according to claim 23 or 24, characterized in that said target material is arranged to be on a film or on a sheet.

27. A target material according to claim 26, characterized in that said target material is on a rollable web.

28. A target material according to claim 26, characterized in that said target material comprises surface structure arranged to lower the ablation threshold at a certain radiation of a radiation source with a feature.

29. A target material according to claim 26, characterized in that said target material comprises surface structure arranged to improve the ablation yield at a certain radiation of a radiation source with a feature.

30. A target material according to claim 23, 28 or 29, characterized in that said surface structure comprises a target feature, which is a geometrical feature, a structural feature and/or a compositional feature.

31. A target material according to claim 23; 28 or 29, characterized in that said surface structure comprises a first target feature, which is a first geometrical feature, a first structural feature and/or a first compositional feature.

32. A target material according to claim 23, 28 or 29, characterized in that said surface structure comprises a second target feature, which is a second geometrical feature, a second structural feature and/or a second compositional feature.

33. A target material according to claim 30, 31 or 32, characterized in that any of said geometrical feature has a surface feature, a base feature and/or a modification feature.

34. A target material according to claim 33, characterized in that any of said surface feature is a figure-shape feature with a shape dimension and a pitch there between two said successive figure-shape parts of same kind.

35. A target material according to claim 34, characterized in that said figure-shape feature comprises at least one of the following shapes: a cubic shape, rectangular-ridge shape, conical-ridge shape, rectangular-ridge shape, cut pyramid shape, round-hole shape, rectangular-hole shape, cylindrical-shape, prismatic-shape, tetra-shape, and a co-operative combination of at least two of the just mentioned.

36. A target material according to claim 35, characterized in that said shape dimension and/or said pitch is arranged according to a radiation source feature to optimize the target material vaporization/ablation.

37. A target material according to claim 33, characterized in that said base feature is at least one of the following: thin base, thick base, opaque base, transparent base, polarizing base, non-transparent base, reflecting base, vaporizing base and a combination of said base features from which combinations of the complementary features are excluded.

38. A target material according to claim 33 or 35, characterized in that said modification feature is at least one of the following: tilt of the figure in figure shape in respect to the normal of a plane defined by three adjacent figure parts, edge curvature of the figure in figure-shape, increase or decrease rate of the pitch in a direction per unit length, increase or decrease rate of the shape dimension per unit length, and a combination of said modification features from which combinations of the complementary features are excluded.

39. A target material according to any of the claims 23-38, characterized in that said target material has a crystalline structure as a structural feature.

40. A target material according to claim 39, characterized in that said target material has a crystalline structure of at least two crystallines comprising a first structural feature with a first set of Miller-indexes and a second structural feature with a second set of Miller-indexes.

41. A target material according to any of the claims 23-40 characterized in that said target material comprises as a first compositional feature an element arranged into the target material to be used for ablation plume formation.

42. A target material according to any of the claims 23-40 characterized in that said target material comprises as a second compositional feature, an element arranged into the target material to be used for ablation plume formation and/or adjusting the ablation plume environment composition.

43. A vacuum vaporization/ablation arrangement, characterized in that said vaporization/ablation arrangement comprises a radiation source arrangement according to claim 10, as arranged to vaporize/ablate material from a target.

44. A vacuum vaporization/ablation arrangement according to claim 43, characterized in that said vaporization/ablation arrangement is arranged to coat a substrate by a target material to be used in coating of the substrate.

45. A vacuum vaporization/ablation arrangement according to claim 43, characterized in that said vaporization/ablation arrangement comprises a target material unit arranged to operate with a target material.

46. A vacuum vaporization/ablation arrangement according to claim 45, characterized in that said target material is target material according to any of the claims 23-42.

47. A vacuum vaporization/ablation arrangement according to claim 43, characterized in that said arrangement is arranged to, as being in the same cover with an arrangement member of the same arrangement, form a device.

48. A vacuum vaporization/ablation arrangement according to claim 43, characterized in that said arrangement comprises atmosphere means arranged to adjust the atmosphere in the reactor volume in which the vaporization/ablation is arranged to occur.

49. A vacuum vaporization/ablation arrangement according to claim 48, characterized in that said atmosphere means comprises a vacuum pump arranged to minimize or adjust the pressure in said reactor volume to pre-defined level.

50. A vacuum vaporization/ablation arrangement according to claim 48, characterized in that said atmosphere means comprises a pre-cursor unit arrange to arrange a pre-defined reactor atmosphere for vaporization/ablation in a pre-defined pressure and/or temperature.

51. A vacuum vaporization/ablation arrangement according to claim 50, characterized in that said atmosphere means comprises a heating element arranged to heat at least one of the pre-cursors to a pre-defined temperature.

52. A target material unit, characterized in that it comprises a roll-arrangement arranged to handle target material in a film-like form according to any of the claims 23-42.

53. A target material unit according to claim 52, characterized in that it comprises a first reel arranged to release target material in one end of the film path and a second reel arranged to roll the released target material in the opposite end of the film path.

54. A target material unit according to claim 52, characterized in that it comprises at least one roll from an ensemble of rolls comprising at least one roll, arrange to handle the target material.

55. A target material unit according to claim 52, characterized in that it comprises a heating element arranged to heat the target material at the vaporization/ablation region of the film.

56. A target material unit according to claim 52, characterized in that it comprises at least one reel that is replaceable with a similar as empty and/or with the target material.

57. A target material unit according to claim 56, characterized in that it comprises a mechanism to assist the film assembly via a roll to the film path.

58. A target material unit according to claim 52, characterized in that it is arranged so that the same unit is utilizable to release the target material for the use and/or to receive the target material for the manufacturing said target material.

59. Turbine scanner, characterized in that the turbine scanner comprises a first mirror arranged to change the direction of a coming radiation beam and a second mirror arranged to cool while said first mirror is about to change the direction of the coming radiation in a radiation path.

60. Turbine scanner according to claim 59, characterized in that said first mirror is a mirror of an ensemble of similar first mirrors.

61. Turbine scanner according to claim 59, characterized in that said second mirror is a mirror of an ensemble of similar second mirrors.

62. Turbine scanner according to claim 59, characterized in that it comprises an ensemble of mirrors arranged to form a polygon with faces of which said first and second mirrors are.

63. Turbine scanner according to claim 59, characterized in that it comprises an ensemble of mirrors arranged to form a polygon with faces of which said first and second mirrors are.

64. Turbine scanner according to claim 63, characterized in that said first mirrors have a different tilt angle as said second mirrors in respect to the central axis of polygon.

65. Turbine scanner according to claim 64, characterized in that it is arranged to rotatable around said central axis.

66. Turbine scanner according to claim 59, characterized in that it has a form of a paddle wheel so that the paddles thereof are mirrors of the turbine scanner, arranged to be rotatable along a circular path around the central axis of said paddle wheel.

67. Turbine scanner according to claim 66, characterized in that each of said mirrors in said paddle wheel are arranged to a sharp angle with a tangent of said circular path.

68. Turbine scanner according to claim 66, characterized in that each of said mirrors in said paddle wheel are arranged to a tilt angle with said axis of said paddle wheel.

69. Turbine scanner according to claim 59, characterized in that a mirror face has a diamond surface.

70. Turbine scanner according to claim 59, characterized in that said cooling of said second mirror is arranged to the opposite side of the mirror by a different fluid as the reflective surface of the mirror.

71. Turbine scanner according to claim 59, characterized in that it comprises tilted turbine paddles with mirrors, attached to the rotor part that is provided with an axes.

72. Turbine scanner according to any of claims 59-71, characterized in that it comprises a replaceable mirror part.

73. Turbine scanner according to any of claims 59-72, characterized in that it comprises a particular part on said mirror arranged to reflect radiation, which part is a replaceable mirror part.

74. Turbine scanner according to any of claims 59-73, characterized in that it comprises a gas bearing.

75. Turbine scanner according to claim 74, characterized in that said gas is air.

76. Turbine scanner according to any of claims 59-75, characterized in that it comprises a bearing arrangement to separate bearing surfaces by a magnetic field.

77. Turbine scanner according to any of claims 59-76, characterized in that it comprises ablatable material on a part of said mirror surface.

78. A surface processing method characterized in that the method comprises:
exposing a target material acting as a target to a surface modifying beam,
directing a radiation path for the surface modifying beam from a radiation source to the target for ablation of the target material,
vaporizing/ablating target material to effective depth, for a modification of at least a surface in respect of at least one surface characteristic.

79. A surface processing method according to claim 78, characterized in that said characteristic is at least one of the composition, chemical structure, mechanical structure, physical structure to said effective depth.

80. A surface processing method according to claim 78, characterized in that it comprises
selecting a first surface to a target and/or selecting a second surface to a substrate, for modifying of target material from said first surface by a first surface modifying beam.

81. A surface processing method according to claim 80, characterized in that said modifying comprises removal of material from the surface at the effective depth by said first surface modifying beam.

82. A surface processing method according to claim 80, characterized in that said it comprises setting a surface of a first body to the target and/or a surface of a second body to a substrate so that a second surface modifying beam is used to bring material on to said surface of the second body.

83. A surface processing method according to claim 82, characterized in that said modifying of said surface comprises addition of material on said surface to the effective depth defined as the layer thickness of said material.

84. A surface processing method according to claim 79 and any claim 80-83, characterized in that in the method, material is transferred to a second surface by a second surface modifying beam so that said material originates to said first surface, as being removed by a first surface modifying beam.

85. A coating method, characterized in that the method comprises a surface processing phases according to claim 84, applied for a plurality of substances comprising at least one or several substances to be used for the coating.

86. A coating method according to claim 85, characterized in that at least two substances are ablated in the method essentially from the same target.

87. A coating method according to claim 85, characterized in that in the method, a first substance is ablated from a different target as a second substance.

88. A coating method according to claim 85, characterized in that a first substance and a second substance are ablated in the method in the order of first substance first and then second substance for a formation of a coating.

89. A coating method according to claim 88, characterized in that at least one further substance is ablated for the coating formation on a substrate in the method.

90. A coating method according to claim 88, characterized in that, in the method, one of said substances is a matrix substance of the coating.

91. A coating method according to claim 88, characterized in that, in the method, one of said substances is a dopant for the coating used in the method.

92. A coating method according to claim 88, characterized in that in the method, one of said substances is an additional dopant for the coating to achieve an additional feature to the surface and/or coating used in the method.

93. A coating method according to claim 88, characterized in that one of said substances comprises carbon for the coating used in the method.

94. A coating method according to claim 93, characterized in that said carbon comprises graphite used in the method.

95. A coating method according to claim 93, characterized in that said carbon comprises diamond used in the method.

96. A coating method according to claim 95, characterized in that said diamond has mono-crystalline structure for the coating to be used in the method.

97. A coating method according to claim 88, characterized in that one of said substances comprises uranium, trans-uranium, earth metal, rear-earth, alkaline, hydrogen, lanthanide, and/or a noble gas to be used in the method.

98. A coating method according to claim 88, characterized in that one of said substances comprises a dopant comprising uranium, trans-uranium, earth metal, rear-earth, alkaline, hydrogen, lanthanide, and/or a noble gas to be used in the method.

99. A coating method according to claim 88, characterized in that one of said substances comprises a dopant from boron-group (IIIb) to be used in the method.

100. A coating method according to claim 88 characterized in that one of said substances comprises a dopant from carbon-group (IVb) to be used in the method.

101. A coating method according to claim 88, characterized in that one of said substances comprises a dopant from nitrogen-group (Vb) to be used in the method.

102. A coating method according to claim 88, characterized in that one of said substances comprises a dopant from oxygen-group (VIb) to be used in the method.

103. A coating method according to claim 88, characterized in that one of said substances comprises a dopant from halogen-group to be used in the method.

104. Use of a coating made according to any claim 85-103.

105. Use of a coating method according to any claim 85-103 for a coating.

106. Use of a coating according to claim 105 to coat a surface of a body, which surface is an outer and/or an inner surface of said body.

107. Use of a coating according to claim 106 to coat a surface of a body, which is a body and/or a lining structure of an air-craft vessel, ship, boat, sailing ship or a part thereof; vehicle, or space-craft-vessel.

108. Use of a coating according to claim 106 to coat a surface of a motor and/or a part thereof for an air-craft vessel, ship, boat, sailing ship or a part thereof, vehicle, or space-craft-vessel.

109. Use of a coating according to claim 106 to coat a surface of a lining structure and/or a part thereof for an air-craft vessel, ship, boat, sailing ship or a part thereof, vehicle, or space-craft-vessel.

110. Use of a coating according to claim 106 to coat a surface of a body, which is tool and/or a part thereof.

111. Use of a coating according to claim 106 to coat a surface of a body, which is a piece of furniture aimed to domestic, business and/or industrial use.

112. Use of a coating according to claim 106 to coat a surface of a body, which is a vessel, dish, holder, receptacle, tank, vat, jar, can, pot, bowl, container; tray, bin, trough, tub and/or barrel.

113. Use of a coating according to claim 112 to coat a surface of a body, which is aimed to be used in kitchen, business, arts and/or industry comprising metallurgical industry, food industry, medical industry, chemical industry, painting and/or pigment industry, semiconductor industry.

114. Use of a coating according to claim 106 to coat a surface of a body, which is kitchen-related body, reactor, reactor for a chemical reaction, and/or transfer line of material.

115. Use of a coating according to claim 106 to coat a surface of a body, which is one of the following:
a transparent plate of glass, plastics, composite or a laminated structure,
opaque plate of glass, plastics, composite or a laminated structure,
solar cell and/or part thereof arranged to operate at least on one certain wavelength range, and
a combination of the mentioned.

116. Use of a coating according to claim 106 to coat a surface of a body, which is a building element for a building to be built for housing, business, industry, storing and/or a building to be built for other purpose.

117. Use of a coating according to claim 116 to coat a surface of a body, which is a building element, for a building for housing and/or other building, composing of natural and/or non-synthetic material originating to nature.

118. Use of a coating according to claim 106 to coat a surface of a body, which is a toy or a part thereof.

119. Use of a coating according to claim 106 to coat a surface of a body, which is a watch, clock, mobile, PDA, computer, display, TV, radio, or a part thereof of the any mentioned.

120. Use of a coating according to claim 119 to coat a surface of a body, which is a casing and/or a shell, or a part thereof of the any mentioned.

121. Use of a coating according to claim 106 to coat a surface of a body, which has a fibrous composition at least partly.

122. Use of a coating according to claim 121 to coat a surface of a body, which is thread, yarn, chord, filament, wire, string, solid conductor, strandline and/or rope.

123. Use of a coating according to claim 122 to coat a surface of a body, which has a web structure and/or has a textile structure.

124. Use of a coating according to claim 123 to coat a surface of a body, which is one of the following: fibrous filter, industrial textile, textile for a cloth or paper.

125. Use of a coating according to claim 121 to coat a surface of a body, which is wave-guide for electromagnetic radiation.

126. Use of a coating according to claim 125 to coat a surface of a body, which is made of diamond at least partly.

127. Use of a coating according to claim 125 to coat a surface of a body, which has a different composition before the coating than after the coating.

128. Use of a coating according to claim 106 to coat a surface of a body, which comprises means for practicing sports.

129. Use of a coating according to claim 106 to coat a surface of means, which comprises means for practicing sports and/or hunting.

130. Use of a coating according to claim 129 to coat a surface of a body, wherein said means are means for skiing, slalom, snow boarding, skating on ice or ground, cradle, sledge, sleight, playing games with at least one stick.

131. Use of a coating according to claim 129 to coat a surface of a body, wherein said means are throwing, shooting, sliding, gliding, scrolling or bowling.

132. Use of a coating according to claim 106 to coat a surface of a body, which is a cycle or a part thereof, chain, bearing, or another part of the just mentioned.

133. Use of a coating according to claim 106 to coat a surface of a body, which is a piece of jewelry, decoration, artwork or a copy thereof.

134. Use of a coating according to claim 106 to coat a surface of a body, which is a micromechanical element.

135. Use of a coating according to claim 106 to coat a surface of a body, which is a semiconductor.

136. Use of a coating according to claim 106 to coat a surface of a body, which is a insulator for electricity and/or warmth.

137. Use of a coating according to claim 106 to coat a surface of a body, which is a conductor for electricity and/or warmth.

138. Use of a coating according to claim 106 to coat a surface of a body, which is spare part of human being and/or animal.

139. Use of a coating according to claim 138 to coat a surface of a body, which is a joint surface.

140. Use of a coating according to claim 138 to coat a surface of a body, which is an fixing means, as a rivet, stud, screw, nail, hook or nut.

141. Use of a coating according to claim 106 to coat a surface of a body, which is at least a part of a radiation path.

142. Use of a coating according to claim 141 to coat a surface of a body, which is a target material base in a certain product form, turbine scanner or a part thereof.

143. Use of a coating according to claim 106 to coat a surface of a body, which is a plastic film, in product form of sheets and/or web.

144. Use of a coating according to claim 106 to coat a surface of a body, which is an optical element.

145. Use of a coating according to claim 106 to coat a surface of a body, which comprises a lens, prism, filter, mirror, an attenuator, polarizer or a combination thereof of the just mentioned.

146. Use of a coating according to claim 106 to coat a surface of a body, which is spectacles or contacts.

147. Use of a coating according to claim 106 to coat a surface of a body, which is bond, stock or another paper of value, or means of payment.

148. Use of a coating according to claim 106 to coat a surface of a body, which is a container for storing a substance.

149. Use of a coating according to claim 106 to coat a surface of a body, which is a container for storing hydrogen and/or releasing hydrogen.

150. Use of a coating according to claim 106 to coat a surface of a body, which is a container for storing hydrocarbon and/or releasing hydrocarbon.

151. Use of a coating according to claim 106 to coat a surface of a body, which is a container for storing nuclear fuel and/or an element thereof.

152. Use of a coating according to claim 106 to coat a surface of a body, which is a substrate body to be coated with an UV-active coating.

153. 3D-printer, characterized in that it comprises an arrangement according to claim 43.

154. 3D-printer, characterized in that it comprises
a target holder for holding a processable surface for exposure of said surface to a surface modifying beam to an effective depth thereof,
means for producing the surface modifying beam and/or radiation transferring path to direct said second surface modifying beam to the target,
means for producing a second surface modifying beam and/or a second radiation transferring path to direct said second surface modifying beam to the target, and
a substrate holder for holding said substrate for exposure of said surface to a second surface modifying beam to an effective depth thereof.

155. 3D-printer according to claim 154, characterized in that said surface modifying beam is an ablating beam to stylization of the print.

156. 3D-printer according to claim 154, characterized in that it comprises controller means arranged to control the printing of the 3D-body slice by slice, each slice with its effective depth, wherein said second surface modifying beam is a material plume.

157. 3D-printer according to claim 154, characterized in that it comprises means arranged to carve by cold ablation.

158. 3D-copy-machine, characterized in that it comprises
first means to define and/or formulate data of a 3D-body on its shape and/or dimensions for recording into a file,
second means to convert said data to control commands for controlling a 3D-printer,
a 3D-printer according to any of claims 153-157.

159. 3D-copy-machine according to claim 158, characterized in that it said first means comprise optical means for UV, visible light and/or IR.

160. 3D-copy-machine according to claim 158, characterized in that it said first means comprise X-ray tomography means.

161. 3D-copy-machine according to claim 158, characterized in that it said first means comprise acoustic means.

162. 3D-copy-machine according to any claim 158-161, characterized in that it said first means is based on interference.

163. 3D-copy-machine according to any claim 158-161, characterized in that it is arranged to copy and/or print micro-scale bodies.

164. 3D-copy-machine according to any claim 158-161, characterized in that it is arranged to copy and/or print macroscopic-scale bodies.

165. 3D-copy-machine according to any claim 158-161, characterized in that it is arranged to copy and/or print bodies that have their size between the microscopic and macroscopic-scale.

166. An arrangement to control radiation power of a radiation source via path of radiation transference for guiding electromagnetic radiation characterized in that the arrangement comprises in said path observation means arranged to observe anomalies in a surface modifying beam from a pre-defined feature and/or to record said anomalies into a file, and feed back means arranged to form a feed back to minimize the observed anomaly and/or to adjust the radiation source to the pre-defined feature.

167. An arrangement according to claim 166, characterized in that said feature is a feature according to claim 14 and/or claim 15.

168. An arrangement according to claim 166, characterized in that said feed back signal is used to adjust a part of a path of radiation transference for guiding electromagnetic radiation.

169. An arrangement according to claim 168, characterized in that said part is a turbine scanner.

170. Use of a coating according to claim 106 to coat a surface of a body as a substrate, which body belongs at least to a patent class human necessities and/or to a sub-class hierarchy thereof.

171. Manufacturing method of target material, characterized in that a film and/or a sheet like base is exposed to a material plume of the ablatable target material for coating a part of the base at least on one side with said target material.

172. The manufacturing method according to claim 171, characterized in that the method comprises utilisation of a mechanical shaplone for providing the target material a shape feature.

173. The manufacturing method according to claim 171, characterized in that the method comprises providing the base markings for the target material having a shape feature with at least a pitch in one direction and/or two directions.

174. The manufacturing method according to claim 173, characterized in that said markings are electric and/or magnetic markings.

175. The manufacturing method according to claim 173, characterized in that said markings are thermal markings.

176. The manufacturing method according to claim 173, characterized in that said markings are provided as seeds onto locations on the base for a heterogeneous nucleation and/or a following condensation to be used for the formation of the target material into certain predefined form.

177. The manufacturing method according to claim 176, characterized in that said method comprises a stylization phase of forming the target material formations on the base.

178. The manufacturing method according any of the claims 171-177, characterized in that said method comprises using a target material unit according to claim 58.
